(19) United States
(12) Patent Application Publication
(10) Pub. No.: US 2024/0014812 A1
(43) Pub. Date: Jan. 11, 2024

(54) SEMICONDUCTOR DEVICE

(71) Applicant: ROHM CO., LTD., Kyoto (JP)

(72) Inventors: Yoshinori FUKUDA, Kyoto (JP); Hajime OKUDA, Kyoto (JP); Yuji OSUMI, Kyoto (JP)

(73) Assignee: ROHM CO., LTD., Kyoto (JP)

(21) Appl. No.: 18/471,842

(22) Filed: Sep. 21, 2023

Related U.S. Application Data
(63) Continuation of application No. PCT/JP2022/012692, filed on Mar. 18, 2022.

(30) Foreign Application Priority Data
Mar. 31, 2021 (JP) 2021-060326

(51) Int. Cl. H03K 17/08

(52) U.S. Cl. CPC H03K 17/08; H01L 29/0696

(57) ABSTRACT

A semiconductor device includes a main transistor which includes a first system transistor generating a first system current and a second system transistor generating a second system current independently of the first system transistor and which generates an output current including the first system current and the second system current, a first system monitor transistor which generates a first system monitor current that corresponds to the first system current, and a second system monitor transistor which generates a second system monitor current that corresponds to the second system current.

### CROSS REFERENCE TO RELATED APPLICATIONS

The present application is a bypass continuation of International Patent Application No. PCT/JP2022/012692, filed on Mar. 18, 2022, which claims priority to Japanese Patent Application No. 2021-060326 filed in the Japan Patent Office on Mar. 31, 2021, and the entire disclosure of the application is incorporated herein by reference.

### BACKGROUND

### 1. Field of the Disclosure

The present disclosure relates to a semiconductor device.

### 2. Description of the Related Art

US Patent Application Publication No. 2019/0260371 disclosed a semiconductor device which includes a first power transistor, a second power transistor, an active clamp circuit and an active clamp shut-off circuit. A drain of the second power transistor is electrically connected to a drain of the first power transistor. A source of the second power transistor is electrically connected to a source of the first power transistor. The active clamp circuit is electrically connected to the drain and a gate of the first power transistor and electrically connected to the drain and a gate of the second power transistor. The active clamp shut-off circuit is electrically connected to the active clamp circuit and the gate of the second power transistor.

### BRIEF DESCRIPTION OF THE DRAWINGS

FIG. 1 is a plan view which shows a semiconductor device according to a first embodiment.

FIG. 2 is a cross-sectional view taken along line II-II shown in FIG. 1.

FIG. 3 is a plan view which shows a layout example inside a semiconductor chip shown in FIG. 1.

FIG. 4 is a block circuit diagram which shows an electrical arrangement example of the semiconductor device shown in FIG. 1.

FIG. 5 is an equivalent circuit diagram of a main transistor and a monitor transistor shown in FIG. 4.

FIG. 6 is another equivalent circuit diagram of a main transistor and a monitor transistor shown in FIG. 5.

FIG. 7A is a circuit diagram which shows an operation example of the main transistor and the monitor transistor.

FIG. 7B is a circuit diagram which shows an operation example of the main transistor and the monitor transistor.

FIG. 7C is a circuit diagram which shows an operation example of the main transistor and the monitor transistor.

FIG. 8 is a block circuit diagram which shows a configuration example of an electrical arrangement of the semiconductor device shown in FIG. 1 (=a configuration example to which a two-system main transistor and a two-system monitor transistor are applied).

FIG. 9 is a circuit diagram which shows a configuration example of the block circuit diagram shown in FIG. 8.

FIG. 10 is an enlarged view of a region X shown in FIG. 3 and a plan view which shows a layout example of the main transistor and the monitor transistor shown in FIG. 8.

FIG. 11 is an enlarged view of a region XI shown in FIG. 10.

FIG. 12 is an enlarged view of a region XII shown in FIG. 10.

FIG. 13 is a cross-sectional view taken along line XIII-XIII shown in FIG. 11.

FIG. 14 is a cross-sectional view taken along line XIV-XIV shown in FIG. 11.

FIG. 15 is a cross-sectional view taken along line XV-XV shown in FIG. 11.

FIG. 16 is a cross-sectional view taken along line XVI-XVI shown in FIG. 11.

FIG. 17 is a cross-sectional perspective view which shows a main portion of the main transistor together with a first configuration example of a first channel region and a second channel region.

FIG. 18 is a cross-sectional perspective view which shows the main portion of the main transistor together with a second configuration example of the first channel region and the second channel region.

FIG. 19 is a cross-sectional perspective view which shows the main portion of the main transistor together with a third configuration example of the first channel region and the second channel region.

FIG. 20 is a cross-sectional perspective view which shows the main portion of the main transistor together with a fourth configuration example of the first channel region and the second channel region.

FIG. 21 is an enlarged view of a region XXI shown in FIG. 10.

FIG. 22 is a cross-sectional view taken along line XXII-XXII shown in FIG. 21.

FIG. 23 is a cross-sectional view taken along line XXIII-XXIII shown in FIG. 21.

FIG. 24 is an enlarged view of a region XXIV shown in FIG. 10.

FIG. 25 is a cross-sectional view taken along line XXV-XXV shown in FIG. 24.

FIG. 26 is a cross-sectional view taken along line XXVI-XXVI shown in FIG. 24.

FIG. 27A is a cross-sectional perspective view which shows an operation example of the main transistor.

FIG. 27B is a cross-sectional perspective view which shows an operation example of the main transistor.

FIG. 27C is a cross-sectional perspective view which shows an operation example of the main transistor.

FIG. 28 is a timing chart which shows a control example of the main transistor.

FIG. 29 is an enlarged view of a region X shown in FIG. 3 and a plan view which shows a layout example of a main transistor and a monitor transistor of a semiconductor device according to a second embodiment.

FIG. 30 is an enlarged view of a region XXX shown in FIG. 29.

FIG. 31 is a cross-sectional view taken along line XXXI-XXXI shown in FIG. 30.

FIG. 32 is a cross-sectional view taken along line XXXII-XXXII shown in FIG. 30.

FIG. 33 is an equivalent circuit diagram which shows the circuit diagram shown in FIG. 5 together with the monitor transistor according to a first modification example.

FIG. 34 is an equivalent circuit diagram which shows the circuit diagram shown in FIG. 5 together with the monitor transistor according to a second modification example.

FIG. 35 is an equivalent circuit diagram which shows the circuit diagram shown in FIG. 5 together with the monitor transistor according to a third modification example.

### DETAILED DESCRIPTION OF THE PREFERRED EMBODIMENTS

Hereinafter, a detailed description of the embodiments shall be given. The attached drawings are not drawn precisely but are schematic views and are not necessarily matched in scale, etc. In addition, the same reference signs are given to corresponding structures in the attached drawings and redundant descriptions shall be omitted or simplified.

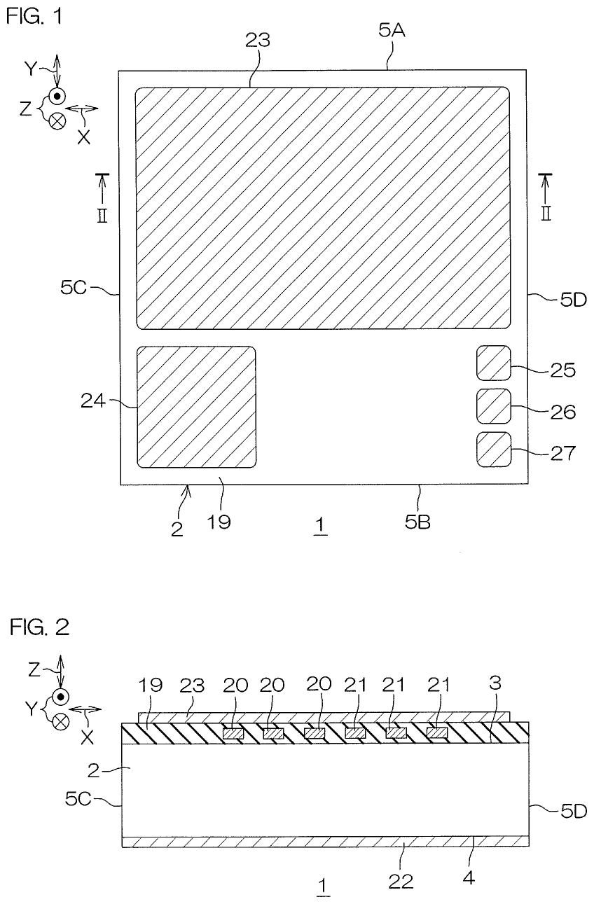

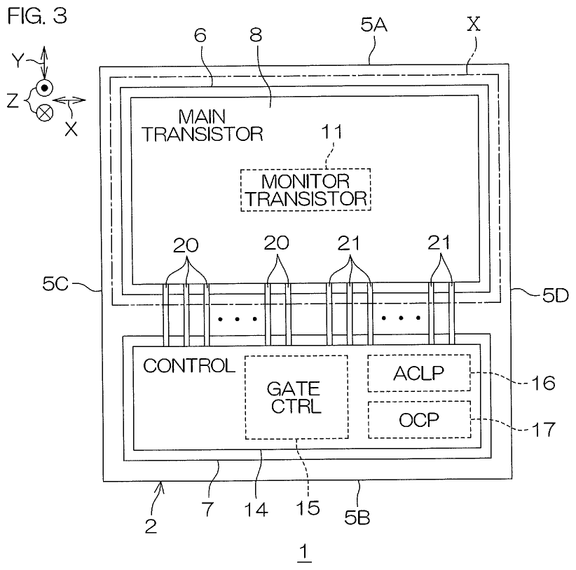

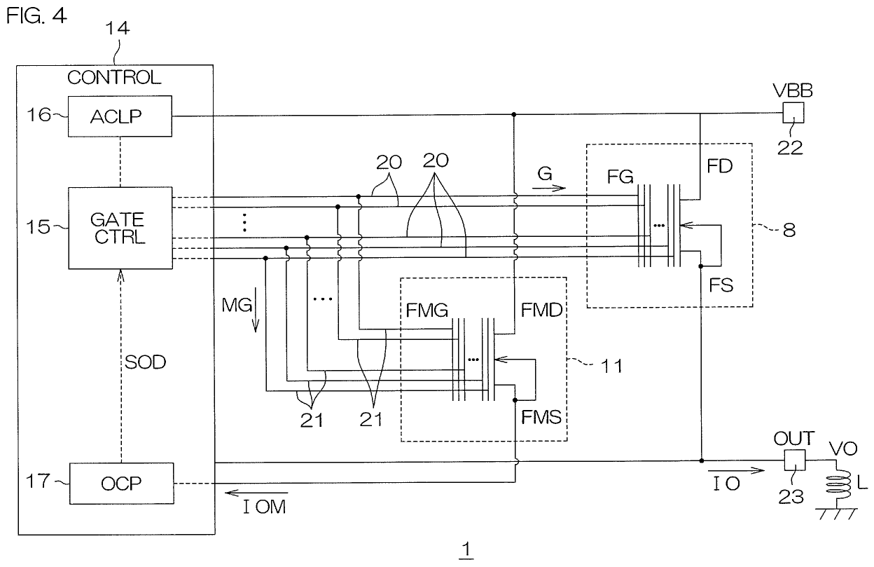

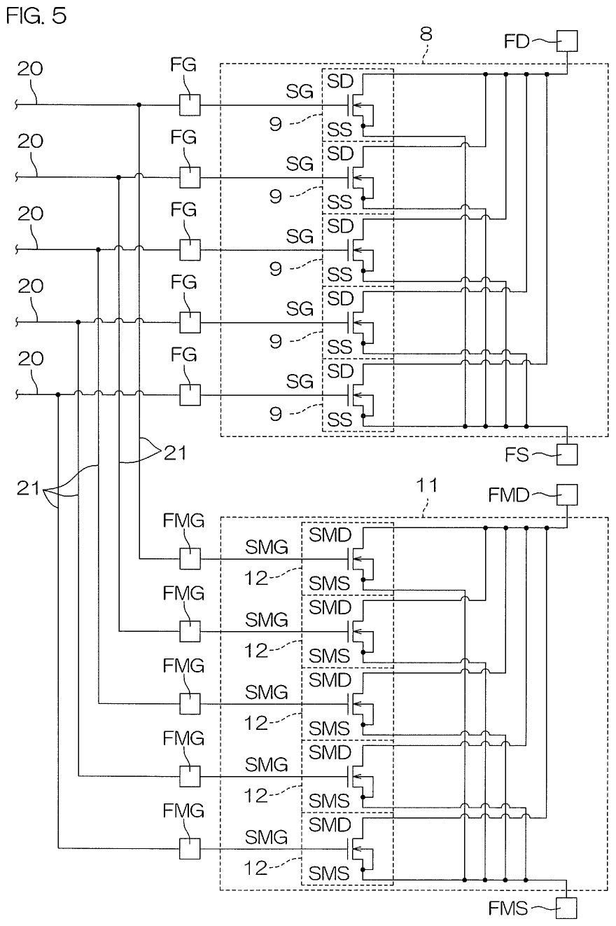

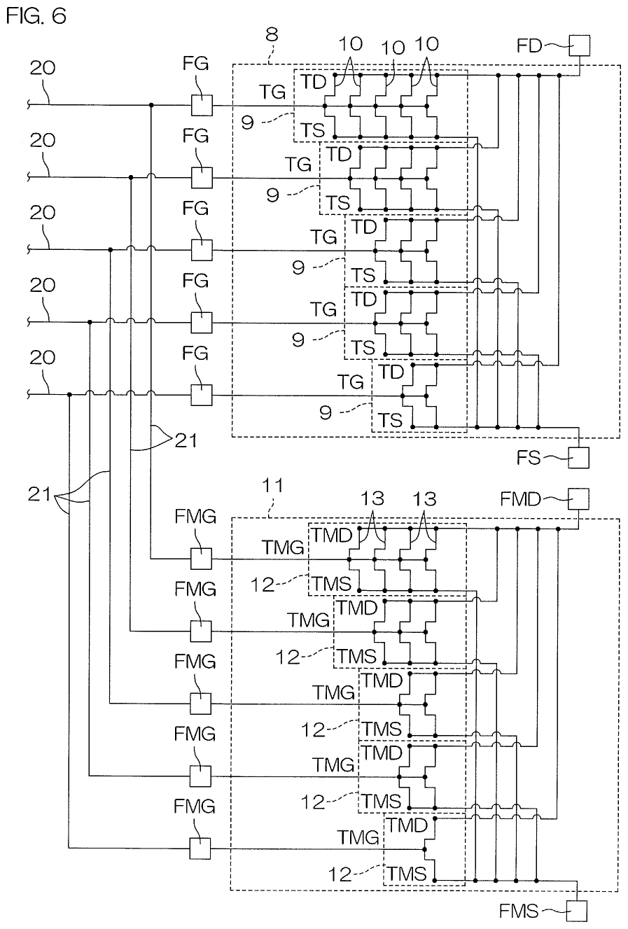

FIG. 1 is a plan view which shows a semiconductor device 1 according to a first embodiment. FIG. 2 is a cross-sectional view taken along line II-II shown in FIG. 1. FIG. 3 is a plan view which shows a layout example inside a semiconductor chip 2 shown in FIG. 1. FIG. 4 is a block circuit diagram showing an electrical arrangement example of the semiconductor device 1 in FIG. 1. FIG. 5 is an equivalent circuit diagram of a main transistor 8 and a monitor transistor 11 shown in FIG. 4. FIG. 6 is another equivalent circuit diagram of the main transistor 8 and the monitor transistor 11 shown in FIG. 5. FIG. 4 shows an example where an inductive load L is externally connected to an output end.

With reference to FIG. 1 and FIG. 2, in this embodiment, the semiconductor device 1 includes the semiconductor chip 2 which is formed in a rectangular parallelepiped shape. The semiconductor chip 2 is constituted of a chip which includes Si (silicon). The semiconductor chip 2 may be constituted of a chip which includes an Si monocrystal or an SiC monocrystal. The semiconductor chip 2 has a first main surface 3 on one side, a second main surface 4 on the other side, and first to fourth side surfaces 5A to 5D which connect the first main surface 3 and the second main surface 4. The first main surface 3 and the second main surface 4 are formed in a quadrilateral shape in a plan view as viewed from a normal direction Z thereto (hereinafter, simply referred to as “plan view”).

The first main surface 3 is a device surface in which a functional device is formed. The second main surface 4 is a mounting surface and may be constituted of a ground surface having a ground mark. The first to fourth side surfaces 5A to 5D include a first side surface 5A, a second side surface 5B, a third side surface 5C, and a fourth side surface 5D. The first side surface 5A and the second side surface 5B extend in a first direction X along the first main surface 3 and oppose a second direction Y that intersects (specifically, orthogonal to) in the first direction X. The third side surface 5C and the fourth side surface 5D extend in the second direction Y and oppose the first direction X.

With reference to FIG. 3, the semiconductor device 1 includes a first device region 6 which is arranged in the first main surface 3. The first device region 6 is an output region in which an output signal that is output to the outside is generated. In this embodiment, the first device region 6 is demarcated in a region of the first main surface 3 on the first side surface 5A side. The first device region 6 may be demarcated in a quadrilateral shape or may be demarcated in a polygonal shape other than the quadrilateral shape in a plan view. The arrangement and planar shape of the first device region 6 are arbitrary and not restricted to a particular mode.

The semiconductor device 1 includes a second device region 7 which is arranged in a region of the first main surface 3 different from the first device region 6. The second device region 7 is an input region into which an electric signal from the outside is to be input. In this embodiment, the second device region 7 is demarcated in a region on the second side surface 5B side with respect to the first device region 6. The second device region 7 may be demarcated in a quadrilateral shape or may be demarcated in a polygonal shape other than the quadrilateral shape in a plan view. The arrangement and planar shape of the second device region 7 are arbitrary and not restricted to a particular mode.

The second device region 7 preferably has a planar area which is not more than a planar area of the first device region 6. The second device region 7 is preferably formed so as to have an area ratio of not less than 0.1 and not more than 1 with respect to the first device region 6. The area ratio is a ratio of the planar area of the second device region 7 to the planar area of the first device region 6. The area ratio is preferably less than 1. As a matter of course, the second device region 7 that has a planar area exceeding the planar area of the first device region 6 may be adopted.

With reference to FIG. 4, the semiconductor device 1 includes an n-system (n≥2) insulated gate type main transistor 8 which is formed in the first device region 6. The main transistor 8 may be referred to as a “gate divided transistor,” a “power transistor” or a “power MISFET (Metal Insulator Semiconductor Field Effect Transistor).” The main transistor 8 includes an n-number of first gates FG, one first drain FD, and one first source FS. The first gate FG, the first drain FD and the first source FS may be respectively referred to as a “main gate,” a “main drain” and a “main source.”

The same or different n-number of gate signals G (gate voltages) are to be input into the n-number of the first gates FG at arbitrary timings. Each gate signal G includes an on signal which controls a part of the main transistor 8 so as to be in an on state and an off signal which controls a part of the main transistor 8 so as to be in an off state. The main transistor 8 generates a single output current IO (output signal) in response to the n-number of the gate signals G and outputs it from the first drain FD and the first source FS. That is, the main transistor 8 is constituted of a multi-input/single-output type switching device. Specifically, the output current IO is a drain-source current which flows between the first drain FD and the first source FS. The output current IO is output to the outside of the first device region 6.

With reference to FIG. 5, the main transistor 8 includes an n-number of system transistors 9. The n-number of the system transistors 9 are formed to concentrate in the single first device region 6 and configured so as to be controlled in an on state and in an off state electrically independently of each other. Specifically, the n-number of the system transistors 9 are connected in parallel to each other so that the n-number of the gate signals G are to be individually input, thereby configuring one system parallel circuit (=main transistor 8). That is, the n-system main transistor 8 is configured so that the system transistor 9 in an on state coexists with the system transistor 9 in an off state at an arbitrary timing.

The n-number of the system transistors 9 each include a second gate SG, a second drain SD, and a second source SS. The second gate SG, the second drain SD, and the second source SS may be respectively referred to as a “system gate,” a “system drain,” and a “system source.” The n-number of the second gates SG are each connected to the n-number of the first gates FG in a one-to-one correspondence. The n-number of the second drains SD are each connected to one first drain FD. The n-number of the second sources SS are each connected to one first source FS.

That is, the n-number of the second gates SG, the n-number of the second drains SD and the n-number of the second sources SS of the n-number of the system transistors 9 respectively configure the n-number of the first gates FG, one first drain FD and one first source FS of the main transistor 8. The n-number of the first gates FG are substantially constituted of the n-number of the second gates SG.

The n-number of the system transistors 9 each generate a system current IS in response to the corresponding gate signal G and each output the system current IS from the first drain FD and the first source FS. Specifically, the n-number of the system currents IS are a drain-source current which flows between the second drain SD and the second source SS of each of the n-number of the system transistors 9. The n-number of the system currents IS may be values different from each other or may be values equal to each other. The n-number of the system currents IS are added between the first drain FD and the first source FS. Thereby, a single output current IO which is constituted of an added value of the n-number of the system currents IS is generated.

With reference to FIG. 6, the n-number of the system transistors 9 each include a single or a plurality of unit transistors 10 which are systematized (grouped) as an individually controlled object. In this embodiment, the plurality of unit transistors 10 are each constituted of a trench gate type. Specifically, the n-number of the system transistors 9 each have a unit parallel circuit which is constituted of the single or the plurality of unit transistors 10.

A case that the system transistor 9 is constituted of the single unit transistor 10 is also included in a “unit parallel circuit” described here. Although the number of the unit transistors 10 included in each system transistor 9 is arbitrary, at least one system transistor 9 preferably includes the plurality of unit transistors 10. The n-number of the system transistors 9 may be constituted of the same number or different numbers of the unit transistors 10.

Each unit transistor 10 includes a third gate TG, a third drain TD, and a third source TS. The third gate TG, the third drain TD, and the third source TS may be respectively referred to as a “unit gate,” a “unit drain” and a “unit source.” In each of the system transistors 9, all of the third gates TG of the single or the plurality of unit transistors 10 are electrically connected to the second gate SG, all of the third drains TD are electrically connected to the second drain SD, and all of the third sources TS are electrically connected to the second source SS. That is, the third gate TG, the third drain TD and the third source TS of the single or the plurality of unit transistors 10 which was systematized configure the second gate SG, the second drain SD and the second source SS of each system transistor 9, respectively.

Electrical characteristics of each system transistors 9 are adjusted according to electrical specifications of the main transistor 8 to be achieved. The electrical specifications of the main transistor 8 include, for example, a channel utilization rate, an on-resistance and a switching waveform, etc. Hereinafter, the term, “substantially equal” in this description includes a case that a value to be measured completely matches a value to be compared and also includes a case that a value to be measured is within a range of not less than 0.9 times and not more than 1.1 times a value to be compared.

The n-number of the system transistors 9 may have a substantially equal gate threshold voltage or may have different gate threshold voltages. The n-number of the system transistors 9 may have a channel area that is substantially equal or may have a channel area that is different for each unit area. That is, the n-number of the system transistors 9 may have substantially similar on-resistance characteristics or may have different on-resistance characteristics.

The plurality of unit transistors 10 may have a substantially equal gate threshold voltage or may have different gate threshold voltages. The plurality of unit transistors 10 may have a substantially equal channel area or may have a different channel area for each unit area. That is, the plurality of unit transistors 10 may have substantially similar on-resistance characteristics or may have different on-resistance characteristics. Electrical characteristics of each system transistor 9 are precisely adjusted by adjusting the number of the plurality of unit transistors 10, a gate threshold voltage, a channel area, etc.

With reference to FIG. 4, the semiconductor device 1 includes an m-system (m≥1) insulated gate type monitor transistor 11 which is formed in the first device region 6. That is, the monitor transistor 11 is formed so as to concentrate in the single first device region 6 together with the main transistor 8. In this embodiment, the monitor transistor 11 is formed in an inner portion (preferably at a central portion) of the first device region 6 at an interval from a peripheral edge of the first device region 6 and arranged so as to be mutually adjacent to the main transistor 8. In this embodiment, the monitor transistor 11 is formed in a region surrounded by the main transistor 8.

The monitor transistor 11 may be configured so as to be connected in parallel to at least one system transistor 9 and monitor at least one system current IS. The monitor transistor 11 is preferably constituted of the m-system (m≥2) monitor transistor 11 which is configured so as to be connected in parallel to the plurality of system transistors 9 and monitor the plurality of system currents IS.

In this embodiment, the monitor transistor 11 is constituted of the n-system (m=n) monitor transistor 11 which is configured so as to be connected in parallel to the n-number of the system transistors 9 and monitor the n-number of the system currents IS. Hereinafter, a description of a configuration of the monitor transistor 11 shall be given by replacing the “m-system” or the “m-number” by the “n-system” or the “n-number,” whenever necessary.

In this embodiment, the monitor transistor 11 includes the n-number of first monitor gates FMG, one first monitor drain FMD and one first monitor source FMS. The first monitor gate FMG, the first monitor drain FMD and the first monitor source FMS may be respectively referred to as a “main monitor gate,” a “main monitor drain” and a “main monitor source.”

The n-number of the first monitor gates FMG are configured so that an n-number of monitor gate signals MG are to be individually input. The first monitor drain FMD is electrically connected to the first drain FD. The first monitor source FMS is electrically separated from the first source FS. The n-number of the monitor gate signals MG (monitor gate voltages) which are the same or different are to be input into the n-number of the first monitor gates FMG at arbitrary timings. Each monitor gate signal MG includes an on signal which controls a part of the monitor transistor 11 so as to be in an on state and an off signal which controls a part of the monitor transistor 11 so as to be in an off state.

In this embodiment, the monitor transistor 11 generates a single output monitor current IOM (output monitor signal) which monitors the n-number of the system currents IS (output currents IO) in response to the n-number of the monitor gate signals MG and outputs it from the first monitor drain FMD and the first monitor source FMS. That is, in this embodiment, the monitor transistor 11 is constituted of a multi-input/single-output type switching device. Specifically, the output monitor current IOM is a drain-source current which flows between the first monitor drain FMD and the first monitor source FMS.

In this embodiment, the n-number of the first monitor gates FMG are each electrically connected to the n-number of the first gates FG in a one-to-one correspondence. Therefore, the n-number of the first monitor gates FMG are configured so that each monitor gate signal MG constituted of the gate signal G are to be individually input. That is, the monitor transistor 11 is subjected to on/off control at the same timing with the n-number of the system transistors 9 and generates the output monitor current IOM which is increased or decreased in conjunction with an increase or a decrease in output current IO. The output monitor current IOM is output to a current path which is electrically independent of a current path of the output current IO. The output monitor current IOM is electrically independent of the output current IO and output to the outside of the first device region 6.

The output monitor current IOM is not more than the output current IO (IOM≤IO). The output monitor current IOM is preferably less than the output current IO (IOM<IO). The output monitor current IOM is preferably proportional to the output current IO. A current ratio IOM/IO of the output monitor current IOM to the output current IO is arbitrary. The current ratio IOM/IO may be not less than 1/10000 and not more than 1 (preferably, less than 1).

With reference to FIG. 5, the monitor transistor 11 includes an m-number (in this embodiment, an n-number) of system monitor transistors 12. The number of the systems of the monitor transistor 11 is adjusted by the number of the system monitor transistors 12. That is, where the m-system (m≥1) monitor transistor 11 monitors at least one system current IS, at least one system monitor transistor 12 is electrically connected (specifically, connected in parallel) to at least one system transistor 9. Also, where the m-system (m≥2) monitor transistor 11 monitors the plurality of system currents IS, the plurality of system monitor transistors 12 are electrically connected to the plurality of system transistors 9. In this embodiment, the n-number of the system monitor transistors 12 are electrically connected to the n-number of the system transistors 9.

The n-number of the system monitor transistors 12 are formed to concentrate in the single first device region 6 and configured so as to be controlled in an on state and in an off state electrically independently of each other. Specifically, the n-number of the system monitor transistors 12 are connected in parallel to each other so that the n-number of the monitor gate signals MG are to be individually input, thereby configuring one system monitor parallel circuit (=monitor transistor 11). That is, the monitor transistor 11 is configured so that the system monitor transistor 12 in an on state coexists with the system monitor transistor 12 in an off state at an arbitrary timing.

The n-number of the system monitor transistors 12 each include a second monitor gate SMG, a second monitor drain SMD and a second monitor source SMS. The second monitor gate SMG, the second monitor drain SMD and the second monitor source SMS may be respectively referred to as a “system monitor gate,” a “system monitor drain” and a “system monitor source.” The n-number of the second monitor gates SMG are each connected to the n-number of the first monitor gates FMG in a one-to-one correspondence. The n-number of the second monitor drains SMD are each connected to one first monitor drain FMD. The n-number of the second monitor sources SMS are each connected to one first monitor source FMS.

The n-number of the second monitor gates SMG, the n-number of the second monitor drains SMD and the n-number of the second monitor sources SMS of the n-number of the system monitor transistors 12 configure the n-number of the first monitor gates FMG, one first monitor drain FMD and one first monitor source FMS of the monitor transistor 11, respectively. The n-number of the first monitor gates FMG are substantially constituted of the n-number of the second monitor gates SMG.

The n-number of the monitor gate signals MG which are the same or different are to be input into the n-number of the second monitor gates SMG at arbitrary timings. The n-number of the system monitor transistors 12 each generate the system monitor current ISM (system monitor signal) for monitoring the system current IS of the corresponding system transistor 9 in response to the corresponding monitor gate signal MG and each output it from the second monitor drain SMD and the second monitor source SMS.

Specifically, each system monitor current ISM is a drain-source current which flows between the second monitor drain SMD and the second monitor source SMS of each of the system monitor transistors 12. The n-number of the system monitor currents ISM are added between the first monitor drain FMD and the first monitor source FMS. Thereby, the single output monitor current IOM constituted of an added value of the n-number of the system monitor currents ISM is generated.

In this embodiment, the n-number of the system monitor transistors 12 are each configured so as to be electrically connected to the corresponding system transistor 9 in a one-to-one correspondence and controlled in conjunction with the corresponding system transistor 9. Specifically, the n-number of the system monitor transistors 12 are each connected in parallel to the corresponding system transistor 9 so that the system monitor current ISM is to be output to a current path electrically independent of a current path of the system current IS. The n-number of the second monitor gates SMG are each electrically connected to the corresponding first gate FG in a one-to-one correspondence. The second monitor drain SMD is electrically connected to the first drain FD. The second monitor source SMS is electrically separated from the first source FS.

That is, in this embodiment, the monitor gate signal MG constituted of the gate signal G is to be input into each of the n-number of the second monitor gates SMG. Thereby, the n-number of the system monitor transistors 12 are subjected to on/off control at the same timing with the corresponding system transistors 9 and each generate the system monitor current ISM which is increased or decreased in conjunction with an increase or a decrease in the corresponding system current IS. The system monitor current ISM is electrically independent of the system current IS and taken out from the second monitor drain SMD and the second monitor source SMS.

Each system monitor current ISM is not more than the corresponding system current IS (ISM≤IS). Each system monitor current ISM is preferably less than the corresponding system current IS (ISM<IS). Each system monitor current ISM is preferably proportional to the corresponding system current IS. A current ratio ISM/IS of the system monitor current ISM to the system current IS is arbitrary. The current ratio ISM/IS may be not less than 1/10000 and not more than 1 (preferably, less than 1).

With reference to FIG. 6, the n-number of the system monitor transistors 12 each include a single or a plurality of unit monitor transistors 13 which are systematized (grouped) as an individually controlled object. In this embodiment, the plurality of unit monitor transistors 13 are each constituted of a trench gate type. Specifically, the n-number of the system monitor transistors 12 each have a unit monitor parallel circuit which is constituted of the single or the plurality of unit monitor transistors 13.

A case that the system monitor transistor 12 is constituted of the single unit monitor transistor 13 is also included in the “unit monitor parallel circuit” described here. The number of the unit monitor transistors 13 included in each system monitor transistor 12 is arbitrary. The n-number of the system monitor transistors 12 may be constituted of the same number or different numbers of the unit monitor transistors 13. The number of the unit monitor transistors 13 included in each system monitor transistor 12 is preferably less than the number of the unit transistors 10 included in the corresponding system transistor 9. In this case, it is possible to easily generate the system monitor current ISM which is not more than the system current IS.

Each unit monitor transistor 13 includes a third monitor gate TMG, a third monitor drain TMD and a third monitor source TMS. The third monitor gate TMG, the third monitor drain TMD and the third monitor source TMS may be respectively referred to as a “unit monitor gate,” a “unit monitor drain” and a “unit monitor source.” In each of the system monitor transistors 12, all of the third monitor gates TMG of the single or the plurality of unit monitor transistors 13 are electrically connected to the second monitor gate SMG, all of the third monitor drains TMD are electrically connected to the second monitor drain SMD, and all of the third monitor sources TMS are electrically connected to the second monitor source SMS.

That is, the third monitor gate TMG, the third monitor drain TMD and the third monitor source TMS of the single or the plurality of unit monitor transistors 13 which was systematized respectively configure the second monitor gate SMG, the second monitor drain SMD and the second monitor source SMS of each of the system monitor transistors 12.

Electrical characteristics of the n-number of the system monitor transistors 12 are adjusted according to electrical specifications of the monitor transistor 11 to be achieved. The electrical specifications of the monitor transistor 11 include, for example, a channel utilization rate, an on-resistance and a switching waveform, etc. The n-number of the system monitor transistors 12 may have a substantially equal gate threshold voltage or may have different gate threshold voltages. The n-number of the system monitor transistors 12 may have a substantially equal channel area or may have a different channel area for each unit area.

That is, the n-number of the system monitor transistors 12 may have substantially similar on-resistance characteristics or may have different on-resistance characteristics. The gate threshold voltage, the channel area, the on-resistance characteristics, etc., of the n-number of the system monitor transistors 12 may be substantially equal or similar to or may be different from the gate threshold voltage, the channel area, the on-resistance characteristics, etc., of the corresponding system transistor 9.

The plurality of unit monitor transistors 13 may have a substantially equal gate threshold voltage or may have different gate threshold voltages. The plurality of unit monitor transistors 13 may have a substantially equal channel area or may have a different channel area for each unit area. That is, the plurality of unit monitor transistors 13 may have substantially similar on-resistance characteristics or may have different on-resistance characteristics.

The gate threshold voltage, the channel area, the on-resistance characteristics, etc., of the unit monitor transistor 13 included in each system monitor transistor 12 may be substantially equal or similar to or may be different from the gate threshold voltage, the channel area, the on-resistance characteristics, etc., of the unit transistor 10 included in the corresponding system transistor 9. The channel area of the unit monitor transistor 13 included in each system monitor transistor 12 is preferably less than the channel area of the unit transistor 10 included in the corresponding system transistor 9. Electrical characteristics of each system monitor transistor 12 are precisely adjusted by adjusting the number of the plurality of unit monitor transistors 13, the gate threshold voltage, the channel area, etc.

With reference to FIG. 3 and FIG. 4, the semiconductor device 1 includes a control IC 14 (Control Integrated Circuit) as an example of a control circuit which is formed in the second device region 7. The control IC 14 configures an IPD (Intelligent Power Device) together with the main transistor 8 and the monitor transistor 11. The IPD may be referred to as an “IPM (Intelligent Power Module).”

The control IC 14 includes multiple types of functional circuits which realize various functions in response to an electric signal input from the outside. The multiple types of functional circuits include a gate control circuit 15, an active clamp circuit 16 and an overcurrent protection circuit 17. The overcurrent protection circuit 17 may be referred to as an “OCP (Over Current Protection) circuit.” Although not shown, the control IC 14 may include multiple types of abnormality detection circuits which detect abnormalities (for example, overvoltage, overheating, etc.) of the main transistor 8, the monitor transistor 11, the functional circuit, etc. The gate control circuit 15 is electrically connected to the first gate FG of the main transistor 8 and the first monitor gate FMG of the monitor transistor 11 and drives and controls the main transistor 8 and the monitor transistor 11 in response to an electric signal from the outside.

Specifically, the gate control circuit 15 is configured so as to be electrically connected to the n-number of the first gates FG of the main transistor 8 (second gates SG of n-number of the system transistors 9) and individually control the n-number of the first gates FG (n-number of system transistors 9). Further, the gate control circuit 15 is configured so as to be electrically connected to the n-number of the first monitor gates FMG of the monitor transistor 11 (n-number of the second monitor gates SMG) and individually control the n-number of the first monitor gates FMG (n-number of the system monitor transistors 12). In this embodiment, the n-number of the first monitor gates FMG (n-number of the second monitor gates SMG) of the monitor transistor 11 are each electrically connected to the corresponding first gate FG. Therefore, the gate control circuit 15 individually controls the n-number of the first monitor gates FMG so as to work with the n-number of the first gates FG.

The active clamp circuit 16 is electrically connected to the main transistor 8 and the gate control circuit 15. The active clamp circuit 16 is configured so as to protect the main transistor 8 from a back electromotive force by restricting (clamping) an output voltage VO when the back electromotive force is to be input into the main transistor 8 due to an energy accumulated in the inductive load L. That is, the active clamp circuit 16 restricts the output voltage VO until the back electromotive force is consumed by making the main transistor 8 perform an active clamp operation when the back electromotive force is to be input.

Specifically, the active clamp circuit 16 is electrically connected to the first gate FG and the first drain FD which are a part (not all) of the main transistor 8. The active clamp circuit 16 controls some of the system transistors 9 so as to be in an on state and controls the rest of the system transistors 9 so as to be in an off state during an active clamp operation. That is, the active clamp circuit 16 raises an on-resistance of the main transistor 8 during the active clamp operation and protects the main transistor 8 from the back electromotive force.

Further, the active clamp circuit 16 is electrically connected to the monitor transistor 11 and the gate control circuit 15. The active clamp circuit 16 is configured so as to protect the monitor transistor 11 from a back electromotive force by restricting (clamping) the output voltage VO when the back electromotive force is to be input into the monitor transistor 11 due to an energy accumulated in the inductive load L. That is, the active clamp circuit 16 restricts the output voltage VO until the back electromotive force is consumed by making the monitor transistor 11 perform an active clamp operation when the back electromotive force is to be input.

Specifically, the active clamp circuit 16 is electrically connected to the first monitor gate FMG and the first monitor drain FMD which are a part (not all) of the monitor transistor 11. The active clamp circuit 16 controls some of the system monitor transistors 12 so as to be in an on state and controls the rest of the system monitor transistors 12 so as to be in an off state during the active clamp operation.

Specifically, the active clamp circuit 16 performs on/off control of the n-system monitor transistor 11 so as to work with an on/off state of the n-system main transistor 8 during the active clamp operation. More specifically, the active clamp circuit 16 controls the system monitor transistor 12 corresponding to the on-state system transistor 9 so as to be in an on state and controls the system monitor transistor 12 corresponding to the off-state system transistor 9 so as to be in an off state during the active clamp operation.

That is, the active clamp circuit 16 raises an on-resistance of the monitor transistor 11 during the active clamp operation and protects the monitor transistor 11 from a back electromotive force. The active clamp circuit 16 may be configured so that when the first source FS of the main transistor 8 is at a voltage not more than a predetermined voltage (for example, a predetermined negative voltage), on/off control of the n-number of the system transistors 9 is performed and on/off control of the n-number of the system monitor transistors 12 is performed.

The overcurrent protection circuit 17 is electrically connected to the monitor transistor 11 and the gate control circuit 15. The overcurrent protection circuit 17 is configured so as to be electrically connected to the first monitor source FMS of the monitor transistor 11 and obtain a part or all (in this embodiment, all) of the output monitor current IOM. The overcurrent protection circuit 17 is configured so as to protect the main transistor 8 from an overcurrent by controlling the gate signal G generated by the gate control circuit 15 in response to the output monitor current IOM and restricting the output current IO to a value not more than a predetermined value.

The overcurrent protection circuit 17 may be configured so as to obtain at least one of the plurality of system monitor currents ISM. Of the output monitor current IOM (plurality of system monitor currents ISM), a current which is to be input into the overcurrent protection circuit 17 is regulated by branching or not branching the output monitor current IOM (plurality of system monitor currents ISM) according to a circuit configuration of the control IC 14. The overcurrent protection circuit 17 indirectly monitors the output current IO by the output monitor current IOM.

The overcurrent protection circuit 17 may be configured so as to generate an overcurrent detecting signal SOD and output the overcurrent detecting signal SOD to the gate control circuit 15 when the output monitor current IOM exceeds a predetermined threshold. The overcurrent detecting signal SOD is a signal for restricting some of or all of the n-number of the gate signals G generated in the gate control circuit 15 to a value not more than a predetermined value (for example, off). The gate control circuit 15 restricts some of or all of the n-number of the gate signals G in response to the overcurrent detecting signal SOD and suppresses an overcurrent that flows through the main transistor 8. When the output monitor current IOM is at a value not more than a predetermined threshold, the overcurrent protection circuit 17 stops generation of the overcurrent detecting signal SOD and shifts the gate control circuit 15 (main transistor 8) to normal control.

The above-described configuration (operation) of the overcurrent protection circuit 17 is merely an example. The overcurrent protection circuit 17 is able to have a variety of current voltage characteristics and a variety of operation methods. The overcurrent protection circuit 17 may have a circuit configuration including at least one current/voltage characteristics among constant current/voltage dropping type characteristics, foldback current limiting characteristics and constant power control voltage dropping type characteristics. The overcurrent protection circuit 17 may have a circuit configuration including an automatic recovery type or a latch type (shutdown type with no automatic recovery) operation method.

With reference to FIG. 2, the semiconductor device 1 includes an interlayer insulating layer 19 which covers the first main surface 3. The interlayer insulating layer 19 collectively covers the first device region 6 and the second device region 7. In this embodiment, the interlayer insulating layer 19 is constituted of a multi-layer wiring structure having a laminated structure in which a plurality of insulating layers and a plurality of wiring layers are alternately laminated. Each of the insulating layers includes at least one of a silicon oxide film and a silicon nitride film. Each of the wiring layers may include at least one among a pure Al layer (Al layer with purity of not less than 99%), a Cu layer (Cu layer with purity of not less than 99%), an AlCu alloy layer, an AlSiCu alloy layer and an AlSi alloy layer.

With reference to FIG. 2 to FIG. 6, the semiconductor device 1 includes an n-number of main gate wirings 20 as an example of a control wiring arranged anywhere above the first main surface 3. The n-number of the main gate wirings 20 are constituted of the n-number of wiring layers selectively routed inside the interlayer insulating layer 19. The n-number of the main gate wirings 20 are electrically connected to the n-number of the first gates FG of the main transistor 8 in a one-to-one correspondence in a state electrically independent of each other in the first device region 6. The n-number of the main gate wirings 20 are each electrically connected to the control IC 14 (gate control circuit 15) in the second device region 7. The n-number of the main gate wirings 20 individually transmit the n-number of the gate signals G generated by the control IC 14 (gate control circuit 15) to the n-number of the first gates FG of the main transistor 8.

The n-number of the main gate wirings 20 are each electrically connected to the third gate TG of one or the plurality of unit transistors 10 which are to be systematized as an individually controlled object from an assembly constituted of the plurality of unit transistors 10. The n-number of the main gate wirings 20 may include one or the plurality of main gate wirings 20 electrically connected to one unit transistor 10 which is to be systematized as an individually controlled object. Also, the n-number of the main gate wirings 20 may include one or the plurality of main gate wirings 20 which connect in parallel the plurality of unit transistors 10 which are to be systematized as an individually controlled object.

The semiconductor device 1 includes an n-number of monitor gate wirings 21 as an example of a monitor control wiring that is arranged anywhere above the first main surface 3. The n-number of the monitor gate wirings 21 are constituted of the n-number of wiring layers selectively routed inside the interlayer insulating layer 19. The n-number of the monitor gate wirings 21 are electrically connected to the n-number of the first monitor gates FMG of the monitor transistor 11 in a one-to-one correspondence in a state electrically independent of each other in the first device region 6. The n-number of the monitor gate wirings 21 are each electrically connected to the control IC 14 (gate control circuit 15) in the second device region 7. The n-number of the monitor gate wirings 21 individually transmit the n-number of the monitor gate signals MG generated by the control IC 14 (gate control circuit 15) to the n-number of the first monitor gates FMG of the monitor transistor 11.

The n-number of the monitor gate wirings 21 are each electrically connected to the third monitor gate TMG of one or the plurality of unit monitor transistors 13 which are to be systematized as an individually controlled object from an assembly constituted of the plurality of unit monitor transistors 13. The n-number of the monitor gate wirings 21 may include one or the plurality of monitor gate wirings 21 electrically connected to one unit monitor transistor 13 which is to be systematized as an individually controlled object. Also, the n-number of the monitor gate wirings 21 may include one or the plurality of monitor gate wirings 21 which connect in parallel the plurality of unit monitor transistors 13 which are to be systematized as an individually controlled object.

In this embodiment, the n-number of the monitor gate wirings 21 are each electrically connected to the corresponding main gate wiring 20 in a one-to-one correspondence. The n-number of the monitor gate wirings 21 may be each integrally formed with the corresponding main gate wiring 20. The n-number of the monitor gate wirings 21 are each electrically connected to the control IC 14 (gate control circuit 15) via the corresponding main gate wiring 20. The n-number of the monitor gate wirings 21 individually transmit the n-number of the gate signals G (n-number of the monitor gate signals MG) generated by the control IC 14 (gate control circuit 15) to the n-number of the first monitor gates FMG of the monitor transistor 11.

With reference to FIG. 1 and FIG. 2, the semiconductor device 1 includes a plurality of terminal electrodes 22 to 27. In FIG. 1, the plurality of terminal electrodes 22 to 27 are indicated by hatching. The number, the arrangement and planar shape of the plurality of terminal electrodes 22 to 27 are adjusted to an arbitrary mode according to specifications of the main transistor 8 and specifications of the control IC 14 and not limited to a mode shown in FIG. 1. In this embodiment, the plurality of terminal electrodes 22 to 27 include a drain terminal 22 (power terminal VBB), a source terminal 23 (output terminal OUT), an input terminal 24, a ground terminal 25, an enable terminal 26 and a sense terminal 27.

The drain terminal 22 is electrically connected to the first drain FD of the main transistor 8, the first monitor drain FMD of the monitor transistor 11, and the control IC 14. The drain terminal 22 transmits a power voltage VB to various circuits such as the first drain FD of the main transistor 8, the first monitor drain FMD of the monitor transistor 11, and the control IC 14. The source terminal 23 is electrically connected to the first source FS of the main transistor 8, and the control IC 14. The source terminal 23 transmits to the outside the output current IO generated by the main transistor 8.

The input terminal 24 transmits an input voltage which drives the control IC 14. The ground terminal 25 transmits a ground voltage GND. The enable terminal 26 transmits an electric signal for enabling or disabling some of or all of functions of the control IC 14. The sense terminal 27 transmits an electric signal for detecting abnormalities of the main transistor 8, the monitor transistor 11, the control IC 14, etc.

The drain terminal 22 directly covers the second main surface 4 of the semiconductor chip 2 and is electrically connected to the second main surface 4. The drain terminal 22 may include at least one among a Ti layer, an Ni layer, an Au layer, an Ag layer and an Al layer. The drain terminal 22 may have a laminated structure in which at least two of the Ti layer, the Ni layer, the Au layer, the Ag layer and the Al layer are laminated in an arbitrary mode.

The source terminal 23, the input terminal 24, the ground terminal 25, the enable terminal 26 and the sense terminal 27 are arranged on the interlayer insulating layer 19. The source terminal 23 is formed above the first device region 6 in the first main surface 3. The input terminal 24, the ground terminal 25, the enable terminal 26 and the sense terminal 27 are each arranged above a region of the first main surface 3 outside the first device region 6 (specifically, the second device region 7). The terminal electrodes 23 to 27 may include at least one among a pure Al layer, a pure Cu layer, an AlCu alloy layer, an AlSiCu alloy layer and an AlSi alloy layer. A plated layer may be formed on an outer surface of each of the terminal electrodes 23 to 27. The plated layer may include at least one among an Ni layer, a Pd layer and an Au layer.

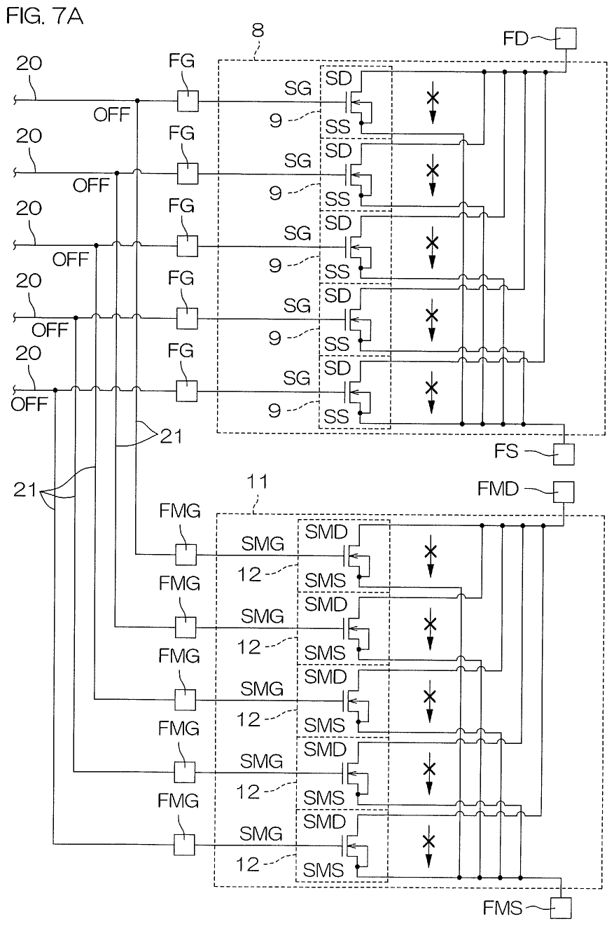

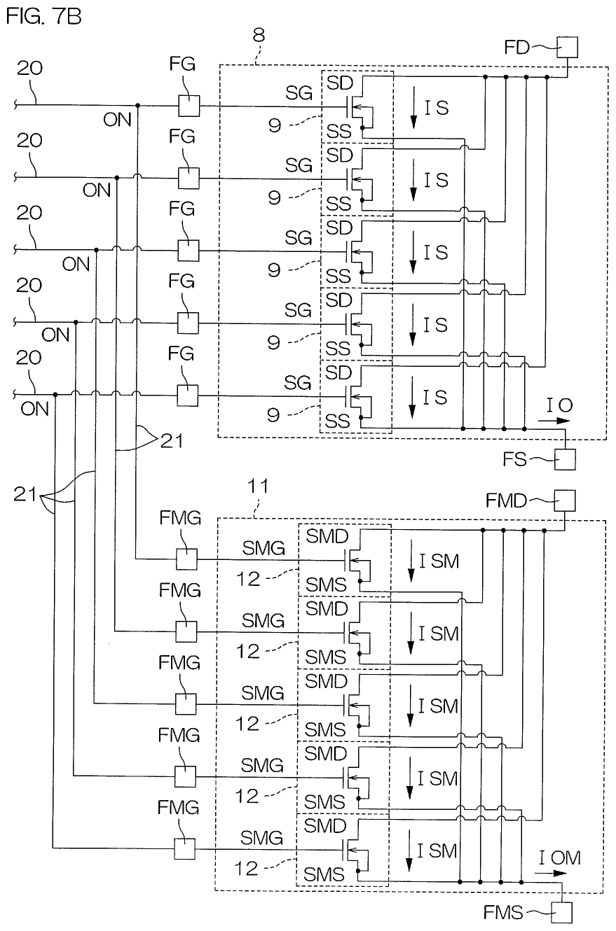

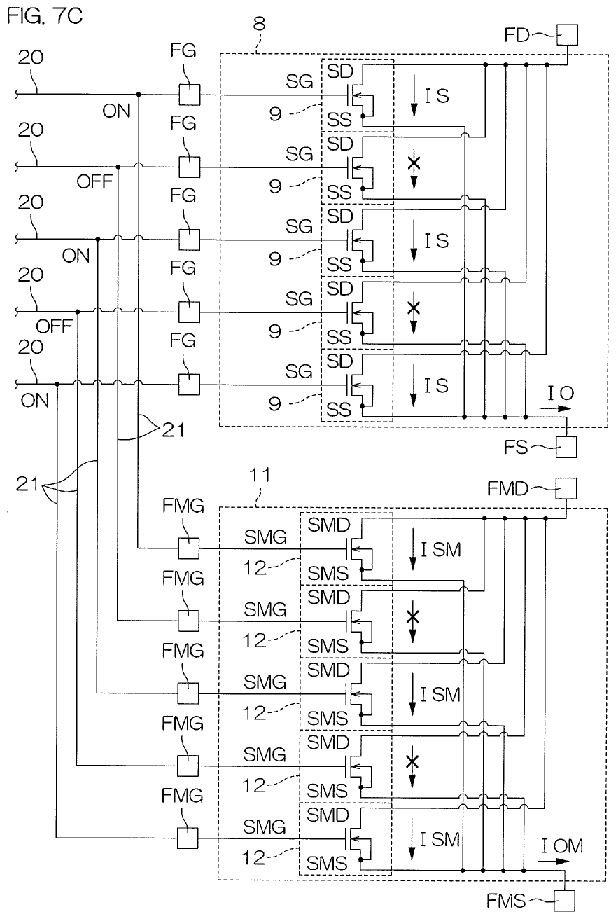

FIG. 7A to FIG. 7C each correspond to FIG. 5 and are a circuit diagram for describing operation examples of the main transistor 8 and the monitor transistor 11. With reference to FIG. 7A, the gate signal G (that is, off signal) less than the gate threshold voltage is input into all of the n-number of the main gate wirings 20. This control is to be applied during an off operation of the main transistor 8. Thereby, in the main transistor 8, as a result of all of the system transistors 9 being turned into an off state, the main transistor 8 is turned into an off state. In the monitor transistor 11, the n-number of the system monitor transistors 12 are turned into an off state in conjunction with the n-number of the system transistors 9. Thereby, the monitor transistor 11 is turned into an off state in conjunction with the main transistor 8.

With reference to FIG. 7B, the gate signal G which is not less than the gate threshold voltage (that is, on signal) is input into all of the n-number of the main gate wirings 20. This control is to be applied during a normal operation of the main transistor 8. Thereby, as a result of the n-number of the system transistors 9 being turned into an on state, the main transistor 8 is turned into an on state. The main transistor 8 generates the output current IO including the n-number of the system currents IS generated by the n-number of the system transistors 9. In this case, the main transistor 8 is relatively increased in channel utilization rate and relatively decreased in on-resistance.

In the monitor transistor 11, the n-number of the system monitor transistors 12 are turned into an on state in conjunction with the n-number of the system transistors 9. Thereby, the monitor transistor 11 is turned into an on state in conjunction with the main transistor 8. The monitor transistor 11 generates the output monitor current IOM which includes the n-number of the system monitor currents ISM generated by the n-number of the system monitor transistors 12 and monitors the output current IO. In this case, the monitor transistor 11 is relatively increased in channel utilization rate and relatively decreased in on-resistance.

With reference to FIG. 7C, the gate signal G which is not less than the gate threshold voltage (that is, on signal) is input into an x-number (1≤x<n) of the main gate wirings 20, and the gate signal G which is less than the gate threshold voltage (that is, off signal) is to be input into the (n-x)-number of the main gate wirings 20. This control is to be applied during an active clamp operation of the main transistor 8. Thereby, as a result of the x-number of the system transistors 9 being turned into an on state and the (n-x)-number of the system transistors 9 being turned into an off state, the main transistor 8 is turned into an on state in such a state that some of the current paths are made conductive and some of the current paths are blocked.

The main transistor 8 generates the output current IO including the x-number of the system currents IS generated by the x-number of the system transistors 9. In other words, the main transistor 8 generates the output current IO including the x-number of the system currents IS constituted of an absolute value exceeding 0 A and the (n-x)-number of the system currents IS constituted of 0 A. In this case, the main transistor 8 is relatively decreased in channel utilization rate and relatively increased in on-resistance.

In the monitor transistor 11, the x-number of the system monitor transistors 12 are turned into an on state in conjunction with the x-number of the system transistors 9, and the (n-x)-number of the system monitor transistors 12 are turned into an off state in conjunction with the (n-x)-number of the system transistors 9. Thereby, the monitor transistor 11 is turned into an on state in conjunction with the main transistor 8 in such a state that some of the current paths are made conductive and some of the current paths are blocked.

The monitor transistor 11 generates the output monitor current IOM which includes the x-number of the system monitor currents ISM generated by the x-number of the system monitor transistors 12 and monitors the output current IO. In other words, the monitor transistor 11 generates the output monitor current IOM including the x-number of the system monitor currents ISM constituted of an absolute value exceeding 0 A and the (n-x)-number of the system monitor currents ISM constituted of 0 A. In this case, the monitor transistor 11 is relatively decreased in channel utilization rate and relatively increased in on-resistance.

In FIG. 7A to FIG. 7C, some of or all (in this embodiment, all) of the output monitor currents IOM generated by the monitor transistor 11 are to be input into the overcurrent protection circuit 17 (see FIG. 4). When the output monitor current IOM exceeds a predetermined threshold, the overcurrent protection circuit 17 generates the overcurrent detecting signal SOD and outputs the overcurrent detecting signal SOD to the gate control circuit 15. The gate control circuit 15 limits some of or all of the n-number of the gate signals G in response to the overcurrent detecting signal SOD and limits some of or all of the n-number of the system currents IS generated by the n-number of the system transistors 9. When the output monitor current IOM is at a value not more than a predetermined threshold, the overcurrent protection circuit 17 stops generation of the overcurrent detecting signal SOD and shifts the gate control circuit 15 (main transistor 8) to normal control.

As described above, in the semiconductor device 1, the n-system main transistor 8 is configured so that an on-resistance (channel utilization rate) is changed by individually controlling the n-number of the system transistors 9. Specifically, the main transistor 8 is controlled so that an on-resistance during an active clamp operation is made different from an on-resistance during a normal operation by individually controlling the n-number of the system transistors 9. More specifically, the main transistor 8 is controlled so that an on-resistance during the active clamp operation exceeds an on-resistance during the normal operation by individually controlling the n-number of the system transistors 9.

On the other hand, the monitor transistor 11 is configured so as to be changed in on-resistance (channel utilization rate) by individually controlling the m-number (in this embodiment, m=n) of the system monitor transistors 12. Specifically, the monitor transistor 11 is configured so as to be changed in on-resistance in conjunction with the main transistor 8. Specifically, the monitor transistor 11 is controlled so that an on-resistance during an active clamp operation is made different from an on-resistance during a normal operation in conjunction with the main transistor 8. More specifically, the monitor transistor 11 is controlled so that an on-resistance during the active clamp operation exceeds an on-resistance during the normal operation in conjunction with the main transistor 8.

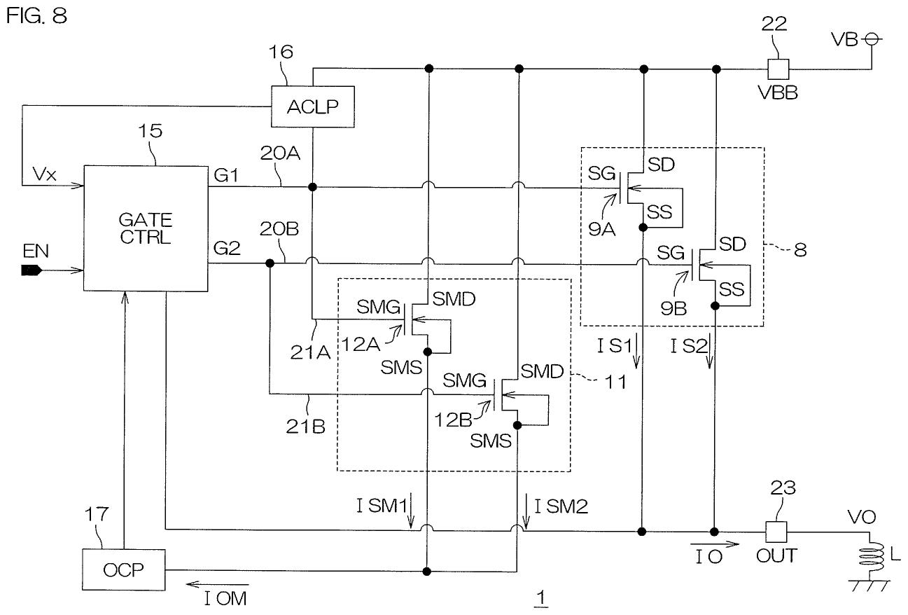

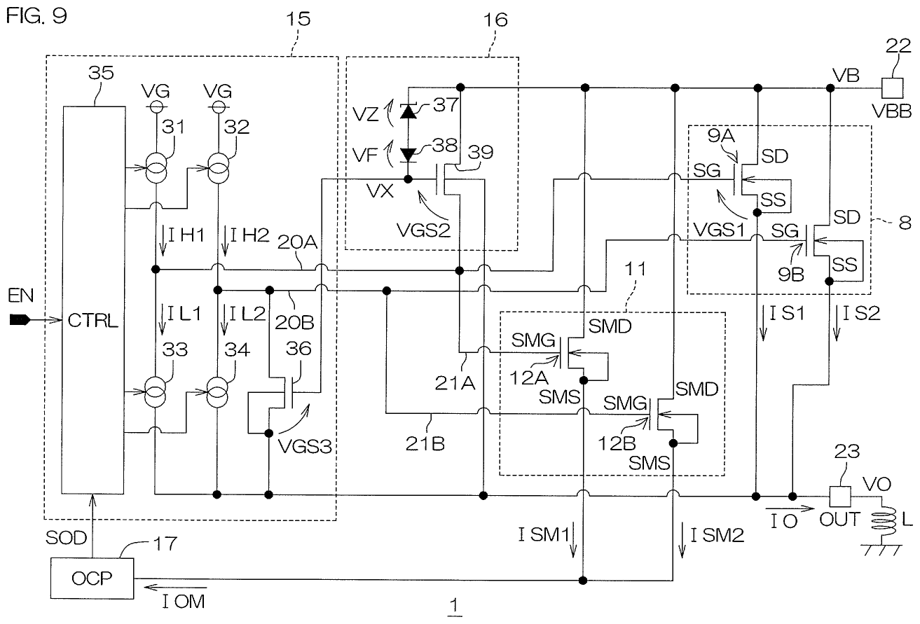

FIG. 8 is a block circuit diagram which shows a configuration example of an electrical arrangement of the semiconductor device 1 in FIG. 1 (=configuration example to which 2-system main transistor 8 and 2-system monitor transistor 11 are applied). FIG. 9 is a circuit diagram which shows a configuration example of the block circuit diagram in FIG. 8. Each of FIG. 8 and FIG. 9 is also a circuit diagram which shows a main portion of the control IC 14. FIG. 8 and FIG. 9 show an example where the inductive load L is connected to the source terminal 23.

The semiconductor device 1 includes the 2-system (n=2) main transistor 8, the 2-system (m=n=2) monitor transistor 11, the two (n=2) main gate wirings 20, the two (m=n=2) monitor gate wirings 21, the gate control circuit 15, the active clamp circuit 16 and the overcurrent protection circuit 17.

The 2-system main transistor 8 includes a first system transistor 9A and a second system transistor 9B. The two second gates SG configure the two first gates FG. The two second drains SD are each electrically connected to the drain terminal 22. The two second sources SS are each electrically connected to the source terminal 23.

The first system transistor 9A generates a first system current IS1 and the second system transistor 9B generates a second system current IS2. The 2-system main transistor 8 generates the output current IO including the first system current IS1 and the second system current IS2. As apparent from the description above, the second system current IS2 may be different from the first system current IS1 or may be the same as the first system current IS1. Hereinafter, the first system current IS1 is not distinguished from the second system current IS2 and they are simply described as the system current IS.

The 2-system main transistor 8 is controlled in a first operation mode, a second operation mode and a third operation mode. In the first operation mode, the first and second system transistors 9A and 9B are controlled so as to be in an off state at the same time. In the second operation mode, the first and second system transistors 9A and 9B are controlled so as to be in an on state at the same time. In the third operation mode, only one of the first and second system transistors 9A and 9B is controlled so as to be in an on state. In this embodiment, in the third operation mode, the first system transistor 9A is controlled so as to be in an on state and the second system transistor 9B is controlled so as to be in an off state.

The 2-system monitor transistor 11 includes a first system monitor transistor 12A and a second system monitor transistor 12B. The two second monitor gates SMG configure the two first monitor gates FMG. The two second monitor drains SMD are each electrically connected to the drain terminal 22. The two second monitor sources SMS are electrically separated from the source terminal 23 (second sources SS of first and second system transistors 9A and 9B).

The first system monitor transistor 12A generates a first system monitor current ISM1 and the second system monitor transistor 12B generates a second system monitor current ISM2. The 2-system monitor transistor 11 generates the output monitor current TOM including the first system monitor current ISM1 and the second system monitor current ISM2. As apparent from the description above, the second system monitor current ISM2 may be different from the first system monitor current ISM1 or may be the same as the first system monitor current ISM1. Hereinafter, the first system monitor current ISM1 is not distinguished from the second system monitor current ISM2 and they are simply described as the system monitor current ISM.

The 2-system monitor transistor 11 is controlled in a first operation mode, a second operation mode and a third operation mode. In the first operation mode, the first and second system monitor transistors 12A and 12B are controlled so as to be in an off state at the same time. In the second operation mode, the first and second system monitor transistors 12A and 12B are controlled so as to be in an on state at the same time. In the third operation mode, only one of the first and second system monitor transistors 12A and 12B is controlled so as to be in an on state. In this embodiment, in the third operation mode, the first system monitor transistor 12A is controlled so as to be in an on state and the second system monitor transistor 12B is controlled so as to be in an off state. In this embodiment, the first to third operation modes of the monitor transistor 11 are executed in conjunction with the first to third operation modes of the main transistor 8.

The two main gate wirings 20 include a first main gate wiring 20A and a second main gate wiring 20B. The first main gate wiring 20A is electrically connected to the second gate SG of the first system transistor 9A. The second main gate wiring 20B is electrically connected to the second gate SG of the second system transistor 9B.

The two monitor gate wirings 21 include a first monitor gate wiring 21A and a second monitor gate wiring 21B. The first monitor gate wiring 21A is electrically connected to the first main gate wiring 20A and the second monitor gate SMG of the first system monitor transistor 12A. The second monitor gate wiring 21B is electrically connected to the second main gate wiring 20B and the second monitor gate SMG of the second system monitor transistor 12B.

In the following description, “a state that is electrically connected to the first main gate wiring 20A” includes “a state that is electrically connected to the second gate SG of the first system transistor 9A” and “a state that is electrically connected to the second monitor gate SMG of the first system monitor transistor 12A.” Also, “a state that is electrically connected to the second main gate wiring 20B” includes “a state that is electrically connected to the second gate SG of the second system transistor 9B” and “a state that is electrically connected to the second monitor gate SMG of the second system monitor transistor 12B.”

The gate control circuit 15 is electrically connected to the first and second main gate wirings 20A and 20B. The gate control circuit 15 generates a first gate signal G1 and a second gate signal G2 in response to an enable signal EN and individually outputs the first and second gate signals G1 and G2 to the first and second main gate wirings 20A and 20B. A first monitor gate signal MG1 and a second monitor gate signal MG2 which are to be input into the first and second system monitor transistors 12A and 12B are respectively constituted of the first and second gate signals G1 and G2.

Specifically, in an enabled state that the enable signal EN is at a high level (EN=H), the gate control circuit 15 generates the first and second gate signals G1 and G2 which control both of the first and second system transistors 9A and 9B and both of the first and second system monitor transistors 12A and 12B so as to be in an on state. In a disabled state that the enable signal EN is at a low level (EN=L), the gate control circuit 15 generates the first and second gate signals G1 and G2 which control both of the first and second system transistors 9A and 9B and both of the first and second system monitor transistors 12A and 12B so as to be in an off state.

In this embodiment, the gate control circuit 15 includes a first current source 31, a second current source 32, a third current source 33, a fourth current source 34, a controller 35 and an n-channel type drive MISFET 36. Although not shown specifically, the first current source 31, the second current source 32, the third current source 33, the fourth current source 34, the controller 35 and the drive MISFET 36 are each formed in the second device region 7.

The first current source 31 generates a first source current IH1. The first current source 31 is electrically connected to an application end of a boosted voltage VG (=charge pump output) and the first main gate wiring 20A. The second current source 32 generates a second source current IH2. The second current source 32 is electrically connected to the application end of boosted voltage VG and the second main gate wiring 20B. The third current source 33 generates a first sink current ILL. The third current source 33 is electrically connected to the first main gate wiring 20A and the source terminal 23. The fourth current source 34 generates a second sink current IL2. The fourth current source 34 is electrically connected to the second main gate wiring 20B and the source terminal 23.

The controller 35 is electrically connected to the first to fourth current sources 31 to 34. In an enabled state (EN=H), while controlling the first and second current sources 31 and 32 so as to be in an on state, the controller 35 controls the third and fourth current sources 33 and 34 so as to be in an off state. Thereby, the first source current IH1 is output to the first main gate wiring 20A, and the second source current IH2 is output to the second main gate wiring 20B. In a disabled state (EN=L), while controlling the first and second current sources 31 and 32 so as to be in an off state, the controller 35 controls the third and fourth current sources 33 and 34 so as to be in an on state. Thereby, the first sink current IL1 is drawn from the first main gate wiring 20A, and the second sink current IL2 is drawn from the second main gate wiring 20B.

The drive MISFET 36 is electrically connected to the second main gate wiring 20B and the source terminal 23. The drive MISFET 36 includes a drain, a source, a gate and a back gate. The drain of the drive MISFET 36 is electrically connected to the second main gate wiring 20B. The source of the drive MISFET 36 is electrically connected to the source terminal 23. The back gate of the drive MISFET 36 is electrically connected to the source terminal 23.

The active clamp circuit 16 is connected between a drain and a gate of the first system transistor 9A. Also, the active clamp circuit 16 is connected between a drain and a gate of the first system monitor transistor 12A. The active clamp circuit 16 is configured so as to control both of the first system transistor 9A and the first system monitor transistor 12A in an on state and control both of the second system transistor 9B and the second system monitor transistor 12B in an off state in collaboration with the gate control circuit 15, when the first source FS (source terminal 23) of the main transistor 8 is at a negative voltage.

Specifically, the active clamp circuit 16 has an internal node voltage Vx which is electrically connected to the gate control circuit 15. The active clamp circuit 16 generates the first and second gate signals G1 and G2 which control both of the first system transistor 9A and the first system monitor transistor 12A so as to be in an on state and controls both of the second system transistor 9B and the second system monitor transistor 12B so as to be in an off state by controlling the gate control circuit 15 via the internal node voltage Vx.

More specifically, the active clamp circuit 16 generates the first and second gate signals G1 and G2 which control both of the first system transistor 9A and the first system monitor transistor 12A so as to be in an on state and control both of the second system transistor 9B and the second system monitor transistor 12B so as to be in an off state by controlling the gate control circuit 15 via the internal node voltage Vx after being shifted from the enabled state (EN=H) to the disabled state (EN=L) and before the main transistor 8 is shifted to an active clamp operation.

Specifically, that before the main transistor 8 is shifted to an active clamp operation means, that before the output voltage VO is clamped. Both of the second system transistor 9B and the second system monitor transistor 12B are controlled so as to be in an off state by the second gate signal G2 which is fixed at the output voltage VO. That is, a gate-to-source portion of the second system transistor 9B is short-circuited and a gate-to-source portion of the second system monitor transistor 12B is short-circuited.

The active clamp circuit 16 limits a drain-source voltage (=VBB−VOUT) of the main transistor 8 to a voltage not more than a clamp voltage Vclp. In this embodiment, the second system transistor 9B and the second system monitor transistor 12B are not involved in the active clamp operation. Therefore, the active clamp circuit 16 is not connected to the second system transistor 9B and the second system monitor transistor 12B.

In this embodiment, the active clamp circuit 16 includes a Zener diode array 37, a diode array 38 and an n-channel type clamp MISFET 39. Although not shown specifically, the Zener diode array 37, the diode array 38 and the clamp MISFET 39 are each formed in the second device region 7.

The Zener diode array 37 is constituted of a series circuit including a plurality (for example, eight) of Zener diodes connected in series in a forward direction. The number of the Zener diodes is arbitrary and the Zener diode may be one. The Zener diode array 37 includes a cathode and an anode. The cathode of the Zener diode array 37 is electrically connected to the drain terminal 22 and the second drains SD of the first and second system transistors 9A and 9B.

The diode array 38 is constituted of a series circuit including a plurality (for example, three) of pn junction diodes connected in series in a forward direction. The number of the pn junction diodes is arbitrary and the Zener diode may be one. The diode array 38 includes a cathode and an anode. The anode of the diode array 38 is connected to the anode of the Zener diode array 37 in a reverse biased manner.

The clamp MISFET 39 includes a drain, a source, a gate and a back gate. The drain of the clamp MISFET 39 is electrically connected to the drain terminal 22 and the second drains SD of the first and second system transistors 9A and 9B. The source of the clamp MISFET 39 is electrically connected to the first main gate wiring 20A. The gate of the clamp MISFET 39 is electrically connected to the cathode of the diode array 38. The back gate of the clamp MISFET 39 is electrically connected to the source terminal 23.

The internal node voltage Vx of the active clamp circuit 16 is electrically connected to the gate of the drive MISFET 36. The active clamp circuit 16 controls the drive MISFET 36 so as to be in an on state or in an off state according to the internal node voltage Vx. The internal node voltage Vx may be an arbitrary voltage inside the active clamp circuit 16. The internal node voltage Vx may be a gate voltage of the clamp MISFET 39 or may be an anode voltage of any one of the pn junction diodes of the diode array 38.

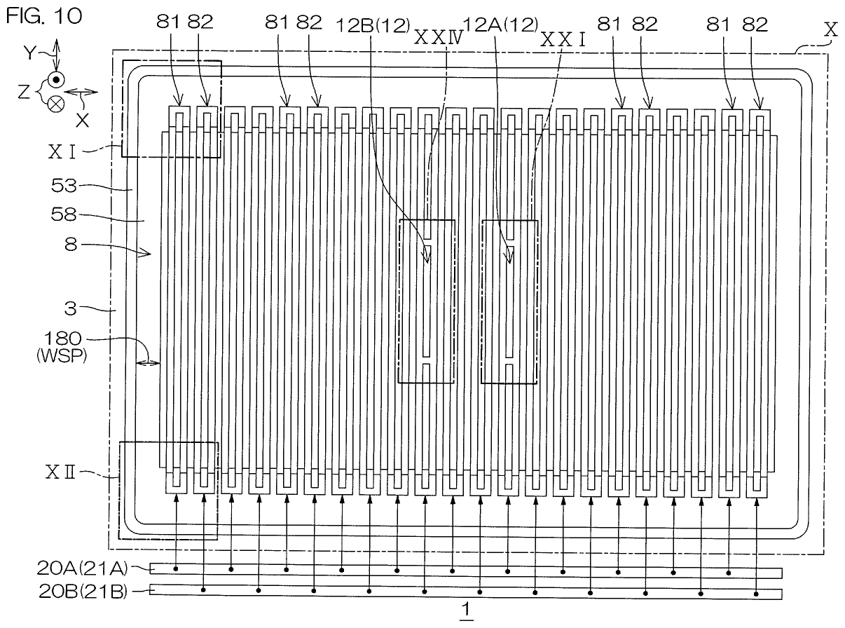

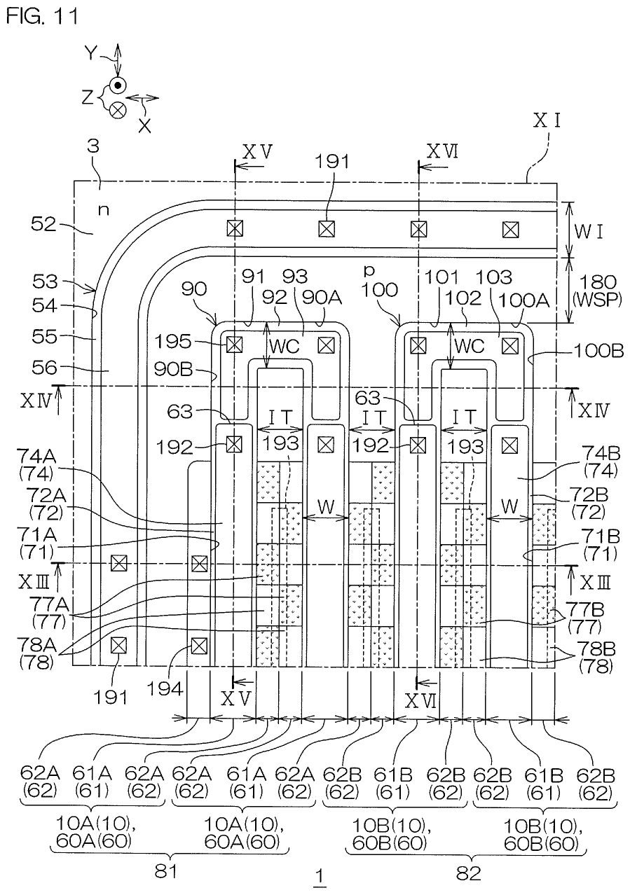

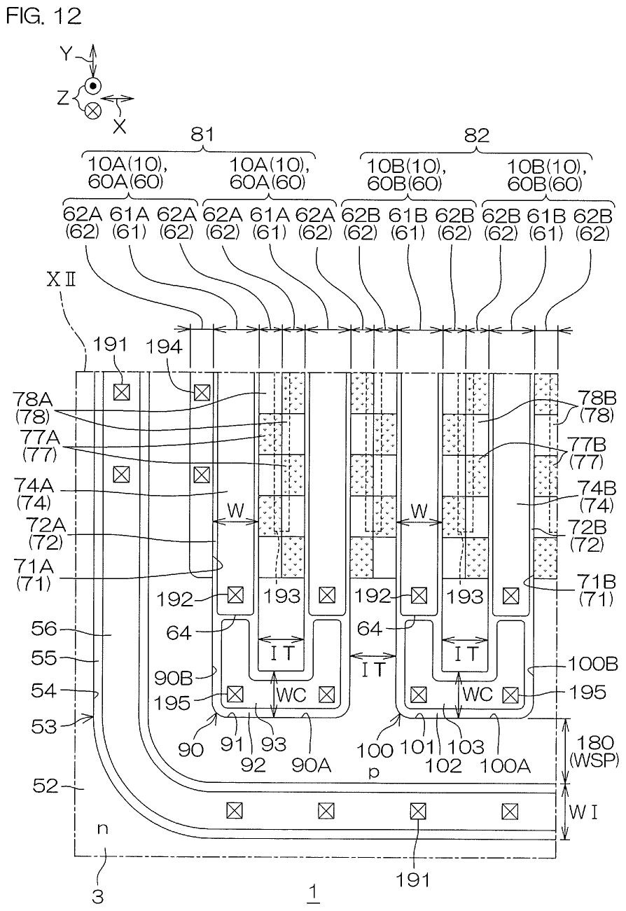

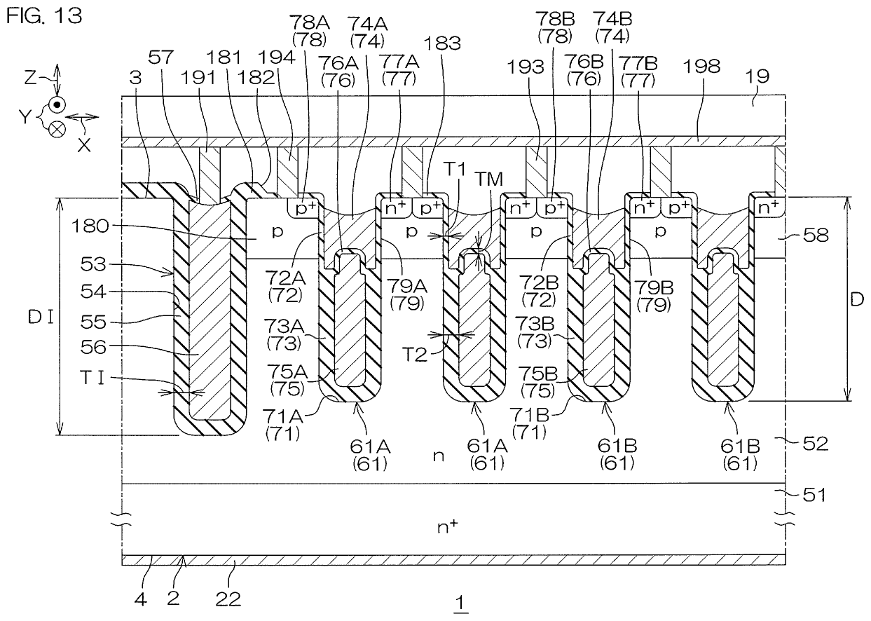

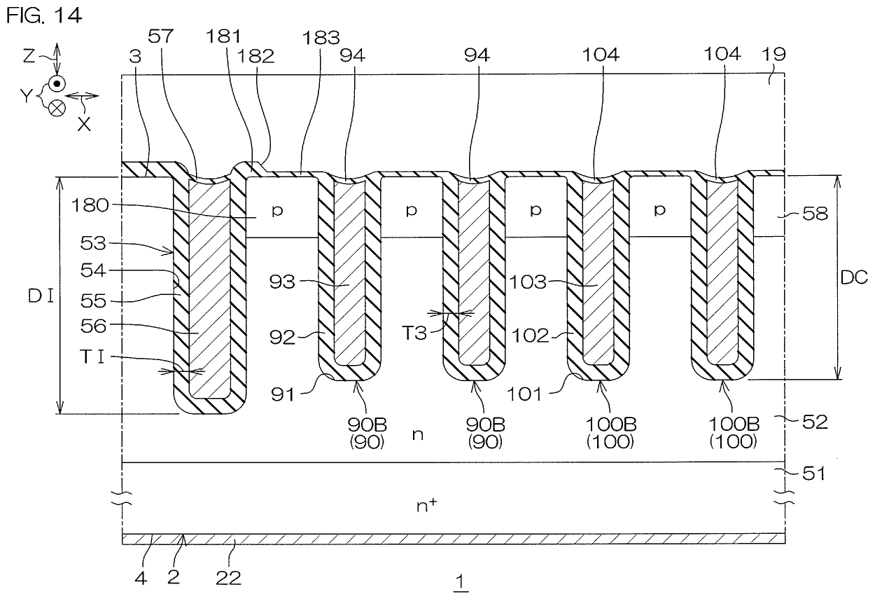

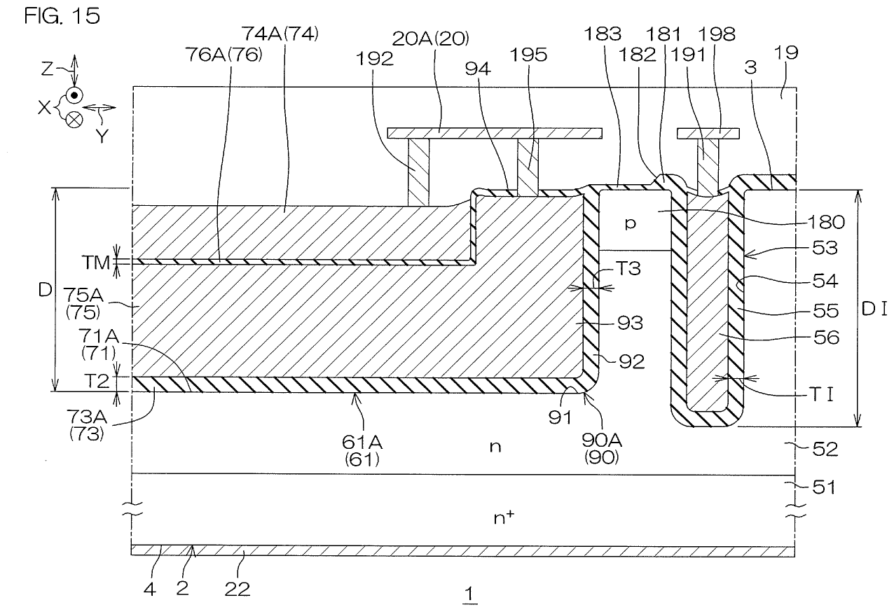

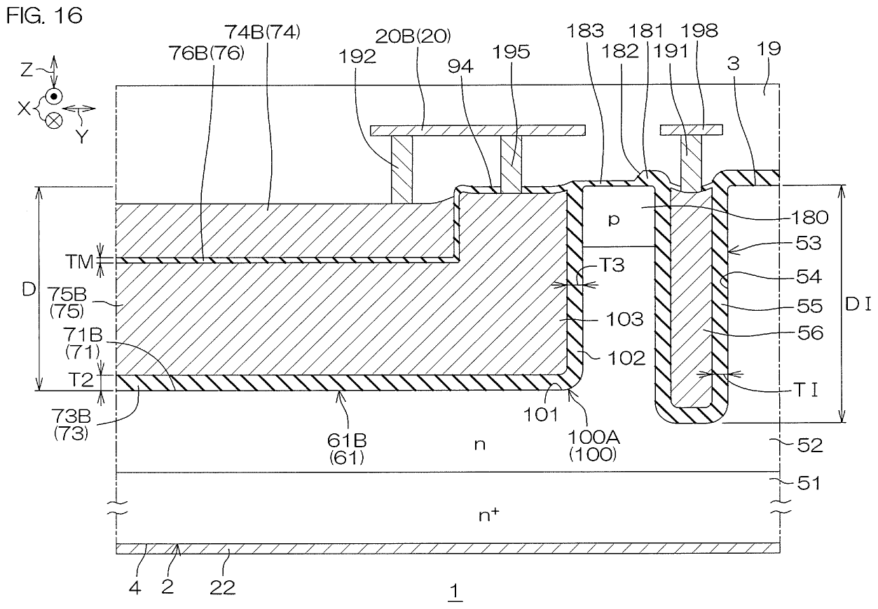

FIG. 10 is an enlarged view of a region X shown in FIG. 3 and a plan view showing a layout example of the main transistor 8 and the monitor transistor 11 in FIG. 8. FIG. 11 is an enlarged view of a region XI shown in FIG. 10. FIG. 12 is an enlarged view of a region XII shown in FIG. 10. FIG. 13 is a cross-sectional view taken along line XIII-XIII shown in FIG. 11. FIG. 14 is a cross-sectional view taken along line XIV-XIV shown in FIG. 11. FIG. 15 is a cross-sectional view taken along line XV-XV shown in FIG. 11. FIG. 16 is a cross-sectional view taken along line XVI-XVI shown in FIG. 11.

With reference to FIG. 10 to FIG. 16, the semiconductor device 1 includes an n-type (first conductive type) first semiconductor region 51 which is formed in a surface layer portion of the second main surface 4 of the semiconductor chip 2. The first semiconductor region 51 forms the first drain FD of the main transistor 8 and the first monitor drain FMD of the monitor transistor 11. The first semiconductor region 51 may be referred to as a “drain region.” The first semiconductor region 51 is formed in an entire area of the surface layer portion of the second main surface 4 and exposed from the second main surface 4 and the first to fourth side surfaces 5A to 5D.

An n-type impurity concentration of the first semiconductor region 51 may be not less than 1×10¹⁸ cm⁻³ and not more than 1×10²¹ cm⁻³. A thickness of the first semiconductor region 51 may be not less than 10 μm and not more than 450 μm. The thickness of the first semiconductor region 51 is preferably not less than 50 μm and not more than 150 μm. In this embodiment, the first semiconductor region 51 is formed of an n-type semiconductor substrate (Si substrate).

The semiconductor device 1 includes an n-type second semiconductor region 52 which is formed in a surface layer portion of the first main surface 3 of the semiconductor chip 2. The second semiconductor region 52 forms the first drain FD of the main transistor 8 and the first monitor drain FMD of the monitor transistor 11 together with the first semiconductor region 51. The second semiconductor region 52 may be referred to as a “drift region.” The second semiconductor region 52 is formed in an entire area of the surface layer portion of the first main surface 3 so as to be electrically connected to the first semiconductor region 51 and exposed from the first main surface 3 and the first to fourth side surfaces 5A to 5D.

The second semiconductor region 52 has an n-type impurity concentration less than the n-type impurity concentration of the first semiconductor region 51. The n-type impurity concentration of the second semiconductor region 52 may be not less than 1×10¹⁵ cm⁻³ and not more than 1×10¹⁸ cm⁻³. The second semiconductor region 52 has a thickness less than the thickness of the first semiconductor region 51. The thickness of the second semiconductor region 52 may be not less than 1 μm and not more than 25 μm. The thickness of the second semiconductor region 52 is preferably not less than 5 μm and not more than 15 μm. In this embodiment, the second semiconductor region 52 is formed of an n-type epitaxial layer (Si epitaxial layer).

The semiconductor device 1 includes a trench separation structure 53 as an example of a region separation structure which demarcates the first device region 6 in the first main surface 3. The trench separation structure 53 may be referred to as a “DTI (deep trench isolation) structure.” The trench separation structure 53 is formed in an annular shape surrounding some regions of the first main surface 3 in a plan view and demarcates the first device region 6 which is in a predetermined shape.

In this embodiment, the trench separation structure 53 is formed in a quadrilateral annular shape having four sides parallel to the first to fourth side surfaces 5A to 5D in a plan view and demarcates the first device region 6 in a quadrilateral shape. The planar shape of the trench separation structure 53 is arbitrary and the trench separation structure 53 may be formed in a polygonal annular shape. The first device region 6 may be demarcated in a polygonal shape according to the planar shape of the trench separation structure 53.

The trench separation structure 53 has a separation width WI and a separation depth DI. The separation width WI is a width in a direction orthogonal to a direction in which the trench separation structure 53 extends in a plan view. The separation width WI may be not less than 0.5 μm and not more than 2.5 μm. The separation width WI is preferably not less than 1.2 μm and not more than 2 μm. The separation depth DI may be not less than 1 μm and not more than 10 μm. The separation depth DI is preferably not less than 2 μm and not more than 6 μm.

An aspect ratio DI/WI of the trench separation structure 53 may be more than 1 and not more than 5. The aspect ratio DI/WI is a ratio of the separation depth DI to the separation width WI. The aspect ratio DI/WI is preferably not less than 2. A bottom wall of the trench separation structure 53 is preferably at an interval of not less than 1 μm and not more than 5 μm from a bottom portion of the second semiconductor region 52.

The trench separation structure 53 has a corner portion which connects a portion extending in the first direction X with a portion extending in the second direction Y in a circular arc shape (curved shape). In this embodiment, four corners of the trench separation structure 53 are formed in a circular arc shape. That is, the first device region 6 is demarcated in a quadrilateral shape having four corners, each of which extends in a circular arc shape. The corner portion of the trench separation structure 53 preferably has a constant separation width WI along a circular arc direction.

The trench separation structure 53 has a single electrode structure including a separation trench 54, a separation insulating film 55 (separation insulator), a separation electrode 56 and a separation cap insulating film 57. The separation trench 54 is dug down from the first main surface 3 toward the second main surface 4. The separation trench 54 is formed at an interval from the bottom portion of the second semiconductor region 52 to the first main surface 3 side.

The separation trench 54 includes a side wall and a bottom wall. An angle formed between the side wall of the separation trench 54 and the first main surface 3 inside the semiconductor chip 2 may be not less than 90° and not more than 92°. The separation trench 54 may be formed in a tapered shape in which an opening width is narrowed from an opening to the bottom wall. A corner portion of the bottom wall of the separation trench 54 is preferably formed in a curved shape. An entirety of the bottom wall of the separation trench 54 may be formed in a curved shape toward the second main surface 4.

The separation insulating film 55 is formed on a wall surface of the separation trench 54. Specifically, the separation insulating film 55 is formed as a film in an entire area of the wall surface of the separation trench 54 and demarcates a recess space inside the separation trench 54. The separation insulating film 55 preferably includes a silicon oxide film. It is particularly preferable that the separation insulating film 55 includes a silicon oxide film constituted of an oxide of the semiconductor chip 2.

The separation insulating film 55 has a separation thickness TI. The separation thickness TI is a thickness along a normal direction of the wall surface of the separation trench 54. The separation thickness TI may be not less than 0.1 μm and not more than 1 μm. The separation thickness TI is preferably not less than 0.15 μm and not more than 0.65 μm. In the separation insulating film 55, a thickness of a portion which covers the bottom wall of the separation trench 54 may be less than a thickness of a portion which covers the side wall of the separation trench 54.

The separation electrode 56 is embedded as an integrated member in the separation trench 54 across the separation insulating film 55. In this embodiment, the separation electrode 56 includes conductive polysilicon. A source potential is to be applied to the separation electrode 56. The separation electrode 56 has an electrode surface (separation electrode surface) which is exposed from the separation trench 54. The electrode surface of the separation electrode 56 may be recessed toward the bottom wall of the separation trench 54 in a curved shape. The electrode surface of the separation electrode 56 is preferably at an interval of not less than 0 Å and less than 2000 Å from the first main surface 3 to the bottom wall of the separation trench 54 with regard to a depth direction of the separation trench 54. It is in particular preferable that the electrode surface of the separation electrode 56 is at an interval of less than 1000 Å from the first main surface 3 to the bottom wall of the separation trench 54.

The separation cap insulating film 57 covers the electrode surface of the separation electrode 56 as a film inside the separation trench 54. The separation cap insulating film 57 prevents a short circuit of the separation electrode 56 with another electrode. The separation cap insulating film 57 continues to the separation insulating film 55. The separation cap insulating film 57 preferably includes a silicon oxide film. It is in particular preferable that the separation cap insulating film 57 includes a silicon oxide film constituted of an oxide of the separation electrode 56. That is, it is preferable that the separation cap insulating film 57 includes an oxide of polysilicon and the separation insulating film 55 includes an oxide of silicon monocrystal.

The semiconductor device 1 includes a p-type (second conductive type) body region 58 which is formed in a surface layer portion of the first main surface 3 in the first device region 6. A p-type impurity concentration of the body region 58 may be not less than 1×10¹⁶ cm⁻³ and not more than 1×10¹⁸ cm⁻³. The body region 58 is formed in an entire area of the surface layer portion of the first main surface 3 in the first device region 6 and in contact with the side wall of the trench separation structure 53. The body region 58 is formed in a region on the first main surface 3 side with respect to the bottom wall of the trench separation structure 53. The body region 58 is preferably formed in a region on the first main surface 3 side with respect to an intermediate portion of the trench separation structure 53.

The semiconductor device 1 includes the 2-system (n=2) main transistor 8 which is formed in the first main surface 3 in the first device region 6. The main transistor 8 is formed in the first main surface 3 at an interval from the trench separation structure 53 in a plan view. The main transistor 8 includes the plurality of unit transistors 10 which are formed so as to concentrate on the first main surface 3 of the first device region 6.

The number of the unit transistors 10 is arbitrary. FIG. 10 shows an example where the 44 unit transistors 10 are formed. The number of the unit transistors 10 is preferably an even number. The plurality of unit transistors 10 are aligned in a single row in the first direction X in a plan view and are each formed as a band extending in the second direction Y. The plurality of unit transistors 10 are formed as a stripe extending in the second direction Y in a plan view.

Specifically, the plurality of unit transistors 10 are each constituted of a unit cell 60. Each unit cell 60 includes one trench structure 61 and a channel cell 62 which is controlled by the trench structure 61. The trench structure 61 may be referred to as a “gate structure” or a “trench gate structure.” Each trench structure 61 configures the third gate TG of each unit transistor 10. The channel cell 62 is a region in which opening/closing of a current path is controlled by the trench structure 61. In this embodiment, the unit cell 60 includes a pair of the channel cells 62 which are formed on both sides of one trench structure 61.

The plurality of trench structures 61 are arrayed at an interval in the first direction X in a plan view and are each formed as a band extending in the second direction Y. That is, the plurality of trench structures 61 are formed as a stripe extending in the second direction Y in a plan view. The plurality of trench structures 61 each have a first end portion 63 on one side and a second end portion 64 on the other side with regard to a longitudinal direction (second direction Y).

Each trench structure 61 has a trench width W and a trench depth D. The trench width W is a width in a direction orthogonal to a direction in which the trench structure 61 extends (first direction X). The trench width W is preferably less than the separation width WI of the trench separation structure 53 (W<WI). The trench width W may be not less than 0.5 μm and not more than 2 μm. The trench width W is preferably not less than 0.5 μm and not more than 1.5 μm. As a matter of course, the trench width W may be substantially equal to the separation width WI (W≈WI).

The trench depth D is preferably less than the separation depth DI of the trench separation structure 53 (D<DI). The trench depth D may be not less than 1 μm and not more than 10 μm. The trench depth D is preferably not less than 2 μm and not more than 6 μm. As a matter of course, the trench depth D may be substantially equal to the separation depth DI (D≈DI). An aspect ratio D/W of the trench structure 61 may be more than 1 and not more than 5. The aspect ratio D/W is a ratio of the trench depth D to the trench width W. The aspect ratio D/W is in particular preferably not less than 2. A bottom wall of the trench structure 61 is preferably at an interval of not less than 1 μm and not more than 5 μm from the bottom portion of the second semiconductor region 52.

The plurality of trench structures 61 are arrayed with a trench interval IT kept in the first direction X. The trench interval IT is preferably set at a value at which a depletion layer expanding from the plurality of trench structures 61 is made integral further below the bottom wall of the plurality of trench structures 61. The trench interval IT may be not less than 0.25 times the trench width W and not more than 1.5 times the trench width W. The trench interval IT is preferably not more than the trench width W (IT≤W). The trench interval IT may be not less than 0.5 μm and not more than 2 μm.

Hereinafter, a description of a configuration of one trench structure 61 shall be given. The trench structure 61 has a multi-electrode structure including a trench 71, an upper insulating film 72, a lower insulating film 73, an upper electrode 74, a lower electrode 75 and an intermediate insulating film 76. The trench 71 may be referred to as a “gate trench.” The trench structure 61 includes an embedded electrode (gate electrode) which is embedded in the trench 71 across an embedded insulator. The embedded insulator is constituted of the upper insulating film 72, the lower insulating film 73 and the intermediate insulating film 76. The embedded electrode is constituted of the upper electrode 74 and the lower electrode 75.

The trench 71 is dug down from the first main surface 3 toward the second main surface 4. The trench 71 penetrates through the body region 58 and is formed at an interval from the bottom portion of the second semiconductor region 52 to the first main surface 3 side. The trench 71 includes a side wall and a bottom wall. An angle formed between the side wall of the trench 71 and the first main surface 3 inside the semiconductor chip 2 may be not less than 90° and not more than 92°. The trench 71 may be formed in a tapered shape in which an opening width is narrowed from an opening to the bottom wall. A corner portion of the bottom wall of the trench 71 is preferably formed in a curved shape. An entirety of the bottom wall of the trench 71 may be formed in a curved shape toward the second main surface 4.

The upper insulating film 72 covers an upper wall surface of the trench 71. Specifically, the upper insulating film 72 covers the upper wall surface of the trench 71 located in a region on the opening side thereof with respect to a bottom portion of the body region 58. The upper insulating film 72 crosses a boundary between the second semiconductor region 52 and the body region 58. The upper insulating film 72 has a portion which covers the body region 58 and a portion which covers the second semiconductor region 52. The area covered by the upper insulating film 72 with regard to the body region 58 is larger than the area covered by upper insulating film 72 with regard to the second semiconductor region 52. The upper insulating film 72 preferably includes a silicon oxide film. It is in particular preferable that the upper insulating film 72 includes a silicon oxide film constituted of an oxide of the semiconductor chip 2. The upper insulating film 72 is formed as a gate insulating film.

The upper insulating film 72 has a first thickness T1. The first thickness T1 is a thickness along a normal direction of a wall surface of the trench 71. The first thickness T1 is less than the separation thickness TI of the separation insulating film 55 (T1<T1). The first thickness T1 may be not less than 0.01 μm and not more than 0.05 μm. The first thickness T1 is preferably not less than 0.02 μm and not more than 0.04 μm.

The lower insulating film 73 covers a lower wall surface of the trench 71. Specifically, the lower insulating film 73 covers the lower wall surface of the trench 71 which is located in a region on the bottom wall side thereof with respect to the bottom portion of the body region 58. The lower insulating film 73 demarcates a recess space in a region on the bottom wall side of the trench 71. The lower insulating film 73 is in contact with the second semiconductor region 52. The lower insulating film 73 preferably includes a silicon oxide film. It is in particular preferable that the lower insulating film 73 incudes a silicon oxide film constituted of an oxide of the semiconductor chip 2.

The lower insulating film 73 has a second thickness T2. The second thickness T2 is a thickness along a normal direction of the wall surface of the trench 71. The second thickness T2 exceeds the first thickness T1 of the upper insulating film 72 (T1<T2). The second thickness T2 may be substantially equal to the separation thickness TI of the separation insulating film 55 (T2≈TI). The second thickness T2 may be not less than 0.1 μm and not more than 1 μm. The second thickness T2 is preferably not less than 0.15 μm and not more than 0.65 μm. In the lower insulating film 73, a thickness of a portion which covers the bottom wall of the trench 71 may be less than a thickness of a portion which covers the side wall of the trench 71.

The upper electrode 74 is embedded on the upper side (opening side) inside the trench 71 across the upper insulating film 72. The upper electrode 74 is embedded as a band extending in the second direction Y in a plan view. The upper electrode 74 faces the body region 58 and the second semiconductor region 52 across the upper insulating film 72. A facing area of the upper electrode 74 with respect to the body region 58 is larger than a facing area of the upper electrode 74 with respect to the second semiconductor region 52. The upper electrode 74 includes conductive polysilicon. The upper electrode 74 is formed as a gate electrode. The gate signal G is to be input into the upper electrode 74.

The upper electrode 74 has an electrode surface (embedded electrode surface) which is exposed from the trench 71. The electrode surface of the upper electrode 74 may be recessed in a curved shape toward the bottom wall of the trench 71. The electrode surface of the upper electrode 74 is preferably positioned further on the bottom wall side of the trench 71 than a depth position of the electrode surface of the separation electrode 56 with regard to a depth direction of the trench 71. The electrode surface of the upper electrode 74 is preferably at an interval of not less than 2000 Å from the first main surface 3 to the bottom wall of the trench 71 with regard to the depth direction of the trench 71. It is in particular preferable that the electrode surface of the upper electrode 74 is at an interval of not less than 2500 Å and not more than 4500 Å from the first main surface 3 to the bottom wall of the trench 71.

The lower electrode 75 is embedded on the lower side (bottom wall side) inside the trench 71 across the lower insulating film 73. The lower electrode 75 is embedded as a band extending in the second direction Y in a plan view. The lower electrode 75 has a thickness (length) exceeding a thickness (length) of the upper electrode 74 with regard to the depth direction of the trench 71. The lower electrode 75 faces the second semiconductor region 52 across the lower insulating film 73. The lower electrode 75 has an upper end portion which protrudes from the lower insulating film 73 to the first main surface 3 side. The upper end portion of the lower electrode 75 meshes with the bottom portion of the upper electrode 74 and faces the upper insulating film 72 across the bottom portion of the upper electrode 74 in a lateral direction along the first main surface 3.

The lower electrode 75 includes conductive polysilicon. In this embodiment, the lower electrode 75 is formed as a gate electrode. The lower electrode 75 is to be fixed at the same potential as the upper electrode 74. That is, the same gate signal G is to be applied to the lower electrode 75 at the same time with the upper electrode 74. Thereby, since it is possible to suppress a voltage drop between the upper electrode 74 and the lower electrode 75, it is possible to suppress an electric field concentration between the upper electrode 74 and the lower electrode 75. Also, the semiconductor chip 2 (in particular, second semiconductor region 52) can be decreased in on-resistance.

The intermediate insulating film 76 is interposed between the upper electrode 74 and the lower electrode 75 and electrically insulates the upper electrode 74 and the lower electrode 75. Specifically, the intermediate insulating film 76 covers the lower electrode 75 which is exposed from the lower insulating film 73 in a region between the upper electrode 74 and the lower electrode 75. The intermediate insulating film 76 continues to the upper insulating film 72 and the lower insulating film 73. The intermediate insulating film 76 preferably includes a silicon oxide film. It is in particular preferable that the intermediate insulating film 76 includes a silicon oxide film constituted of an oxide of the lower electrode 75.

The intermediate insulating film 76 has an intermediate thickness TM with regard to the normal direction Z. The intermediate thickness TM is less than the second thickness T2 of the lower insulating film 73 (TM<T2). The intermediate thickness TM may be not less than 0.01 μm and not more than 0.05 μm. The intermediate thickness TM is preferably not less than 0.02 μm and not more than 0.04 μm.

The pair of channel cells 62 are each formed as a band extending in the second direction Y on both sides of each trench structure 61. The pair of channel cells 62 have a length less than a length of the trench structure 61 with regard to the second direction Y. An entire area of the pair of channel cells 62 faces the upper electrode 74 across the upper insulating film 72. The pair of channel cells 62 each have a channel width equivalent to a value that is one-half the trench interval IT.

The pair of channel cells 62 include at least one n-type source region 77 which is formed in a surface layer portion of the body region 58. The number of the source regions 77 included in the pair of channel cells 62 is arbitrary. In this embodiment, the pair of channel cells 62 each include the plurality of source regions 77. All of the source regions 77 included in each unit cell 60 forms the third source TS of each unit transistor 10.

An n-type impurity concentration of the source region 77 exceeds the n-type impurity concentration of the second semiconductor region 52. The n-type impurity concentration of the source region 77 may be not less than 1×10¹⁸ cm⁻³ and not more than 1×10²¹ cm⁻³. The plurality of source regions 77 are formed in a region on the first main surface 3 side at an interval from the bottom portion of the body region 58 and face the upper electrode 74 across the upper insulating film 72. The plurality of source regions 77 are arrayed in each channel cell 62 at an interval in the second direction Y. That is, the plurality of source regions 77 are arrayed on both sides of the corresponding trench structure 61 at an interval along the trench structure 61.

The pair of channel cells 62 include at least one p-type contact region 78 which is formed in a region different from the source region 77 at the surface layer portion of the body region 58. The number of the contact regions 78 included in the pair of channel cells 62 is arbitrary. In this embodiment, the pair of channel cells 62 each include the plurality of contact regions 78. A p-type impurity concentration of the contact region 78 exceeds the p-type impurity concentration of the body region 58. The p-type impurity concentration of the contact region 78 may be not less than 1×10¹⁸ cm⁻³ and not more than 1×10²¹ cm⁻³.

The plurality of contact regions 78 are formed in a region on the first main surface 3 side at an interval from the bottom portion of the body region 58 and face the upper electrode 74 across the upper insulating film 72. The plurality of contact regions 78 are formed alternately with the plurality of source regions 77 in the second direction Y in a manner that one source region 77 is sandwiched therebetween. That is, the plurality of contact regions 78 are arrayed on both sides of the corresponding trench structure 61 at an interval along the trench structure 61.

The pair of channel cells 62 include a plurality of channel regions 79 which are formed between the plurality of source regions 77 and the second semiconductor region 52 inside the body region 58. On/off control of the plurality of channel regions 79 in the pair of channel cells 62 is performed by one trench structure 61. The plurality of channel regions 79 included in the pair of channel cells 62 form one channel of the unit transistor 10. Thereby, one unit cell 60 functions as one unit transistor 10.

In this embodiment, the two unit cells 60 arranged on both sides in the first direction X inside the first device region 6 do not include the source region 77 in the channel cell 62 on the trench separation structure 53 side. According to this structure, it is possible to suppress a leakage current between the trench structure 61 and the trench separation structure 53. In this embodiment, the two unit cells 60 arranged on both sides include only the contact region 78 (hereinafter, referred to as the “outermost contact region 78”) in the channel cell 62 on the trench separation structure 53 side. The outermost contact region 78 is formed in an interval from the trench separation structure 53 to the trench structure 61 side and is connected to a side wall of the corresponding trench structure 61. The outermost contact region 78 may be formed as a band extending along the side wall of the corresponding trench structure 61.

The main transistor 8 includes two (n=2) system transistors 9 which are formed so as to concentrate in the first device region 6. The two system transistors 9 include the first system transistor 9A and the second system transistor 9B. The first system transistor 9A includes a plurality (in this embodiment, 22) of first unit transistors 10A which are selectively systematized as an individually controlled object from the plurality of unit transistors 10.

The second system transistor 9B includes a plurality (in this embodiment, 22) of second unit transistors 10B which are selectively systematized as an individually controlled object from the plurality of unit transistors 10 excluding the first unit transistors 10A. The number of the second unit transistors 10B may be different from the number of the first unit transistors 10A. The number of the second unit transistors 10B is preferably equal to the number of the first unit transistors 10A.

Hereinafter, the “unit cell 60,” the “trench structure 61,” the “channel cell 62,” the “trench 71,” the “upper insulating film 72,” the “lower insulating film 73,” the “upper electrode 74,” the “lower electrode 75,” the “intermediate insulating film 76,” the “source region 77,” the “contact region 78” and the “channel region 79” of the first unit transistor 10A are respectively referred to as a “first unit cell 60A,” a “first trench structure 61A,” a “first channel cell 62A,” a “first trench 71A,” a “first upper insulating film 72A,” a “first lower insulating film 73A,” a “first upper electrode 74A,” a “first lower electrode 75A,” a “first intermediate insulating film 76A,” a “first source region 77A,” a “first contact region 78A” and a “first channel region 79A.” The first gate signal G1 is to be input into the first upper electrode 74A and the first lower electrode 75A.

Hereinafter, the “unit cell 60,” the “trench structure 61,” the “channel cell 62,” the “trench 71,” the “upper insulating film 72,” the “lower insulating film 73,” the “upper electrode 74,” the “lower electrode 75,” and the “intermediate insulating film 76,” the “source region 77,” the “contact region 78” and the “channel region 79” of the second unit transistor 10B are respectively referred to as a “second unit cell 60B,” a “second trench structure 61B,” a “second channel cell 62B,” a “second trench 71B,” a “second upper insulating film 72B,” a “second lower insulating film 73B,” a “second upper electrode 74B,” a “second lower electrode 75B,” a “second intermediate insulating film 76B,” a “second source region 77B,” a “second contact region 78B” and a “second channel region 79B.” The second gate signal G2 which is electrically independent of the first gate signal G1 is to be input into the second upper electrode 74B and the second lower electrode 75B.

The first system transistor 9A includes at least one first composite cell 81. The number of the first composite cells 81 is arbitrary and is adjusted according to a size of the first device region 6 (a total number of the unit transistors 10). In this embodiment, the first system transistor 9A includes the plurality (in this embodiment, 11) of first composite cells 81. The plurality of first composite cells 81 are each constituted of an α (α≥2) number of the first unit transistors 10A (first unit cell 60A) arrayed which are mutually adjacent to the first main surface 3 in a plan view. The plurality of first composite cells 81 are arrayed at an interval in the first direction X in a plan view.

The second system transistor 9B includes at least one second composite cell 82. The number of the second composite cells 82 is arbitrary and is adjusted according to a size of the first device region 6 (a total number of the unit transistors 10). The number of the second composite cells 82 may be different from the number of the first composite cells 81. The number of the second composite cells 82 is preferably equal to the number of the first composite cells 81. In this embodiment, the second system transistor 9B includes the plurality (in this embodiment, 11) of second composite cells 82. The plurality of second composite cells 82 are each constituted of a β (β≥2) number of the second unit transistors 10B (second unit cell 60B) which are which are arrayed mutually adjacent to the first main surface 3 in a plan view.

The plurality of second composite cells 82 are each arranged mutually adjacent to the plurality of first composite cells 81 in a plan view. Specifically, the plurality of second composite cells 82 are each arranged in a region between the plurality of first composite cells 81 which are in close proximity to each other in a plan view. More specifically, the plurality of second composite cells 82 are arrayed alternately with the plurality of first composite cells 81 along the first direction X in a manner that one first composite cell 81 is sandwiched therebetween in a plan view.

The number of the first unit transistors 10A included in one first composite cell 81 may be given as one (α=1) and the number of the second unit transistors 10B included in one second composite cell 82 may be given as one (β=1). That is, the plurality of second unit transistors 10B may be arrayed alternately with the plurality of first unit transistors 10A in a manner that one first unit transistor 10A is sandwiched therebetween in a plan view.

However, in this case, the number of the plurality of first unit transistors 10A and the plurality of second unit transistors 10B which face each other increase. As a result, a risk of short circuit between the first unit transistor 10A and the second unit transistor 10B which are in close proximity to each other is increased due to a process error, etc. Here, “short circuit” refers to a short circuit between the first trench structure 61A (third gate TG) of the first unit transistor 10A and the second trench structure 61B (third gate TG) of the second unit transistor 10B (also see the circuit diagram of FIG. 6).

For example, where one first unit transistor 10A short-circuits with one second unit transistor 10B to which the first unit transistor 10A is in close proximity, all of the first unit transistors 10A are short-circuited by all of the second unit transistors 10B. That is, as a result of the first system transistor 9A and the second system transistor 9B functioning as one system transistor 9, the first system transistor 9A and the second system transistor 9B do not configure the 2-system main transistor 8 (also see the circuit diagram of FIG. 6).

Therefore, the number of the first unit transistors 10A included in one first composite cell 81 is preferably not less than 2 (α≥2), and the number of the second unit transistors 10B included in one second composite cell 82 is preferably not less than 2 (β≥2). In this structure, the number of the plurality of first unit transistors 10A and the plurality of second unit transistors 10B which face each other can be decreased. As a result, it is possible to decrease a risk of short circuit between the first unit transistor 10A and the second unit transistor 10B which are in close proximity to each other.

In this case, an electrode surface of the first upper electrode 74A according to the first system transistor 9A is preferably at an interval of not less than 2000 Å (preferably not less than 2500 Å and not more than 4500 Λ) from the first main surface 3 to the bottom wall of the first trench 71A with regard to a depth direction of the first trench 71A. A depth position of the electrode surface of the first upper electrode 74A is adjusted to a depth position at which characteristics of the gate threshold voltage of the first unit transistor 10A will not deteriorate.

Similarly, an electrode surface of the second upper electrode 74B according to the second system transistor 9B is preferably at an interval of not less than 2000 Å (preferably, not less than 2500 Å and not more than 4500 Å) from the first main surface 3 to the bottom wall of the second trench 71B with regard to a depth direction of the second trench 71B. A depth position of the electrode surface of the second upper electrode 74B is adjusted to a depth position at which characteristics of the gate threshold voltage of the second unit transistor 10B will not deteriorate.

According to the structures above, the first upper electrode 74A can be appropriately separated from the second upper electrode 74B and embedded in the first trench 71A, and the second upper electrode 74B can be appropriately separated from the first upper electrode 74A and embedded in the second trench 71B. Thereby, risk of short circuit of the first upper electrode 74A and the second upper electrode 74B can be appropriately decreased. Also, the first source region 77A (first channel region 79A) can be appropriately faced to the first upper electrode 74A, and the second source region 77B (second channel region 79B) can be appropriately faced to the second upper electrode 74B.

The first unit transistor 10A (specifically, first channel region 79A) serves as a heating source in the first device region 6. Therefore, the number of the first unit transistors 10A regulates a heating amount of one first composite cell 81, and an arrangement of the plurality of first composite cells 81 regulates a heating site in the first device region 6. That is, an increase in the number of the first unit transistors 10A which configure one first composite cell 81 results in an increase in heating amount inside one first composite cell 81. Also, where the plurality of first composite cells 81 are arranged so as to be mutually adjacent, the heating sites of the first device region 6 are localized.

Therefore, the number of the first unit transistors 10A is preferably not more than four (α≤4). According to this structure, it is possible to suppress a local temperature rise in one first composite cell 81. In view of the risk of short circuit and the heating amount, the number of the first unit transistors 10A is in particular preferably two (α=2). The plurality of first composite cells 81 are preferably arrayed at an equal interval in a region between one end portion and the other end portion of the first device region 6. According to this structure, it is possible to thin out the heating sites coming from the plurality of first composite cells 81 in the first device region 6 and it is possible to suppress a local temperature rise in the first device region 6.

In each first composite cell 81, the plurality of first channel regions 79A (first source regions 77A) arrayed on the side of one of the first trench structures 61A preferably face a region between the plurality of first channel regions 79A (first source regions 77A) arrayed on the side of the other of the first trench structures 61A in the first direction X. According to this structure, it is possible to thin out starting points of heating in each first composite cell 81. Thereby, it is possible to suppress a local temperature rise in each first composite cell 81.

In this case, in each first unit cell 60A, the plurality of first channel regions 79A formed in one of the first channel cells 62A preferably face the plurality of first channel regions 79A formed in the other of the first channel cells 62A across the corresponding first trench structure 61A. In each first composite cell 81, the plurality of first channel regions 79A formed in a region between a pair of the first trench structures 61A are preferably arrayed so as to be shifted from each other in the second direction Y in a plan view. As a matter of course, in each first unit cell 60A, the plurality of first channel regions 79A formed in one of the first channel cells 62A may face a region between the plurality of first channel regions 79A formed in the other of the first channel cells 62A across the corresponding first trench structure 61A.

In each first unit cell 60A, the plurality of first contact regions 78A formed in one of the first channel cells 62A may face the plurality of first contact regions 78A formed in the other of the first channel cells 62A across the corresponding first trench structure 61A. In each first composite cell 81, the plurality of first contact regions 78A arrayed on the side of one of the first trench structures 61A may face a region between the plurality of first contact regions 78A arrayed on the side of the other of the first trench structures 61A in the first direction X.

In each first composite cell 81, the plurality of first contact regions 78A formed in a region between the pair of first trench structures 61A may be arrayed so as to be shifted from each other in the second direction Y in a plan view. Also, the plurality of first contact regions 78A may face the plurality of first source regions 77A in the first direction X in a plan view.

The second unit transistor 10B serves as a heating source in the first device region 6. Therefore, the number of the second unit transistors 10B regulates a heating amount of one second composite cell 82, and an arrangement of the plurality of second composite cells 82 regulates the heating site in the first device region 6. That is, an increase in the number of the second unit transistors 10B which configure one second composite cell 82 results in an increase in heating amount inside one second composite cell 82. Also, where the plurality of second composite cells 82 are arranged so as to be mutually adjacent, the heating sites of the first device region 6 are localized.

Therefore, the number of the second unit transistors 10B is preferably not more than four (β≤4). According to this structure, it is possible to suppress a local temperature rise in one second composite cell 82. In this case, the number of the second unit transistors 10B is preferably equal to the number of the first unit transistors 10A. According to this structure, it is possible to suppress a variation in heating range due to the first composite cell 81 and a variation in heating range due to the second composite cell 82. In view of the risk of short circuit and the heating amount, the number of the second unit transistors 10B is in particular preferably two (β=2).

The plurality of second composite cells 82 are preferably arrayed at an equal interval in a region between one end portion and the other end portion of the first device region 6. According to this structure, it is possible to thin out the heating sites coming from the plurality of second composite cells 82 in the first device region 6 and it is possible to suppress a local temperature rise in the first device region 6. In this case, it is preferable that at least one second composite cell 82 is arranged so as to be in close proximity to at least one first composite cell 81. According to this structure, it is possible to create such a situation that, in the first composite cell 81 and the second composite cell 82 which are in close proximity to each other, one of the cells is in an on state and the other of the cells is in an off state. It is therefore possible to suppress a local temperature rise due to the first composite cell 81 and the second composite cell 82.

In this case, at least one second composite cell 82 is preferably arranged in a region between the two mutually adjacent first composite cells 81. Further, in this case, it is in particular preferable that the plurality of second composite cells 82 are alternately arrayed with the plurality of first composite cells 81 in a manner that one first composite cell 81 is sandwiched therebetween. According to the structures above, the two first composite cells 81 which are in close proximity to each other can be isolated at an interval corresponding to the second composite cell 82. Thereby, it is possible to appropriately thin out the heating sites coming from the plurality of first composite cells 81 and the plurality of second composite cells 82 and it is possible to appropriately suppress a local temperature rise in the first device region 6.

In each second composite cell 82, the plurality of second channel regions 79B (second source regions 77B) arrayed on the side of one of the second trench structures 61B preferably face a region between the plurality of second channel regions 79B (second source regions 77B) arrayed on the side of the other of the second trench structures 61B in the first direction X. According to this structure, it is possible to thin out starting points of heating in each second composite cell 82. Thereby, it is possible to suppress a local temperature rise in each second composite cell 82.

In this case, in each second unit cell 60B, the plurality of second channel regions 79B formed in one of the second channel cells 62B preferably face the plurality of second channel regions 79B formed in the other of the second channel cells 62B across the corresponding second trench structure 61B. In each second composite cell 82, the plurality of second channel regions 79B formed in a region between a pair of the second trench structures 61B are preferably arrayed so as to be shifted from each other in the second direction Y in a plan view.

The plurality of second channel regions 79B are preferably arrayed so as to be shifted in the second direction Y with respect to the plurality of first channel regions 79A in an inter-trench region between each first trench structure 61A and each second trench structure 61B. That is, the plurality of second channel regions 79B preferably face a region between the plurality of first contact regions 78A in the first direction X in the inter-trench region. According to the structures above, it is possible to thin out starting points of heating in the inter-trench region. It is therefore possible to suppress a local temperature rise in the inter-trench region.

In each second unit cell 60B, the plurality of second contact regions 78B formed in one of the second channel cells 62B may face the plurality of second contact regions 78B formed in the other of the second channel cells 62B across the corresponding second trench structure 61B. In each second composite cell 82, the plurality of second contact regions 78B arrayed on the side of one of the second trench structures 61B may face a region between the plurality of second contact regions 78B arrayed on the side of the other of the second trench structures 61B in the first direction X. As a matter of course, in each second unit cell 60B, the plurality of second channel regions 79B formed in one of the second channel cells 62B may face a region between the plurality of second channel regions 79B formed in the other of the second channel cells 62B across the corresponding second trench structure 61B.

In each second composite cell 82, the plurality of second contact regions 78B formed in a region between the pair of second trench structures 61B may be arrayed so as to be shifted from each other in the second direction Y in a plan view. The plurality of second contact regions 78B may face the plurality of second source regions 77B in the first direction X in a plan view.

The n-system main transistor 8 has a total channel ratio RT. The total channel ratio RT is a ratio of a total planar area of all of the channel regions 79 which occupies a planar area of all of the channel cells 62. A planar area of each channel region 79 is defined by a planar area of each source region 77. The total channel ratio RT is adjusted in a range of more than 0% and less than 100%. The total channel ratio RT is preferably adjusted in a range of not less than 25% and not more than 75%.

The total channel ratio RT is divided into an n-number of system channel ratios RS by the n-number of the system transistors 9. The total channel ratio RT of the 2-system main transistor 8 is constituted of an added value (RT=RSA+RSB) of a first system channel ratio RSA of the first system transistor 9A and a second system channel ratio RSB of the second system transistor 9B. The first system channel ratio RSA is a ratio of a total planar area of all of the first channel regions 79A which occupies a total planar area of all of the channel cells 62. The second system channel ratio RSB is a ratio of a total planar area of all of the second channel regions 79B which occupies a total planar area of all of the channel cells 62.

A planar area of each first channel region 79A is defined by a planar area of each first source region 77A, and a planar area of each second channel region 79B is defined by a planar area of each second source region 77B. The first system channel ratio RSA is adjusted by an arrayed pattern of the first source region 77A and the first contact region 78A. The second system channel ratio RSB is adjusted by an arrayed pattern of the second source region 77B and the second contact region 78B.

The first system channel ratio RSA is divided into a plurality of first channel ratios RCA by the plurality of first composite cells 81. The first channel ratio RCA is a ratio of a total planar area of the plurality of first channel regions 79A which occupies a total planar area of all of the channel cells 62 in each first composite cell 81. The first system channel ratio RSA is constituted of an added value of the plurality of first channel ratios RCA. The plurality of first composite cells 81 preferably have the first channel ratios RCA which are equal to each other. In each first unit transistor 10A, the plurality of first channel regions 79A may be formed in a first area which is different from each other or equal to each other for each unit area.

The second system channel ratio RSB is divided into a plurality of second channel ratios RCB by the plurality of second composite cells 82. The second channel ratio RCB is a ratio of a total planar area of the plurality of second channel regions 79B which occupies a total planar area of all of the channel cells 62 in each second composite cell 82. The plurality of second composite cells 82 are constituted of an added value of the plurality of second channel ratios RCB. The plurality of second composite cells 82 preferably have the second channel ratios RCB which are equal to each other. In each second unit transistor 10B, the plurality of second channel regions 79B may be formed in a second area which is different from each other or equal to each other for each unit area. The second area may be equal to or different from the first area of the plurality of first channel regions 79A for each unit area.

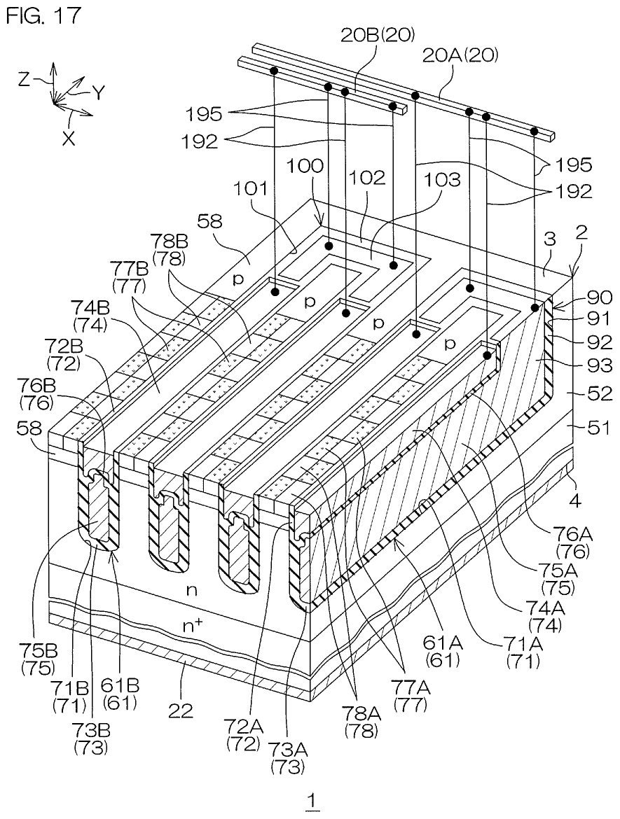

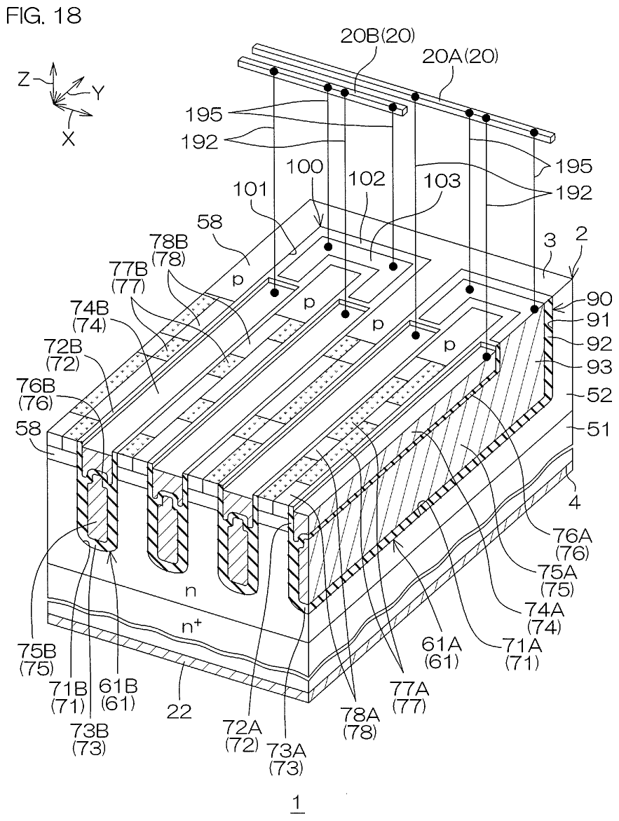

The second system channel ratio RSB may be substantially equal to the first system channel ratio RSA (RSA≈RSB). The second system channel ratio RSB may exceed the first system channel ratio RSA (RSA<RSB). The second system channel ratio RSB may be less than the first system channel ratio RSA (RSB<RSA). Hereinafter, in FIG. 17 to FIG. 20, configuration examples of the first channel region 79A and the second channel region 79B are shown.

FIG. 17 is a cross-sectional perspective view which shows a main portion of the main transistor 8 together with a first configuration example of the first channel region 79A and the second channel region 79B. In this configuration example, the total channel ratio RT is 50%, the first system channel ratio RSA is 25% and the second system channel ratio RSB is 25%.

FIG. 18 is a cross-sectional perspective view which shows the main portion of the main transistor 8 together with a second configuration example of the first channel region 79A and the second channel region 79B. In this configuration example, the total channel ratio RT is 50%, the first system channel ratio RSA is 37.5% and the second system channel ratio RSB is 12.5%.

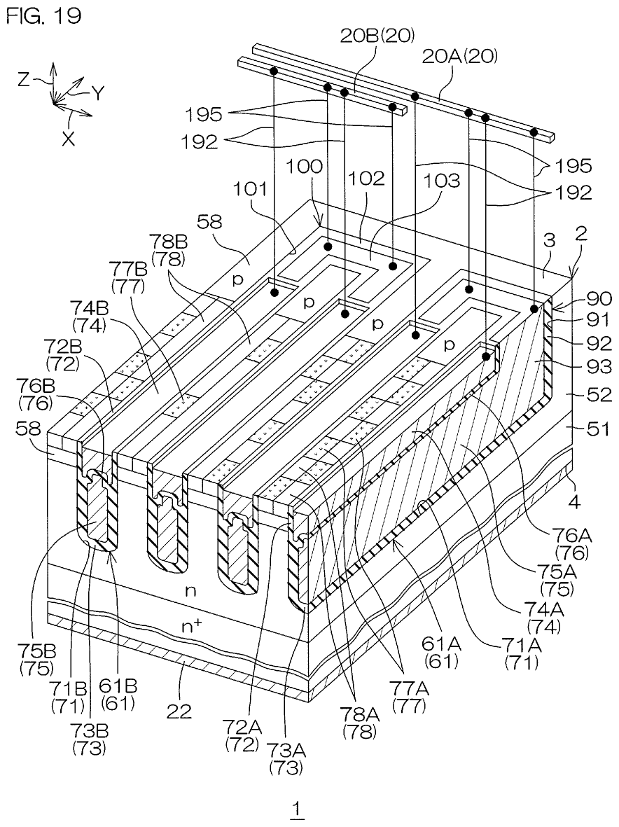

FIG. 19 is a cross-sectional perspective view which shows the main portion of the main transistor 8 together with a third configuration example of the first channel region 79A and the second channel region 79B. In this configuration example, the total channel ratio RT is 33%, the first system channel ratio RSA is 24.7% and the second system channel ratio RSB is 8.3%.

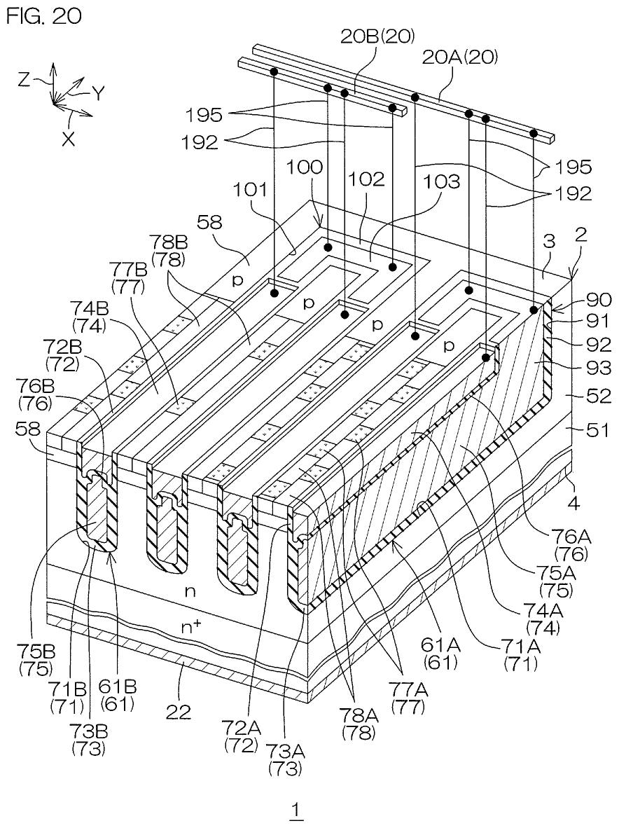

FIG. 20 is a cross-sectional perspective view which shows the main portion of the main transistor 8 together with a fourth configuration example of the first channel region 79A and the second channel region 79B. In this configuration example, the total channel ratio RT is 25%, the first system channel ratio RSA is 18.7% and the second system channel ratio RSB is 6.3%.

With again reference to FIG. 10 to FIG. 16, the main transistor 8 includes multiple pairs (in this embodiment, 11 pairs, total of 22) of first trench connection structures 90 which are formed in the first main surface 3 in the first device region 6. The multiple pairs of first trench connection structures 90 each include the first trench connection structure 90 on one side (first side surface 5A side) and the first trench connection structure 90 on the other side (second side surface 5B side) which face each other across one corresponding first composite cell 81 with regard to the second direction Y.

The first trench connection structure 90 on one side connects the first end portions 63 of the plurality (in this embodiment, one pair) of first trench structures 61A each other in an arch shape in a plan view. The first trench connection structure 90 on the other side connects the second end portions 64 of the plurality (in this embodiment, one pair) of first trench structures 61A each other in an arch shape in a plan view. With the plurality (in this embodiment, one pair) of first trench structures 61A which configure one first composite cell 81, the pair of first trench connection structures 90 configure one annular-shaped trench structure.

The first trench connection structure 90 on the other side has the same structure as the first trench connection structure 90 on one side except that it is connected to the second end portion 64 of the first trench structure 61A. Hereinafter, a description of a configuration of one first trench connection structure 90 on one side shall be given, and a description of a configuration of the first trench connection structure 90 on the other side shall be omitted.

The first trench connection structure 90 on one side has a first portion 90A extending in the first direction X and a plurality (in this embodiment, one pair) of second portions 90B extending in the second direction Y. The first portion 90A faces the plurality of first end portions 63 in a plan view. The plurality of second portions 90B extend from the first portion 90A to the plurality of first end portions 63 and are connected to the plurality of first end portions 63.

The first trench connection structure 90 on one side has a connection width WC and a connection depth DC. The connection width WC is a width in a direction orthogonal to a direction in which the first trench connection structure 90 extends. The connection width WC is preferably substantially equal to the trench width W of the trench structure 61 (WC≈W). The connection depth DC is preferably substantially equal to the trench depth D of the trench structure 61 (DC≈D). It is preferable that an aspect ratio DC/WC of the first trench connection structure 90 is substantially equal to the aspect ratio D/W of the trench structure 61 (DC/WC≈D/W). A bottom wall of the first trench connection structure 90 is preferably at an interval of not less than 1 μm and not more than 5 μm from the bottom portion of the second semiconductor region 52.

The first trench connection structure 90 on one side has a single electrode structure including a first connection trench 91, a first connection insulating film 92, a first connection electrode 93 and a first cap insulating film 94. The first connection trench 91 extends in an arch shape so as to be communicatively connected to the first end portions 63 of the plurality of first trenches 71A in a plan view and is dug down from the first main surface 3 to the second main surface 4. The first connection trench 91 demarcates the first portion 90A and the second portion 90B of the first trench connection structure 90. The first connection trench 91 is formed at an interval from the bottom portion of the second semiconductor region 52 to the first main surface 3 side.

The first connection trench 91 includes a side wall and a bottom wall. An angle formed between the side wall of the first connection trench 91 and the first main surface 3 inside the semiconductor chip 2 may be not less than 90° and not more than 92°. The first connection trench 91 may be formed in a tapered shape in which an opening width is narrowed from an opening to the bottom wall. A corner portion of the bottom wall of the first connection trench 91 is preferably formed in a curved shape. An entirety of the bottom wall of the first connection trench 91 may be formed in a curved shape toward the second main surface 4. The side wall and the bottom wall of the first connection trench 91 are smoothly connected to the side wall and the bottom wall of the first trench 71A.

The first connection insulating film 92 is formed on a wall surface of the first connection trench 91. Specifically, the first connection insulating film 92 is formed as a film in an entire area of the wall surface of the first connection trench 91 and demarcates a recess space inside the first connection trench 91. The first connection insulating film 92 extends in the first direction X at the first portion 90A of the first connection trench 91. The first connection insulating film 92 extends in the second direction Y at the second portion 90B of the first connection trench 91. The first connection insulating film 92 is connected to the first upper insulating film 72A and the first lower insulating film 73A at a communicatively connected portion of the first connection trench 91 and the first trench 71A. The first connection insulating film 92 includes a silicon oxide film. It is in particular preferable that the first connection insulating film 92 includes a silicon oxide film constituted of an oxide of the semiconductor chip 2.

The first connection insulating film 92 has a third thickness T3. The third thickness T3 is a thickness along a normal direction of the wall surface of the first connection trench 91. The third thickness T3 exceeds the first thickness T1 of the first upper insulating film 72A (T1<T3). The third thickness T3 may be substantially equal to the second thickness T2 of the lower insulating film 73 (T2≈T3). The third thickness T3 may be substantially equal to the separation thickness TI of the separation insulating film 55 (T3≈T1). The third thickness T3 may be not less than 0.1 μm and not more than 1 μm. The third thickness T3 is preferably not less than 0.15 μm and not more than 0.65 μm. A thickness of a portion which covers the bottom wall of the first connection trench 91 in the first connection insulating film 92 may be less than a thickness of a portion which covers the side wall of the first connection trench 91.

The first connection electrode 93 is embedded in the first connection trench 91 as an integrated member across the first connection insulating film 92. In this embodiment, the first connection electrode 93 includes conductive polysilicon. The first connection electrode 93 extends in the first direction X at the first portion 90A of the first connection trench 91. The first connection electrode 93 extends in the second direction Y at the second portion 90B of the first connection trench 91. The first connection electrode 93 is connected to the first lower electrode 75A at the communicatively connected portion of the first connection trench 91 and the first trench 71A.

The first connection electrode 93 is electrically insulated from the first upper electrode 74A across the first intermediate insulating film 76A. That is, the first connection electrode 93 is constituted of a lead-out portion which is led out to the first connection trench 91 from the first trench 71A across the first connection insulating film 92 and the first intermediate insulating film 76A in the first lower electrode 75A. The first gate signal G1 is transmitted to the first lower electrode 75A via the first connection electrode 93. That is, the same first gate signal G1 is to be applied to the first connection electrode 93 at the same time with the first upper electrode 74A.

The first connection electrode 93 has an electrode surface (first connection electrode surface) which is exposed from the first connection trench 91. The electrode surface of the first connection electrode 93 may be recessed in a curved shape toward the bottom wall of the first connection trench 91. The electrode surface of the first connection electrode 93 is preferably located (protrudes) further on the first main surface 3 side than a depth position of the electrode surface of the upper electrode 74 of the trench structure 61 with regard to a depth direction of the first connection trench 91. The electrode surface of the first connection electrode 93 is preferably at an interval of not less than 0 Å and less than 2000 Å from the first main surface 3 to the bottom wall of the first connection trench 91. It is in particular preferable that the electrode surface of the first connection electrode 93 is at an interval of less than 1000 Å from the first main surface 3 to the bottom wall of the first connection trench 91.

The first cap insulating film 94 covers the electrode surface of the first connection electrode 93 as a film inside the first connection trench 91. The first cap insulating film 94 prevents a short circuit of the first connection electrode 93 with another electrode. The first cap insulating film 94 continues to the first connection insulating film 92. The first cap insulating film 94 preferably includes a silicon oxide film. It is in particular preferable that the first cap insulating film 94 includes a silicon oxide film constituted of an oxide of the first connection electrode 93. That is, it is preferable that the first cap insulating film 94 includes an oxide of polysilicon and the first connection insulating film 92 includes an oxide of silicon monocrystal.

The main transistor 8 includes multiple pairs (in this embodiment, 11 pairs, a total of 22) of second trench connection structures 100 which are formed in the first main surface 3 in the first device region 6. The multiple pairs of second trench connection structures 100 each include the second trench connection structure 100 on one side (first side surface 5A side) and the second trench connection structure 100 on the other side (second side surface 5B side) which face each other across one corresponding second composite cell 82 with regard to the second direction Y.

The second trench connection structure 100 on one side connects the first end portions 63 of the plurality (in this embodiment, one pair) of second trench structures 61B each other in an arch shape in a plan view. The second trench connection structure 100 on the other side connects the second end portions 64 of the plurality (in this embodiment, one pair) of second trench structures 61B each other in an arch shape in a plan view. With the plurality (in this embodiment, one pair) of second trench structures 61B which configure one second composite cell 82, the pair of second trench connection structures 100 configure one annular-shaped trench structure.

The second trench connection structure 100 on the other side has the same structure as the second trench connection structure 100 on one side except that it is connected to the second end portion 64 of the second trench structure 61B. Hereinafter, a description of a configuration of one second trench connection structure 100 on one side shall be given, and a description of a configuration of the second trench connection structure 100 on the other side shall be omitted.

The second trench connection structure 100 on one side has a first portion 100A which extends in the first direction X and a plurality (in this embodiment, one pair) of second portions 100B which extend in the second direction Y. The first portion 100A faces the plurality of first end portions 63 in a plan view. The plurality of second portions 100B extend from the first portion 100A to the plurality of first end portions 63 and are connected to the plurality of first end portions 63. As with each of the first trench connection structures 90, the second trench connection structure 100 on one side has the connection width WC and the connection depth DC.

The second trench connection structure 100 on one side has a single electrode structure including a second connection trench 101, a second connection insulating film 102, a second connection electrode 103 and a second cap insulating film 104. The second connection trench 101 extends in an arch shape so as to be communicatively connected to the first end portions 63 of the pair of second trenches 71B in a plan view and is dug down from the first main surface 3 toward the second main surface 4. The second connection trench 101 demarcates the first portion 100A and the second portion 100B of the second trench connection structure 100. The second connection trench 101 is formed at an interval from the bottom portion of the second semiconductor region 52 to the first main surface 3 side.

The second connection trench 101 includes a side wall and a bottom wall. An angle formed between the side wall of the second connection trench 101 and the first main surface 3 inside the semiconductor chip 2 may be not less than 90° and not more than 92°. The second connection trench 101 may be formed in a tapered shape in which an opening width is narrowed from an opening to the bottom wall. A corner portion of the bottom wall of the second connection trench 101 is preferably formed in a curved shape. An entirety of the bottom wall of the second connection trench 101 may be formed in a curved shape toward the second main surface 4. The side wall and the bottom wall of the second connection trench 101 are smoothly connected to the side wall and the bottom wall of the second trench 71B.

The second connection insulating film 102 is formed on a wall surface of the second connection trench 101. Specifically, the second connection insulating film 102 is formed as a film in an entire area of the wall surface of the second connection trench 101 and demarcates a recess space inside the second connection trench 101. The second connection insulating film 102 extends in the first direction X at the first portion 100A of the second connection trench 101. The second connection insulating film 102 extends in the second direction Y at the second portion 100B of the second connection trench 101. The second connection insulating film 102 includes a silicon oxide film. It is in particular preferable that the second connection insulating film 102 includes a silicon oxide film constituted of an oxide of the semiconductor chip 2. As with the first connection insulating film 92, the second connection insulating film 102 has the third thickness T3.

The second connection electrode 103 is embedded as an integrated member in the second connection trench 101 across the second connection insulating film 102. In this embodiment, the second connection electrode 103 includes conductive polysilicon. The second connection electrode 103 extends in the first direction X at the first portion 100A of the second connection trench 101. The second connection electrode 103 extends in the second direction Y at the second portion 100B of the second connection trench 101. The second connection electrode 103 is connected to the second lower electrode 75B at a communicatively connected portion of the second connection trench 101 and the second trench 71B.

The second connection electrode 103 is electrically insulated from the second upper electrode 74B across the second intermediate insulating film 76B. That is, the second connection electrode 103 is constituted of a lead-out portion which is led out to the second connection trench 101 from the second trench 71B across the second connection insulating film 102 and the second intermediate insulating film 76B in the second lower electrode 75B. The second gate signal G2 is transmitted to the second lower electrode 75B via the second connection electrode 103. That is, the same second gate signal G2 is to be applied to the second connection electrode 103 at the same time with the second upper electrode 74B.

The second connection electrode 103 has an electrode surface (second connection electrode surface) which is exposed from the second connection trench 101. The electrode surface of the second connection electrode 103 may be recessed in a curved shape toward the bottom wall of the second connection trench 101. The electrode surface of the second connection electrode 103 is preferably located (protrudes) further on the first main surface 3 side than the depth position of the electrode surface of the upper electrode 74 of the trench structure 61 with regard to a depth direction of the second connection trench 101. The electrode surface of the second connection electrode 103 is preferably at an interval of not less than 0 and less than 2000 Å from the first main surface 3 to the bottom wall of the second connection trench 101. It is in particular preferable that the electrode surface of the second connection electrode 103 is at an interval of less than 1000 Å from the first main surface 3 to the bottom wall of the second connection trench 101.

The second cap insulating film 104 covers the electrode surface (second connection electrode surface) of the second connection electrode 103 as a film inside the second connection trench 101. The second cap insulating film 104 prevents a short circuit of the second connection electrode 103 with another electrode. The second cap insulating film 104 continues to the second connection insulating film 102. The second cap insulating film 104 preferably includes a silicon oxide film. It is in particular preferable that the second cap insulating film 104 includes a silicon oxide film constituted of an oxide of the second connection electrode 103. That is, it is preferable that the second cap insulating film 104 includes an oxide of polysilicon and the second connection insulating film 102 includes an oxide of silicon monocrystal.

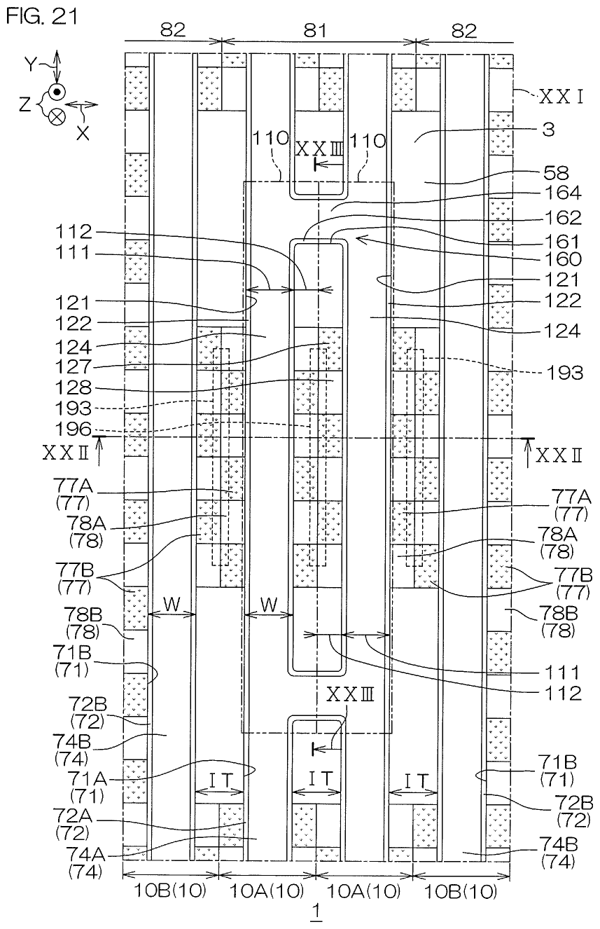

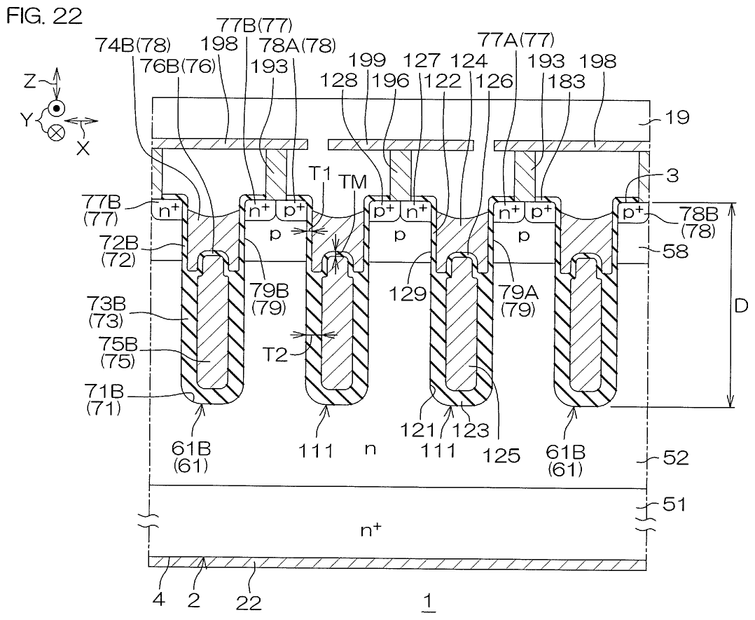

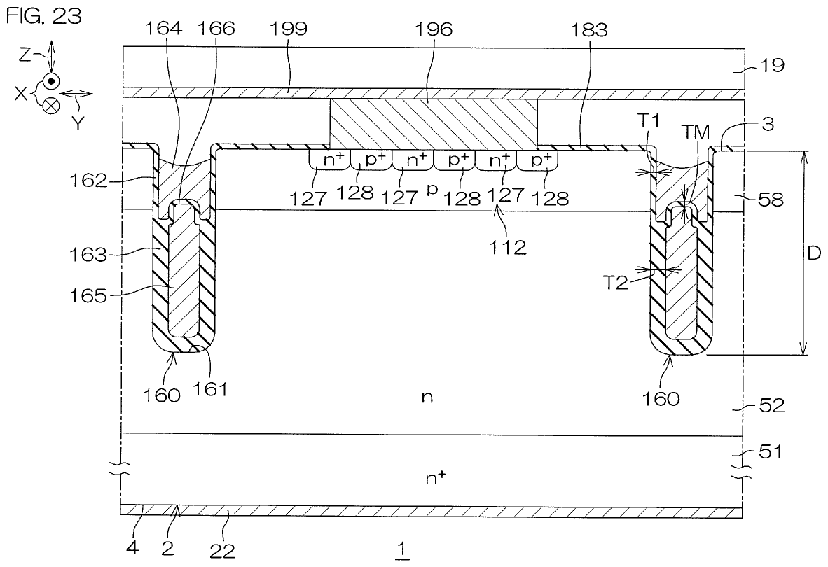

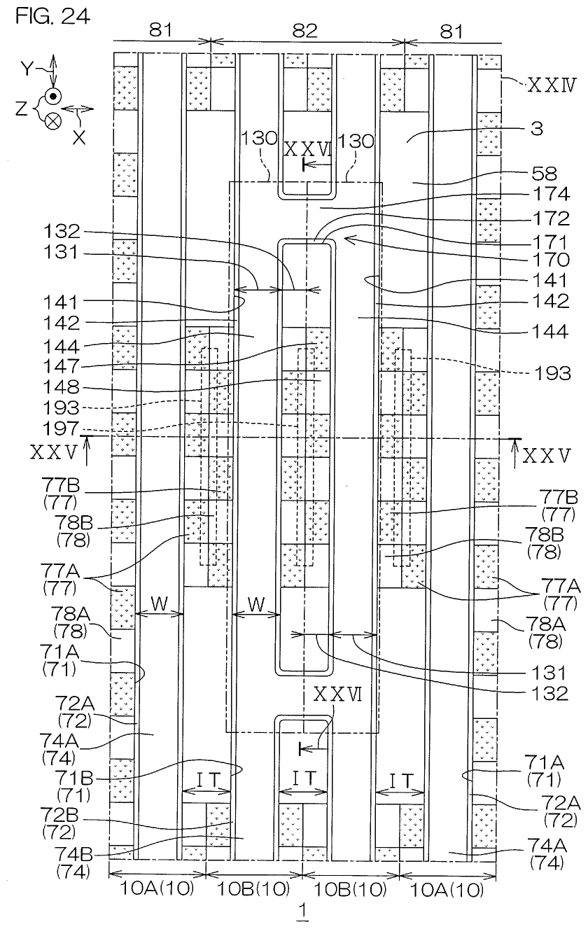

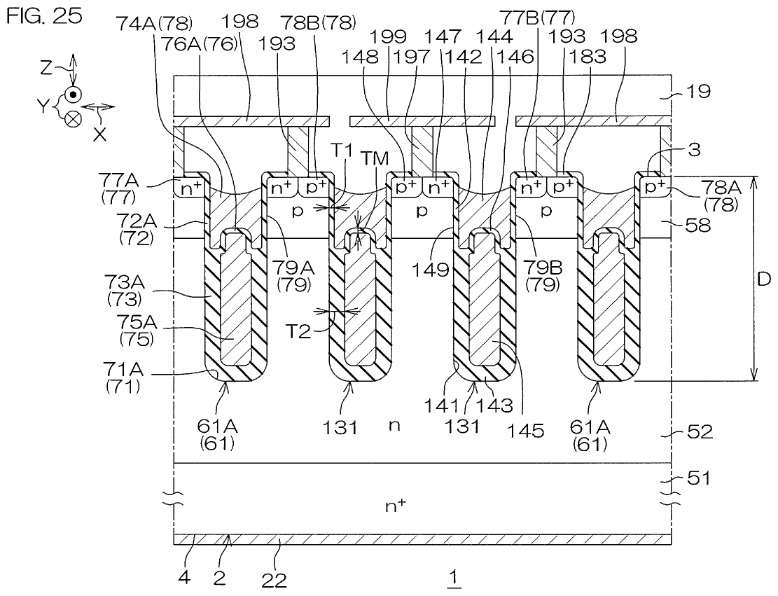

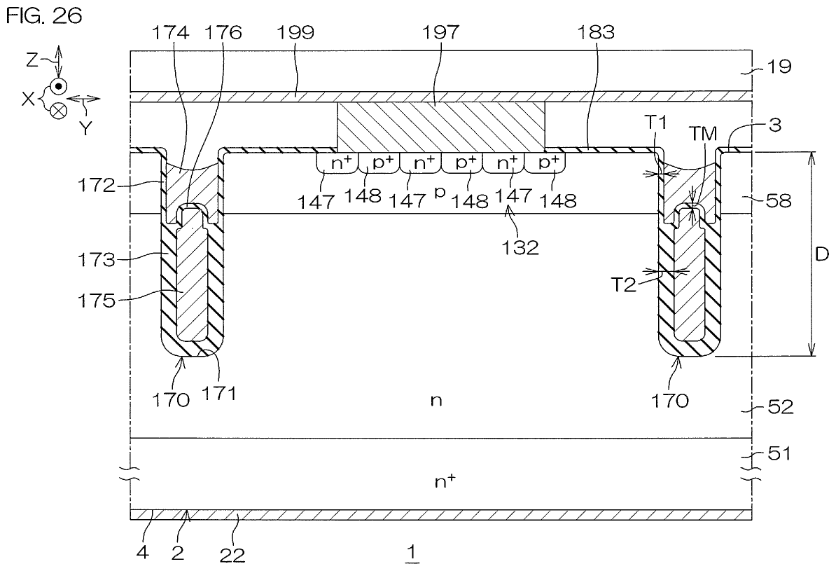

FIG. 21 is an enlarged view of a region XXI shown in FIG. 10. FIG. 22 is a cross-sectional view taken along line XXII-XXII shown in FIG. 21. FIG. 23 is a cross-sectional view taken along line XXIII-XXIII shown in FIG. 21. FIG. 24 is an enlarged view of a region XXIV shown in FIG. 10. FIG. 25 is a cross-sectional view taken along line XXV-XXV shown in FIG. 24. FIG. 26 is a cross-sectional view taken along line XXVI-XXVI shown in FIG. 24.

With reference to FIG. 21 to FIG. 26, the semiconductor device 1 includes the 2-system (m=n=2) monitor transistor 11 formed in the first main surface 3 of the first device region 6. That is, the monitor transistor 11 is formed so as to concentrate on the first main surface 3 of the first device region 6 together with the main transistor 8. The monitor transistor 11 is formed in an inner portion of the first device region 6 (preferably, central portion) at an interval from the trench separation structure 53 in a plan view. The monitor transistor 11 is preferably arranged so as to be sandwiched between the plurality of unit transistors 10 in the first direction X in a plan view.

In this embodiment, the monitor transistor 11 includes a plurality (in this embodiment, four) of unit monitor transistors 13 formed in the first main surface 3 of the first device region 6. That is, the plurality of unit monitor transistors 13 are formed so as to concentrate on the first main surface 3 of the first device region 6 together with the plurality of unit transistors 10. Although the number of the unit monitor transistors 13 is arbitrary, they are preferably provided in an even number.

In this embodiment, the plurality of unit monitor transistors 13 include a plurality (in this embodiment, two) of first unit monitor transistors 13A which are systematized and a plurality (in this embodiment, two) of second unit monitor transistors 13B which are systematized. That is, the plurality of first unit monitor transistors 13A configure the first system monitor transistor 12A, and the plurality of second unit monitor transistors 13B configure the second system monitor transistor 12B.

With reference to FIG. 21 to FIG. 23, the plurality of first unit monitor transistors 13A are aligned in a single row in the first direction X in a plan view and are each formed as a band extending in the second direction Y. The plurality of first unit monitor transistors 13A are formed as a stripe extending in the second direction Y in a plan view. The plurality of first unit monitor transistors 13A are preferably formed by utilizing some regions of the plurality of first unit transistors 10A.

That is, specifically, the plurality of first unit monitor transistors 13A are preferably incorporated into some of the plurality of first unit transistors 10A (at least one first composite cell 81). In this embodiment, the plurality of first unit monitor transistors 13A are incorporated into the first composite cell 81 which is positioned at the seventh as counted from the left side of the sheet surface of FIG. 10. In this embodiment, the plurality of first unit monitor transistors 13A separate one first unit transistor 10A into a region on one side and a region on the other side in the second direction Y in a plan view and are positioned on extension lines of the region on one side of the first unit transistor 10A and the region on the other side thereof.

Specifically, the plurality of first unit monitor transistors 13A are each constituted of a first unit monitor cell 110. Each first unit monitor cell 110 includes one first monitor trench structure 111 and a first monitor channel cell 112 which is controlled by the first monitor trench structure 111. The first monitor trench structure 111 may be referred to as a “monitor gate structure” or a “first monitor trench gate structure.”

Each first monitor trench structure 111 configures the third monitor gate TMG of each first unit monitor transistor 13A. The first monitor channel cell 112 is a region in which opening/closing of a current path is controlled by the first monitor trench structure 111. The first monitor channel cell 112 is electrically separated from the first channel cell 62A and the second channel cell 62B.

The plurality of first monitor trench structures 111 are arrayed at an interval in the first direction X in a plan view and are each formed as a band extending in the second direction Y. That is, the plurality of first monitor trench structures 111 are formed as a stripe extending in the second direction Y in a plan view. The plurality of first monitor trench structures 111 are each connected to the plurality of first trench structures 61A in a one-to-one correspondence with regard to the second direction Y. As with the first trench structure 61A, each first monitor trench structure 111 has the trench width W and the trench depth D. As with the first trench structure 61A, the plurality of first monitor trench structures 111 are arrayed with a trench interval IT kept in the first direction X.

Hereinafter, a description of a configuration of one first monitor trench structure 111 shall be given. The first monitor trench structure 111 has a multi-electrode structure including a first monitor trench 121, a first upper monitor insulating film 122, a first lower monitor insulating film 123, a first upper monitor electrode 124, a first lower monitor electrode 125 and a first intermediate monitor insulating film 126. That is, the first monitor trench structure 111 includes a first embedded monitor electrode (first monitor gate electrode) which is embedded in the first monitor trench 121 across a first embedded monitor insulator. The first embedded monitor insulator is constituted of the first upper monitor insulating film 122, the first lower monitor insulating film 123 and the first intermediate monitor insulating film 126. The first embedded monitor electrode is constituted of the first upper monitor electrode 124 and the first lower monitor electrode 125.

The first monitor trench 121 is dug down from the first main surface 3 toward the second main surface 4 and is formed as a band extending in the first direction X so as to be communicatively connected to the first trench 71A in a plan view. The first monitor trench 121 penetrates through the body region 58 and is formed at an interval from the bottom portion of the second semiconductor region 52 to the first main surface 3 side.

The first monitor trench 121 includes a side wall and a bottom wall. An angle formed between the side wall of the first monitor trench 121 and the first main surface 3 inside the semiconductor chip 2 may be not less than 90° and not more than 92°. The first monitor trench 121 may be formed in a tapered shape in which an opening width is narrowed from an opening to the bottom wall. A corner portion of the bottom wall of the first monitor trench 121 is preferably formed in a curved shape. An entirety of the bottom wall of the first monitor trench 121 may be formed in a curved shape toward the second main surface 4.

The first upper monitor insulating film 122 covers an upper wall surface of the first monitor trench 121. Specifically, the first upper monitor insulating film 122 covers the upper wall surface of the first monitor trench 121 located in a region on the opening side thereof with respect to the bottom portion of the body region 58. The first upper monitor insulating film 122 crosses a boundary between the second semiconductor region 52 and the body region 58. The first upper monitor insulating film 122 has a portion which covers the body region 58 and a portion which covers the second semiconductor region 52. The area covered by the first upper monitor insulating film 122 with regard to the body region 58 is larger than the area covered by the first upper monitor insulating film 122 with regard to the second semiconductor region 52.

The first upper monitor insulating film 122 continues to the first upper insulating film 72A at a communicatively connected portion of the first trench 71A and the first monitor trench 121. With the first upper insulating film 72A, the first upper monitor insulating film 122 forms one insulating film. The first upper monitor insulating film 122 preferably includes the same insulating material (silicon oxide film) as the first upper insulating film 72A. The first upper monitor insulating film 122 is formed as a gate insulating film. As with the first upper insulating film 72A, the first upper monitor insulating film 122 has the first thickness T1.

The first lower monitor insulating film 123 covers a lower wall surface of the first monitor trench 121. Specifically, the first lower monitor insulating film 123 covers the lower wall surface of the first monitor trench 121 which is located in a region on the bottom wall side thereof with respect to the bottom portion of the body region 58. The first lower monitor insulating film 123 demarcates a recess space in a region on the bottom wall side of the first monitor trench 121. The first lower monitor insulating film 123 is in contact with the second semiconductor region 52.

The first lower monitor insulating film 123 continues to the first lower insulating film 73A at the communicatively connected portion of the first trench 71A and the first monitor trench 121. With the first lower insulating film 73A, the first lower monitor insulating film 123 forms one insulating film. The first lower monitor insulating film 123 preferably includes the same insulating material (silicon oxide film) as the first lower insulating film 73A. The first lower monitor insulating film 123 has the second thickness T2, as with the first lower insulating film 73A.

The first upper monitor electrode 124 is embedded on the upper side (opening side) inside the first monitor trench 121 across the first upper monitor insulating film 122. The first upper monitor electrode 124 is embedded as a band extending in the second direction Y in a plan view. The first upper monitor electrode 124 faces the body region 58 and the second semiconductor region 52 across the first upper monitor insulating film 122. A facing of the first upper monitor electrode 124 facing with respect to the body region 58 is larger than a facing area of the first upper monitor electrode 124 with respect to the second semiconductor region 52.

The first upper monitor electrode 124 continues to the first upper electrode 74A at the communicatively connected portion of the first trench 71A and the first monitor trench 121. With the first upper electrode 74A, the first upper monitor electrode 124 forms one electrode. The first upper monitor electrode 124 preferably includes the same electrode material (conductive polysilicon) as the first upper electrode 74A. The first upper monitor electrode 124 is formed as a gate electrode.

The first gate signal G1 is to be input as the first monitor gate signal MG1 into the first upper monitor electrode 124 via the first upper electrode 74A. The first upper monitor electrode 124 has an electrode surface (embedded monitor electrode surface) which is exposed from the first monitor trench 121. The electrode surface of the first upper monitor electrode 124 may be recessed in a curved shape toward the bottom wall of the first monitor trench 121. The electrode surface of the first upper monitor electrode 124 is preferably positioned further on the bottom wall side of the first monitor trench 121 than a depth position of the electrode surface of the separation electrode 56 with regard to a depth direction of the first monitor trench 121.

The electrode surface of the first upper monitor electrode 124 is preferably at an interval of not less than 2000 Å from the first main surface 3 to the bottom wall of the first monitor trench 121 with regard to the depth direction of the first monitor trench 121. It is in particular preferable that the electrode surface of the first upper monitor electrode 124 is at an interval of not less than 2500 Å and not more than 4500 Å from the first main surface 3 to the bottom wall of the first monitor trench 121. In this embodiment, the electrode surface of the first upper monitor electrode 124 continues to the electrode surface of the first upper electrode 74A at a depth position equal to the electrode surface of the first upper electrode 74A.

The first lower monitor electrode 125 is embedded on the lower side (bottom wall side) inside the first monitor trench 121 across the first lower monitor insulating film 123. The first lower monitor electrode 125 is embedded as a band extending in the second direction Y in a plan view. The first lower monitor electrode 125 has a thickness (length) exceeding the thickness (length) of the first upper monitor electrode 124 with regard to the depth direction of the first monitor trench 121. The first lower monitor electrode 125 faces the second semiconductor region 52 across the first lower monitor insulating film 123. The first lower monitor electrode 125 has an upper end portion which protrudes from the first lower monitor insulating film 123 to the first main surface 3 side.

The upper end portion of the first lower monitor electrode 125 meshes with the bottom portion of the first upper monitor electrode 124 and faces the first upper monitor insulating film 122 across the bottom portion of the first upper monitor electrode 124 in a lateral direction along the first main surface 3. The first lower monitor electrode 125 continues to the first lower electrode 75A at the communicatively connected portion of the first trench 71A and the first monitor trench 121. With the first lower electrode 75A, the first lower monitor electrode 125 forms one electrode. The first lower monitor electrode 125 preferably includes the same electrode material (conductive polysilicon) as the first lower electrode 75A.

In this embodiment, the first lower monitor electrode 125 is formed as a gate electrode. The first gate signal G1 is to be input as the first monitor gate signal MG1 into the first lower monitor electrode 125 via the first lower electrode 75A. That is, in this embodiment, the first monitor gate signal MG1 (first gate signal G1) is to be input into the first lower monitor electrode 125 at the same time with the first upper monitor electrode 124. Thereby, since it is possible to suppress a voltage drop between the first upper monitor electrode 124 and the first lower monitor electrode 125, it is possible to suppress an electric field concentration between the first upper monitor electrode 124 and the first lower monitor electrode 125. Also, the semiconductor chip 2 (in particular, second semiconductor region 52) can be decreased in on-resistance.

The first intermediate monitor insulating film 126 is interposed between the first upper monitor electrode 124 and the first lower monitor electrode 125 and electrically insulates the first upper monitor electrode 124 and the first lower monitor electrode 125. Specifically, the first intermediate monitor insulating film 126 covers the first lower monitor electrode 125 exposed from the first lower monitor insulating film 123 in a region between the first upper monitor electrode 124 and the first lower monitor electrode 125. The first intermediate monitor insulating film 126 continues to the first upper monitor insulating film 122 and the first lower monitor insulating film 123.

The first intermediate monitor insulating film 126 continues to the first intermediate insulating film 76A at the communicatively connected portion of the first trench 71A and the first monitor trench 121. The first intermediate monitor insulating film 126 preferably includes the same insulating material (silicon oxide film) as the first intermediate insulating film 76A. As with the first intermediate insulating film 76A, the first intermediate monitor insulating film 126 has the intermediate thickness TM. As described above, the first monitor trench structure 111 is formed in a manner that can be regarded as a part of the first trench structure 61A.

In this embodiment, the first monitor channel cell 112 is formed as a band extending along the corresponding first monitor trench structure 111 in a region that is demarcated by the two first monitor trench structures 111. The first monitor channel cell 112 has a length less than the length of the first monitor trench structure 111 with regard to the second direction Y. An entire area of the first monitor channel cell 112 faces the first upper monitor electrode 124 across the first upper monitor insulating film 122. The first monitor channel cell 112 has a channel width equivalent to a value that is one-half the trench interval IT.

The first monitor channel cell 112 includes at least one n-type first monitor source region 127 which is formed in the surface layer portion of the body region 58. The number of the first monitor source regions 127 included in the first monitor channel cell 112 is arbitrary. In this embodiment, the first monitor channel cell 112 includes the plurality of first monitor source regions 127. All of the first monitor source regions 127 included in each first unit monitor cell 110 form the third monitor source TMS of each first unit monitor transistor 13A.

An n-type impurity concentration of the plurality of first monitor source regions 127 is substantially equal to the n-type impurity concentration of the first source region 77A. The plurality of first monitor source regions 127 are formed in a region on the first main surface 3 side at an interval from the bottom portion of the body region 58 and face the first upper monitor electrode 124 across the first upper monitor insulating film 122. The plurality of first monitor source regions 127 are arrayed at an interval in the second direction Y in the first monitor channel cell 112. That is, the plurality of first monitor source regions 127 are arrayed at an interval along the corresponding first monitor trench structure 111.

The first monitor channel cell 112 includes at least one p-type first monitor contact region 128 which is formed in a region different from the first monitor source region 127 at the surface layer portion of the body region 58. The number of the first monitor contact regions 128 included in the first monitor channel cell 112 is arbitrary. In this embodiment, the first monitor channel cell 112 includes the plurality of first monitor contact regions 128. A p-type impurity concentration of the first monitor contact region 128 is substantially equal to the p-type impurity concentration of the first contact region 78A.

The plurality of first monitor contact regions 128 are formed in a region on the first main surface 3 side at an interval from the bottom portion of the body region 58 and face the first upper monitor electrode 124 across the first upper monitor insulating film 122. The plurality of first monitor contact regions 128 are formed alternately with the plurality of first monitor source regions 127 in the second direction Y in a manner that one first monitor source region 127 is sandwiched therebetween. That is, the plurality of first monitor contact regions 128 are arrayed at an interval along the corresponding first monitor trench structure 111.

The first monitor channel cell 112 includes a plurality of first monitor channel regions 129 which are formed between the plurality of first monitor source regions 127 and the second semiconductor region 52 inside the body region 58. On/off control of the plurality of first monitor channel regions 129 in the first monitor channel cell 112 is performed by one first monitor trench structure 111. The plurality of first monitor channel regions 129 included in the first monitor channel cell 112 form one channel of the first unit monitor transistor 13A. Thereby, one first unit monitor cell 110 functions as one first unit monitor transistor 13A.

The plurality of first monitor channel regions 129 (first monitor source region 127) arrayed on the side of one of the first monitor trench structures 111 in a region between the plurality of first monitor trench structures 111 preferably face a region between the plurality of first monitor channel regions 129 (first monitor source region 127) arrayed on the side of the other of the first monitor trench structures 111 in the first direction X. According to this structure, it is possible to thin out starting points of heating in the first unit monitor cell 110.

In this embodiment, the first unit cell 60A in which the first unit monitor cell 110 is incorporated includes a first channel cell 62A (hereinafter, referred to as the “monitor-side first channel cell 62A”) which is controlled by the first monitor trench structure 111. The monitor-side first channel cell 62A faces the first monitor channel cell 112 across the first monitor trench structure 111.

The monitor-side first channel cell 62A preferably has a layout (length and channel area) corresponding to the first monitor channel cell 112. In the monitor-side first channel cell 62A, the plurality of first channel regions 79A (first source regions 77A) preferably face the plurality of first monitor channel regions 129 (first monitor source regions 127) across the first monitor trench structure 111.

The second unit cell 60B which is mutually adjacent to the first unit monitor cell 110 includes the second channel cell 62B (hereinafter, referred to as the “monitor-side second channel cell 62B”) adjacent to the monitor-side first channel cell 62A. The monitor-side second channel cell 62B preferably has a layout (length and channel area) corresponding to the monitor-side first channel cell 62A with regard to the second direction Y. In the monitor-side second channel cell 62B, the plurality of second channel regions 79B (second source regions 77B) preferably face a region between the plurality of first channel regions 79A (first source regions 77A) in the first direction X.

With reference to FIG. 24 to FIG. 26, the plurality of second unit monitor transistors 13B are aligned in a single row in the first direction X in a plan view and are each formed as a band extending in the second direction Y. The plurality of second unit monitor transistors 13B are formed as a stripe extending in the second direction Y in a plan view. The second unit monitor transistor 13B may be arranged so as to be mutually adjacent to the first unit monitor transistor 13A with regard to the first direction X. The second unit monitor transistor 13B may be arranged at an interval corresponding to at least one first composite cell 81 and at least one second composite cell 82 from the first unit monitor transistor 13A.

That is, the second unit monitor transistor 13B may face the first unit monitor transistor 13A in the first direction X across at least one first composite cell 81 and at least one second composite cell 82. In this embodiment, the plurality of second unit monitor transistors 13B face the first unit monitor transistor 13A across one first composite cell 81 and one second composite cell 82. The second unit monitor transistor 13B is preferably formed by utilizing some regions of the second unit transistor 10B.

Specifically, the plurality of second unit monitor transistors 13B are preferably incorporated into some of the plurality of second unit transistors 10B (at least one second composite cell 82). In this embodiment, the plurality of second unit monitor transistors 13B are incorporated into the second composite cell 82 which is positioned at the fifth as counted from the left side of the sheet surface of FIG. 10. In this embodiment, the plurality of second unit monitor transistors 13B separate one second unit transistor 10B into a region on one side and a region on the other side in the second direction Y in a plan view and are positioned on extension lines of the region on one side of the second unit transistor 10B and the region on the other side thereof.

Specifically, the plurality of second unit monitor transistors 13B are each constituted of a second unit monitor cell 130. Each of the second unit monitor cells 130 includes one second monitor trench structure 131 and a second monitor channel cell 132 which is controlled by the second monitor trench structure 131. The second monitor trench structure 131 may be referred to as a “second monitor trench gate structure.”

Each second monitor trench structure 131 configures the third monitor gate TMG of each second unit monitor transistor 13B. The second monitor channel cell 132 is a region in which opening/closing of a current path is controlled by the second monitor trench structure 131. The second monitor channel cell 132 is electrically separated from the first channel cell 62A, the second channel cell 62B and the first monitor channel cell 112.

The plurality of second monitor trench structures 131 are arrayed at an interval in the first direction X in a plan view and are each formed as a band extending in the second direction Y. That is, the plurality of second monitor trench structures 131 are formed as a stripe extending in the second direction Y in a plan view. The plurality of second monitor trench structures 131 are each communicatively connected to the plurality of second trench structures 61B with regard to the second direction Y in a one-to-one correspondence. As with the second trench structure 61B, each second monitor trench structure 131 has the trench width W and the trench depth D. The plurality of second monitor trench structures 131 are arrayed with the trench interval IT kept in the first direction X, as with the second trench structure 61B.

Hereinafter, a description of a configuration of one second monitor trench structure 131 shall be given. The second monitor trench structure 131 has a multi-electrode structure including a second monitor trench 141, a second upper monitor insulating film 142, a second lower monitor insulating film 143, a second upper monitor electrode 144, a second lower monitor electrode 145 and a second intermediate monitor insulating film 146. That is, the second monitor trench structure 131 includes a second embedded monitor electrode (second monitor gate electrode) which is embedded in the second monitor trench 141 across a second embedded monitor insulator. The second embedded monitor insulator is constituted of the second upper monitor insulating film 142, the second lower monitor insulating film 143 and the second intermediate monitor insulating film 146. The second embedded monitor electrode is constituted of the second upper monitor electrode 144 and the second lower monitor electrode 145.

The second monitor trench 141 is dug down from the first main surface 3 toward the second main surface 4 and is formed as a band extending in the first direction X so as to be communicatively connected to the second trench 71B in a plan view. The second monitor trench 141 penetrates through the body region 58 and is formed at an interval from the bottom portion of the second semiconductor region 52 to the first main surface 3 side.

The second monitor trench 141 includes a side wall and a bottom wall. An angle formed between the side wall of the second monitor trench 141 and the first main surface 3 inside the semiconductor chip 2 may be not less than 90° and not more than 92°. The second monitor trench 141 may be formed in a tapered shape in which an opening width is narrowed from an opening to the bottom wall. A corner portion of the bottom wall of the second monitor trench 141 is preferably formed in a curved shape. An entirety of the bottom wall of the second monitor trench 141 may be formed in a curved shape toward the second main surface 4.

The second upper monitor insulating film 142 covers an upper wall surface of the second monitor trench 141. Specifically, the second upper monitor insulating film 142 covers the upper wall surface of the second monitor trench 141 which is located in a region on the opening side thereof with respect to the bottom portion of the body region 58. The second upper monitor insulating film 142 crosses a boundary between the second semiconductor region 52 and the body region 58. The second upper monitor insulating film 142 has a portion which covers the body region 58 and a portion which covers the second semiconductor region 52. The area covered by the second upper monitor insulating film 142 with regard to the body region 58 is larger than the area covered by the second upper monitor insulating film 142 with regard to the second semiconductor region 52.

The second upper monitor insulating film 142 continues to the second upper insulating film 72B at a communicatively connected portion of the second trench 71B and the second monitor trench 141. With the second upper insulating film 72B, the second upper monitor insulating film 142 forms one insulating film. The second upper monitor insulating film 142 preferably includes the same insulating material (silicon oxide film) as the second upper insulating film 72B. The second upper monitor insulating film 142 is formed as a gate insulating film. As with the second upper insulating film 72B, the second upper monitor insulating film 142 has the first thickness T1.

The second lower monitor insulating film 143 covers a lower wall surface of the second monitor trench 141. Specifically, the second lower monitor insulating film 143 covers the lower wall surface of the second monitor trench 141 which is located in a region on the bottom wall side thereof with respect to the bottom portion of the body region 58. The second lower monitor insulating film 143 demarcates a recess space in a region on the bottom wall side of the second monitor trench 141. The second lower monitor insulating film 143 is in contact with the second semiconductor region 52.

The second lower monitor insulating film 143 continues to the second lower insulating film 73B at the communicatively connected portion of the second trench 71B and the second monitor trench 141. With the second lower insulating film 73B, the second lower monitor insulating film 143 forms one insulating film. The second lower monitor insulating film 143 preferably includes the same insulating material (silicon oxide film) as the second lower insulating film 73B. As with the second lower insulating film 73B, the second lower monitor insulating film 143 has the second thickness T2.

The second upper monitor electrode 144 is embedded on the upper side (opening side) inside the second monitor trench 141 across the second upper monitor insulating film 142. The second upper monitor electrode 144 is embedded as a band extending in the second direction Y in a plan view. The second upper monitor electrode 144 faces the body region 58 and the second semiconductor region 52 across the second upper monitor insulating film 142. A facing area of the second upper monitor electrode 144 with respect to the body region 58 is larger than a facing area of the second upper monitor electrode 144 with respect to the second semiconductor region 52.

The second upper monitor electrode 144 continues to the second upper electrode 74B at the communicatively connected portion of the second trench 71B and the second monitor trench 141. With the second upper electrode 74B, the second upper monitor electrode 144 forms one electrode. The second upper monitor electrode 144 preferably includes the same electrode material (conductive polysilicon) as the second upper electrode 74B. The second upper monitor electrode 144 is formed as a gate electrode.

The second gate signal G2 is to be input as the second monitor gate signal MG2 into the second upper monitor electrode 144 via the second upper electrode 74B. The second upper monitor electrode 144 has an electrode surface (embedded monitor electrode surface) which is exposed from the second monitor trench 141. The electrode surface of the second upper monitor electrode 144 may be recessed in a curved shape toward the bottom wall of the second monitor trench 141. The electrode surface of the second upper monitor electrode 144 is preferably positioned further on the bottom wall side of the second monitor trench 141 than the depth position of the electrode surface of the separation electrode 56 with regard to a depth direction of the second monitor trench 141.

The electrode surface of the second upper monitor electrode 144 is preferably at an interval of not less than 2000 Å from the first main surface 3 to the bottom wall of the second monitor trench 141 with regard to the depth direction of the second monitor trench 141. It is in particular preferable that the electrode surface of the second upper monitor electrode 144 is at an interval of not less than 2500 Å and not more than 4500 Å from the first main surface 3 to the bottom wall of the second monitor trench 141. The electrode surface of the second upper monitor electrode 144 continues to the electrode surface of the second upper electrode 74B at a depth position equal to the electrode surface of the second upper electrode 74B.

The second lower monitor electrode 145 is embedded on the lower side (bottom wall side) inside the second monitor trench 141 across the second lower monitor insulating film 143. The second lower monitor electrode 145 is embedded as a band extending in the second direction Y in a plan view. The second lower monitor electrode 145 has a thickness (length) exceeding the thickness (length) of the second upper monitor electrode 144 with regard to the depth direction of the second monitor trench 141. The second lower monitor electrode 145 faces the second semiconductor region 52 across the second lower monitor insulating film 143. The second lower monitor electrode 145 has an upper end portion which protrudes from the second lower monitor insulating film 143 to the first main surface 3 side.

The upper end portion of the second lower monitor electrode 145 meshes with the bottom portion of the second upper monitor electrode 144 and faces the second upper monitor insulating film 142 across the bottom portion of the second upper monitor electrode 144 in a lateral direction along the first main surface 3. The second lower monitor electrode 145 continues to the second lower electrode 75B at the communicatively connected portion of the second trench 71B and the second monitor trench 141. With the second lower electrode 75B, the second lower monitor electrode 145 forms one electrode. The second lower monitor electrode 145 preferably includes the same electrode material (conductive polysilicon) as the second lower electrode 75B.

In this embodiment, the second lower monitor electrode 145 is formed as a gate electrode. The second gate signal G2 is to be input as the second monitor gate signal MG2 into the second lower monitor electrode 145 via the second lower electrode 75B. That is, in this embodiment, the second monitor gate signal MG2 (second gate signal G2) is to be input into the second lower monitor electrode 145 at the same time with the second upper monitor electrode 144. Thereby, since it is possible to suppress a voltage drop between the second upper monitor electrode 144 and the second lower monitor electrode 145, it is possible to suppress an electric field concentration between the second upper monitor electrode 144 and the second lower monitor electrode 145. Also, the semiconductor chip 2 (in particular, second semiconductor region 52) can be decreased in on-resistance.

The second intermediate monitor insulating film 146 is interposed between the second upper monitor electrode 144 and the second lower monitor electrode 145 and electrically insulates the second upper monitor electrode 144 and the second lower monitor electrode 145. Specifically, the second intermediate monitor insulating film 146 covers the second lower monitor electrode 145 which is exposed from the second lower monitor insulating film 143 in a region between the second upper monitor electrode 144 and the second lower monitor electrode 145. The second intermediate monitor insulating film 146 continues to the second upper monitor insulating film 142 and the second lower monitor insulating film 143.

The second intermediate monitor insulating film 146 continues to the second intermediate insulating film 76B at the communicatively connected portion of the second trench 71B and the second monitor trench 141. The second intermediate monitor insulating film 146 preferably includes the same insulating material (silicon oxide film) as the second intermediate insulating film 76B. As with the second intermediate insulating film 76B, the second intermediate monitor insulating film 146 has the intermediate thickness TM. As described above, the second monitor trench structure 131 is formed in a manner that can be regarded as a part of the second trench structure 61B.

In this embodiment, the second monitor channel cell 132 is formed as a band extending along the corresponding second monitor trench structure 131 in a region which is demarcated by the two second monitor trench structures 131. The second monitor channel cell 132 has a length less than the length of the second monitor trench structure 131 with regard to the second direction Y. An entire area of a pair of the second monitor channel cells 132 faces the second upper monitor electrode 144 across the second upper monitor insulating film 142. The second monitor channel cell 132 has a channel width equivalent to a value that is one-half the trench interval IT.

The second monitor channel cell 132 includes at least one n-type second monitor source region 147 which is formed in the surface layer portion of the body region 58. The number of the second monitor source regions 147 included in the second monitor channel cell 132 is arbitrary. In this embodiment, the second monitor channel cell 132 includes the plurality of second monitor source regions 147. All of the second monitor source regions 147 included in each second unit monitor cell 130 form the third monitor source TMS of each second unit monitor transistor 13B.

An n-type impurity concentration of the plurality of second monitor source regions 147 is substantially equal to the n-type impurity concentration of the second source region 77B. The plurality of second monitor source regions 147 are formed in a region on the first main surface 3 side at an interval from the bottom portion of the body region 58 and face the second upper monitor electrode 144 across the second upper monitor insulating film 142. The plurality of second monitor source regions 147 are arrayed at an interval in the second direction Y in the second monitor channel cell 132. That is, the plurality of second monitor source regions 147 are arrayed, at an interval along the corresponding second monitor trench structure 131.

The second monitor channel cell 132 includes at least one p-type second monitor contact region 148 which is formed in a region different from the second monitor source region 147 at the surface layer portion of the body region 58. The number of the second monitor contact regions 148 included in the second monitor channel cell 132 is arbitrary. In this embodiment, the second monitor channel cell 132 includes the plurality of second monitor contact regions 148. A p-type impurity concentration of the second monitor contact region 148 exceeds the p-type impurity concentration of the body region 58. The p-type impurity concentration of the second monitor contact region 148 is substantially equal to the p-type impurity concentration of the second contact region 78B.

The plurality of second monitor contact regions 148 are formed in a region on the first main surface 3 side at an interval from the bottom portion of the body region 58 and face the second upper monitor electrode 144 across the second upper monitor insulating film 142. The plurality of second monitor contact regions 148 are formed alternately with the plurality of second monitor source regions 147 in the second direction Y in a manner that one second monitor source region 147 is sandwiched therebetween. That is, the plurality of second monitor contact regions 148 are arrayed at an interval along the corresponding second monitor trench structure 131.

The second monitor channel cell 132 includes a plurality of second monitor channel regions 149 which are formed between the plurality of second monitor source regions 147 and the second semiconductor region 52 inside the body region 58. On/off control of the plurality of second monitor channel regions 149 in the second monitor channel cell 132 is performed by one second monitor trench structure 131. The plurality of second monitor channel regions 149 included in the pair of second monitor channel cells 132 form one channel of the second unit monitor transistor 13B. Thereby, one second unit monitor cell 130 functions as one second unit monitor transistor 13B.

The plurality of second monitor channel regions 149 (second monitor source regions 147) which are arrayed on the side of one of the second monitor trench structures 131 in a region between the plurality of second monitor trench structures 131 preferably face a region between the plurality of second monitor channel regions 149 (second monitor source region 147) which are arrayed on the side of the other of the second monitor trench structures 131 in the first direction X. According to this structure, it is possible to thin out starting points of heating in the second unit monitor cell 130.

In this embodiment, the second unit cell 60B in which the second unit monitor cell 130 is incorporated includes the second channel cell 62B (hereinafter, referred to as the “monitor-side second channel cell 62B”) which is controlled by the second monitor trench structure 131. The monitor-side second channel cell 62B faces the second monitor channel cell 132 across the second monitor trench structure 131.

The monitor-side second channel cell 62B preferably has a layout (length and channel area) corresponding to the second monitor channel cell 132 with regard to the second direction Y. In the monitor-side second channel cell 62B, the plurality of second channel regions 79B (second source regions 77B) preferably face the plurality of second monitor channel regions 149 (second monitor source regions 147) across the second monitor trench structure 131.

The first unit cell 60A which is mutually adjacent to the second unit monitor cell 130 includes the first channel cell 62A which is adjacent to the monitor-side second channel cell 62B (hereinafter, referred to as the “monitor-side first channel cell 62A”). The monitor-side first channel cell 62A preferably has a layout (length and channel area) corresponding to the monitor-side second channel cell 62B with regard to the second direction Y. In the monitor-side first channel cell 62A, the plurality of first channel regions 79A (first source regions 77A) preferably face a region between the plurality of second monitor channel regions 149 (second monitor source regions 147) in the first direction X.

The n-system monitor transistor 11 has a total monitor channel ratio RMT. The total monitor channel ratio RMT is a ratio of a total planar area of all of the first monitor channel regions 129 and all of the second monitor channel regions 149 which occupies a total planar area of the first monitor channel cell 112 and the second monitor channel cell 132. A planar area of each first monitor channel region 129 is defined by a planar area of each first monitor source region 127, and a planar area of each second monitor channel region 149 is defined by a planar area of each second monitor source region 147. The total monitor channel ratio RMT is adjusted in a range of more than 0% and less than 100%. The total monitor channel ratio RMT is preferably adjusted in a range of not less than 25% and not more than 75%.

The total monitor channel ratio RMT is divided into an n-number of system channel ratios RMS by the n-number of the system monitor transistors 12. The total monitor channel ratio RMT of the 2-system monitor transistor 11 is constituted of an added value (RT=RSMA+RSMB) of a first system monitor channel ratio RMSA of the first system monitor transistor 12A and a second system monitor channel ratio RMSB of the second system monitor transistor 12B.

The first system monitor channel ratio RMSA is a ratio of a total planar area of all of the first monitor channel regions 129 which occupies a total planar area of the first monitor channel cell 112 and the second monitor channel cell 132. The second system monitor channel ratio RMSB is a ratio of a total planar area of all of the second monitor channel regions 149 which occupies a total planar area of the first monitor channel cell 112 and the second monitor channel cell 132. The first system monitor channel ratio RMSA is adjusted by an arrayed pattern of the first monitor source region 127 and the first monitor contact region 128. The second system monitor channel ratio RMSB is adjusted by an arrayed pattern of the second monitor source region 147 and the second monitor contact region 148.

A value of the first system monitor channel ratio RMSA may be not less than a value of the first system channel ratio RSA of the first system transistor 9A (RMSA≥RSA) or may be less than a value of the first system channel ratio RSA (RMSA<RSA). The value of the first system monitor channel ratio RMSA is preferably substantially equal to the value of the first system channel ratio RSA (RMSA≈RSA). That is, it is preferable that a ratio of a planar area of the first monitor channel region 129 which occupies a unit planar area of the first unit monitor transistor 13A is substantially equal to a ratio of a planar area of the first channel region 79A which occupies a unit planar area of the first unit transistor 10A.

The second system monitor channel ratio RMSB may be not less than the first system monitor channel ratio RMSA (RMSA≤RSMB) or may be less than the first system monitor channel ratio RMSA (RMSA>RSMB). As a matter of course, the second system monitor channel ratio RMSB may be substantially equal to the first system monitor channel ratio RMSA (RMSA≈RSMB).

A value of the second system monitor channel ratio RMSB may be not less than a value of the second system channel ratio RSB of the second system transistor 9B (RMSB≥RSB) or may be less than a value of the second system channel ratio RSB (RMSB<RSB). It is preferable that the value of the second system monitor channel ratio RMSB is set at a value substantially equal to a value of the second system channel ratio RSB (RMSB≈RSB). That is, it is preferable that a ratio of a planar area of the second monitor channel region 149 which occupies a unit planar area of the second unit monitor transistor 13B is substantially equal to a ratio of a planar area of the second channel region 79B which occupies a unit planar area of the second unit transistor 10B.

A ratio RSB/RMSB which is a ratio of the second system monitor channel ratio RMSB to the second system channel ratio RSB may be not less than a ratio RSA/RMSA which is a ratio of the first system monitor channel ratio RMSA to the first system channel ratio RSA (RSA/RMSA≤RSB/RMSB), or may be less than the ratio RSB/RMSB (RSA/RMSA>RSB/RMSB). The ratio RSB/RMSB is preferably substantially equal to the ratio RSA/RMSA (RSA/RMSA≈RSB/RMSB).

Where the first system channel ratio RSA is 25% and the second system channel ratio RSB is 25% (see FIG. 17), the first system monitor channel ratio RMSA may be 25% and the second system monitor channel ratio RMSB may be 25%. Where the first system channel ratio RSA is 37.5% and the second system channel ratio RSB is 12.5% (see FIG. 18), the first system monitor channel ratio RMSA may be 37.5% and the second system monitor channel ratio RMSB may be 12.5%.

Where the first system channel ratio RSA is 24.7% and the second system channel ratio RSB is 8.3% (see FIG. 19), the first system monitor channel ratio RMSA may be 24.7% and the second system monitor channel ratio RMSB may be 8.3%. Where the first system channel ratio RSA is 18.7% and the second system channel ratio RSB is 6.3% (see FIG. 20), the first system monitor channel ratio RMSA may be 18.7% and the second system monitor channel ratio RMSB may be 6.3%.

By making the value of the first system monitor channel ratio RMSA substantially match the value of the first system channel ratio RSA and making the value of the second system monitor channel ratio RMSB substantially match the value of the second system channel ratio RSB, it is made possible to appropriately create the system monitor current ISM that is proportional to the system current IS. Therefore, it is possible to create the output monitor current TOM which is proportional to the output current IO and is capable of appropriately monitoring the output current IO in the monitor transistor 11.

The monitor transistor 11 includes a plurality (in this embodiment, one pair, a total of two) of first monitor trench connection structures 160 which are formed in the first main surface 3 in the first device region 6. The plurality of first monitor trench connection structures 160 are formed in a region between the two first monitor trench structures 111 that configure the first composite cell 81. The plurality of first monitor trench connection structures 160 are formed at an interval so as to sandwich the first monitor channel cell 112 therebetween in the second direction Y in a plan view and are each formed as a band extending in the first direction X.

The plurality of first monitor trench connection structures 160 are connected to the two first monitor trench structures 111 that configure the first composite cell 81 and electrically separate the first monitor channel cell 112 from the first channel cell 62A. That is, the plurality of first monitor trench connection structures 160 demarcate a region which is sandwiched between the two first monitor trench structures 111 from a region which is sandwiched between the two first trench structures 61A. That is, the plurality of first monitor trench connection structures 160 divide the first composite cell 81 into three regions.

With the plurality of first monitor trench structures 111, the plurality of first monitor trench connection structures 160 configure one annular-shaped trench structure. The plurality of first monitor trench connection structures 160 are formed at an interval from the first channel cell 62A and the first monitor channel cell 112 with regard to the second direction Y and face the first channel cell 62A and the first monitor channel cell 112 across the body region 58.

In this embodiment, the plurality of first monitor trench connection structures 160 are connected only to the body region 58 with regard to the first direction X and the second direction Y and are not connected to the first channel cell 62A, the second channel cell 62B, the first monitor channel cell 112 and the second monitor channel cell 132 in the first direction X and in the second direction Y. As with the first trench structure 61A, each first monitor trench connection structure 160 has the trench width W and the trench depth D. The trench width W of the first monitor trench connection structure 160 is a width of the first monitor trench connection structure 160 in the second direction Y.

Each first monitor trench connection structure 160 has a multi-electrode structure including a first monitor connection trench 161, a first upper monitor connection insulating film 162, a first lower monitor connection insulating film 163, a first upper monitor connection electrode 164, a first lower monitor connection electrode 165 and a first intermediate monitor connection insulating film 166.

The first monitor connection trench 161, the first upper monitor connection insulating film 162, the first lower monitor connection insulating film 163, the first upper monitor connection electrode 164, the first lower monitor connection electrode 165 and the first intermediate monitor connection insulating film 166 each have a structure respectively corresponding to the first monitor trench 121, the first upper monitor insulating film 122, the first lower monitor insulating film 123, the first upper monitor electrode 124, the first lower monitor electrode 125 and the first intermediate monitor insulating film 126 of the first monitor trench structure 111. Hereinafter, a description of a structure different from the first monitor trench structure 111 in the first monitor trench connection structure 160 shall be given.

The first monitor connection trench 161 is communicatively connected to the first monitor trench 121. That is, the first monitor connection trench 161 is also communicatively connected to the first trench 71A. The first upper monitor connection insulating film 162 is connected to the first upper insulating film 72A and the first upper monitor insulating film 122 at a communicatively connected portion of the first monitor trench 121 and the first monitor connection trench 161. The first lower monitor connection insulating film 163 is connected to the first lower insulating film 73A and the first lower monitor insulating film 123 at the communicatively connected portion of the first monitor trench 121 and first monitor connection trench 161.

The first upper monitor connection electrode 164 is connected to the first upper electrode 74A and the first upper monitor electrode 124 at the communicatively connected portion of the first monitor trench 121 and the first monitor connection trench 161. The first lower monitor connection electrode 165 is connected to the first lower electrode 75A and the first lower monitor electrode 125 at the communicatively connected portion of the first monitor trench 121 and the first monitor connection trench 161. The first intermediate monitor connection insulating film 166 is connected to the first intermediate insulating film 76A and the first intermediate monitor insulating film 126 at the communicatively connected portion of the first monitor trench 121 and the first monitor connection trench 161.

The monitor transistor 11 includes a plurality (in this embodiment, one pair, a total of two) of second monitor trench connection structures 170 which are formed in the first main surface 3 in the first device region 6. The plurality of second monitor trench connection structures 170 are formed in a region between the two second monitor trench structures 131 which configure the first composite cell 81. The plurality of second monitor trench connection structures 170 are formed at an interval so as to sandwich the second monitor channel cell 132 therebetween in the second direction Y in a plan view and are each formed as a band extending in the first direction X.

The plurality of second monitor trench connection structures 170 are connected to the two second monitor trench structures 131 which configure the first composite cell 81 and electrically separate the second monitor channel cell 132 from the second channel cell 62B. That is, the plurality of second monitor trench connection structures 170 demarcate a region sandwiched between the two second monitor trench structure 131 from a region sandwiched between the two second trench structures 61B. That is, the plurality of second monitor trench connection structures 170 divide the second composite cell 82 into three regions.

With the plurality of second monitor trench structures 131, the plurality of second monitor trench connection structures 170 configure one annular-shaped trench structure. The plurality of second monitor trench connection structures 170 are formed at an interval from the second channel cell 62B and the second monitor channel cell 132 with regard to the second direction Y and face the second channel cell 62B and the second monitor channel cell 132 across the body region 58.

In this embodiment, the plurality of second monitor trench connection structures 170 are connected only to the body region 58 with regard to the first direction X and the second direction Y and are not connected to the first channel cell 62A, the second channel cell 62B, the first monitor channel cell 112 and the second monitor channel cell 132 in the first direction X and the second direction Y. As with the second trench structure 61B, each second monitor trench connection structure 170 has the trench width W and the trench depth D. The trench width W of the second monitor trench connection structure 170 is a width of the second monitor trench connection structure 170 in the second direction Y.

Each second monitor trench connection structure 170 has a multi-electrode structure including a second monitor connection trench 171, a second upper monitor connection insulating film 172, a second lower monitor connection insulating film 173, a second upper monitor connection electrode 174, a second lower monitor connection electrode 175 and a second intermediate monitor connection insulating film 176.

The second monitor connection trench 171, the second upper monitor connection insulating film 172, the second lower monitor connection insulating film 173, the second upper monitor connection electrode 174, the second lower monitor connection electrode 175 and the second intermediate monitor connection insulating film 176 each have a structure respectively corresponding to the second monitor trench 141, the second upper monitor insulating film 142, the second lower monitor insulating film 143, the second upper monitor electrode 144, the second lower monitor electrode 145 and the second intermediate monitor insulating film 146 of the second monitor trench structure 131. Hereinafter, a description of a structure different from the second monitor trench structure 131 in the second monitor trench connection structure 170 shall be given.

The second monitor connection trench 171 is communicatively connected to the second monitor trench 141. That is, the second monitor connection trench 171 is also communicatively connected to the second trench 71B. The second upper monitor connection insulating film 172 is connected to the second upper insulating film 72B and the second upper monitor insulating film 142 at a communicatively connected portion of the second monitor trench 141 and the second monitor connection trench 171. The second lower monitor connection insulating film 173 is connected to the second lower insulating film 73B and the second lower monitor insulating film 143 at the communicatively connected portion of the second monitor trench 141 and the second monitor connection trench 171.

The second upper monitor connection electrode 174 is connected to the second upper electrode 74B and the second upper monitor electrode 144 at the communicatively connected portion of the second monitor trench 141 and the second monitor connection trench 171. The second lower monitor connection electrode 175 is connected to the second lower electrode 75B and the second lower monitor electrode 145 at the communicatively connected portion of the second monitor trench 141 and the second monitor connection trench 171. The second intermediate monitor connection insulating film 176 is connected to the second intermediate insulating film 76B and the second intermediate monitor insulating film 146 at the communicatively connected portion of the second monitor trench 141 and the second monitor connection trench 171.

The semiconductor device 1 includes a body space 180 which is formed along an inner periphery (inner peripheral wall) of the trench separation structure 53 in the first device region 6. The body space 180 is constituted of a part of the body region 58. The body space 180 is formed as a band extending along the main transistor 8 in a plan view. Specifically, the body space 180 is formed in an annular shape which surrounds the main transistor 8 in a plan view.

The body space 180 has a space width WSP. The space width WSP may be not less than the separation width WI (WI≤WSP) or may be less than the separation width WI (WSP<WI). The body space 180 preferably has the substantially constant space width WSP, with the inner periphery of the trench separation structure 53 given as a reference. The space width WSP may be not less than 1 μm and not more than 2.5 μm. The space width WSP is preferably not less than 1.2 μm and not more than 2 μm.

The semiconductor device 1 includes a field insulating film 181 which partially covers the first main surface 3 in the first device region 6. The field insulating film 181 is formed at an interval from the main transistor 8 to the trench separation structure 53 side in a plan view and covers a periphery of the trench separation structure 53. That is, the field insulating film 181 covers the body space 180 (body region 58). The field insulating film 181 faces the second semiconductor region 52 (first semiconductor region 51) across the body space 180 (body region 58) at a peripheral edge portion of the first device region 6. The field insulating film 181 includes a silicon oxide film. It is in particular preferable that the field insulating film 181 includes a silicon oxide film constituted of an oxide of the semiconductor chip 2.

The field insulating film 181 is formed as a band extending along an inner periphery (inner peripheral wall) of the trench separation structure 53 in a plan view. In this embodiment, the field insulating film 181 is formed in an annular shape extending along an inner peripheral wall of the trench separation structure 53 in a plan view and surrounds an entire periphery of the inner portion of the first device region 6. The field insulating film 181 has a side extending in one direction (first direction X) and a side extending in an intersecting direction (second direction Y) which intersects the one direction in a plan view. The field insulating film 181 continues to the separation insulating film 55 on the inner periphery (inner peripheral wall) side of the trench separation structure 53. The first device region 6 is demarcated by the trench separation structure 53 inside the semiconductor chip 2 and demarcated by the field insulating film 181 on the semiconductor chip 2.

The field insulating film 181 has an insulating side wall 182 which demarcates an inner portion of the first device region 6. The insulating side wall 182 is formed along an entire periphery of the field insulating film 181. The insulating side wall 182 has a side extending in one direction (first direction X) and a side extending in an intersecting direction (second direction Y) which intersects the one direction. The insulating side wall 182 is positioned on the body space 180 (body region 58). The insulating side wall 182 is inclined obliquely downward so as to form an acute angle with the first main surface 3. Specifically, the insulating side wall 182 has an upper end portion which is positioned on the main surface side of the field insulating film 181 and a lower end portion which is positioned on the first main surface 3 side and is inclined obliquely downward from the upper end portion to the lower end portion.

The insulating side wall 182 forms an inclination angle of not less than 20° and not more than 40° (20°≤θ≤40°) between the insulating side wall 182 and the first main surface 3. Where there is drawn a straight line that connects the upper end portion and the lower end portion of the insulating side wall 182 in a cross-sectional view, the inclination angle is an angle (absolute value) formed between the straight line and the first main surface 3 inside the field insulating film 181. The inclination angle is preferably less than 40° (θ<40°).

It is in particular preferable that the inclination angle falls within a range of 30°±6° (24°≤θ≤36°). Typically, the inclination angle falls within a range of not less than 28° and not more than 36° (28°≤θ≤36°). The insulating side wall 182 may be inclined in a curved shape which is recessed to the first main surface 3 in a region between the upper end portion and the lower end portion. In this case as well, where there is drawn a straight line that connects the upper end portion and the lower end portion of the insulating side wall 182 in a cross-sectional view, the inclination angle is an angle (absolute value) formed between the straight line and the first main surface 3.

According to the insulating side wall 182 having a relatively gentle inclination angle, it is possible to prevent electrode residue which is produced upon formation of the trench structure 61, etc., from remaining in a state that it adheres on the insulating side wall 182. Thereby, it is possible to decrease a risk of short circuit between the plurality of unit transistors 10 due to the electrode residue. in reducing a risk of short circuit between the first upper electrode 74A and the second upper electrode 74B due to the electrode residue, it is effective to dig down the electrode surface of the first upper electrode 74A and the electrode surface of the second upper electrode 74B deeper than the electrode surface of the separation electrode 56, etc.

The field insulating film 181 has a thickness exceeding the first thickness T1 of the upper insulating film 72. The thickness of the field insulating film 181 is a thickness along the normal direction Z of a portion other than the insulating side wall 182. The thickness of the field insulating film 181 preferably exceeds the intermediate thickness TM of the intermediate insulating film 76. The thickness of the field insulating film 181 may be substantially equal to the second thickness T2 of the lower insulating film 73. The thickness of the field insulating film 181 may be substantially equal to the separation thickness TI of the separation insulating film 55. The thickness of the field insulating film 181 may be not less than 0.1 μm and not more than 1 μm. The thickness of the field insulating film 181 is preferably not less than 0.15 μm and not more than 0.65 μm.

The semiconductor device 1 includes a main surface insulating film 183 which selectively covers the first main surface 3 in the first device region 6. The main surface insulating film 183 includes a silicon oxide film. It is in particular preferable that the main surface insulating film 183 includes a silicon oxide film constituted of an oxide of the semiconductor chip 2. The main surface insulating film 183 covers a region outside the trench structure 61, the first trench connection structure 90, the second trench connection structure 100 and the field insulating film 181 in the first main surface 3 and continues to the upper insulating film 72, the first connection insulating film 92, the second connection insulating film 102 and the field insulating film 181 (insulating side wall 182).

The main surface insulating film 183 has a thickness which is less than the thickness of the field insulating film 181. The thickness of the main surface insulating film 183 is preferably not more than one-fifth the thickness of the field insulating film 181. The thickness of the main surface insulating film 183 may be substantially equal to the first thickness T1 of the upper insulating film 72. The thickness of the main surface insulating film 183 may be not less than 0.01 μm and not more than 0.05 μm. The thickness of the main surface insulating film 183 is preferably not less than 0.02 μm and not more than 0.04 μm.

The semiconductor device 1 includes the aforementioned interlayer insulating layer 19 which covers the first main surface 3. The semiconductor device 1 includes a plurality of plug electrodes 191 to 197 which are embedded in the interlayer insulating layer 19. The plurality of plug electrodes 191 to 197 may be constituted of a plurality of first plug electrodes 191, a plurality of second plug electrodes 192, a plurality of third plug electrodes 193, a plurality of fourth plug electrodes 194, a plurality of fifth plug electrodes 195, at least one (in this embodiment, one) sixth plug electrode 196 and at least one (in this embodiment, one) seventh plug electrode 197. The plurality of plug electrodes 191 to 197 may be constituted of a tungsten plug electrode. In some of the attached drawings, the plurality of plug electrodes 191 to 197 are indicated, for simplification, by a cross mark or by a line.

The plurality of first plug electrodes 191 are each constituted of a source plug electrode for the separation electrode 56. The plurality of first plug electrodes 191 are each embedded at a portion which covers the trench separation structure 53 in the interlayer insulating layer 19. The plurality of first plug electrodes 191 are embedded at an interval along the separation electrode 56 and are each electrically connected to the separation electrode 56. The arrangement and shape of the plurality of first plug electrodes 191 are arbitrary. One or the plurality of first plug electrodes 191 extending as a band or in an annular shape in a plan view may be formed on the separation electrode 56.

The plurality of second plug electrodes 192 are each constituted of a gate plug electrode for the plurality of upper electrodes 74. The plurality of second plug electrodes 192 are each embedded at a portion which covers the plurality of trench structures 61 in the interlayer insulating layer 19. In this embodiment, the plurality of second plug electrodes 192 are each electrically connected to both end portions of the plurality of upper electrodes 74. The arrangement and shape of the plurality of second plug electrodes 192 are arbitrary. One or the plurality of second plug electrodes 192 extending as a band along the upper electrode 74 in a plan view may be formed on each of the upper electrodes 74.

The plurality of third plug electrodes 193 are each constituted of a source plug electrode for the plurality of channel cells 62. The plurality of third plug electrodes 193 are each embedded at a portion which covers the plurality of channel cells 62 in the interlayer insulating layer 19. The plurality of third plug electrodes 193 are each electrically connected to the plurality of source regions 77 and the plurality of contact regions 78. The arrangement and shape of the plurality of third plug electrodes 193 are arbitrary.

The plurality of fourth plug electrodes 194 are each constituted of a source plug electrode for the plurality of outermost contact regions 78. The plurality of fourth plug electrodes 194 are each embedded at a portion which covers the plurality of outermost contact regions 78 in the interlayer insulating layer 19. The plurality of fourth plug electrodes 194 are embedded at an interval along each of the outermost contact regions 78 and are each electrically connected to each of the outermost contact regions 78. The arrangement and shape of the plurality of fourth plug electrodes 194 are arbitrary. One or the plurality of fourth plug electrodes 194 extending as a band along the outermost contact region 78 in a plan view may be formed on each of the outermost contact regions 78.

The plurality of fifth plug electrodes 195 are each constituted of a gate plug electrode for the plurality of first and second connection electrodes 93 and 103. The plurality of fifth plug electrodes 195 are each embedded at a portion which covers the plurality of first and second connection electrodes 93 and 103 in the interlayer insulating layer 19. Each of the fifth plug electrodes 195 is electrically connected to the plurality of first and second connection electrodes 93 and 103. The arrangement and shape of the plurality of fifth plug electrodes 195 are arbitrary. One or the plurality of fifth plug electrodes 195 extending as a band along the plurality of first and second connection electrodes 93 and 103 in a plan view may be formed on the plurality of first and second connection electrodes 93 and 103.

The sixth plug electrode 196 is constituted of a source plug electrode for the first monitor channel cell 112. The sixth plug electrode 196 is embedded at a portion which covers the first monitor channel cell 112 in the interlayer insulating layer 19. The sixth plug electrode 196 is electrically connected to the plurality of first monitor source regions 127 and the plurality of first monitor contact regions 128. The arrangement and shape of the sixth plug electrode 196 are arbitrary. The plurality of sixth plug electrodes 196 may be arrayed at an interval along the first monitor channel cell 112 in a plan view.

The seventh plug electrode 197 is constituted of a source plug electrode for the second monitor channel cell 132. The seventh plug electrode 197 is embedded at a portion which covers the second monitor channel cell 132 in the interlayer insulating layer 19. The seventh plug electrode 197 is electrically connected to the plurality of second monitor source regions 147 and the plurality of second monitor contact regions 148. The arrangement and shape of the seventh plug electrode 197 are arbitrary. The plurality of seventh plug electrodes 197 may be arrayed at an interval along the second monitor channel cell 132 in a plan view.

The semiconductor device 1 includes one or a plurality of main source wirings 198 which are arranged inside the interlayer insulating layer 19 (see FIG. 13). One or the plurality of main source wirings 198 are constituted of a wiring layer formed inside the interlayer insulating layer 19. One or the plurality of main source wirings 198 are selectively routed inside the interlayer insulating layer 19, electrically connected to the separation electrode 56 via the plurality of first plug electrodes 191 and electrically connected to the source region 77 and the contact region 78 via the plurality of third plug electrodes 193 and the plurality of fourth plug electrodes 194. One or the plurality of main source wirings 198 are electrically connected to the aforementioned source terminal 23.

The semiconductor device 1 includes one or a plurality of monitor source wirings 199 which are arranged inside the interlayer insulating layer 19 (see FIG. 22 to FIG. 23 and FIG. 25 to FIG. 26). One or the plurality of monitor source wirings 199 are constituted of a wiring layer which is formed inside the interlayer insulating layer 19. One or the plurality of monitor source wirings 199 are selectively routed inside the interlayer insulating layer 19, electrically connected to the first monitor channel cell 112 via the sixth plug electrode 196 and electrically connected to the second monitor channel cell 132 via the seventh plug electrode 197. One or the plurality of monitor source wirings 199 are electrically connected to the aforementioned overcurrent protection circuit 17.

The semiconductor device 1 includes the aforementioned n-number of the main gate wirings 20 which are formed inside the interlayer insulating layer 19. The n-number of main gate wirings 20 are selectively routed inside the interlayer insulating layer 19. The n-number of the main gate wirings 20 are each electrically connected to one or the plurality of trench structures 61 (unit transistor 10) which are to be systematized as an individually controlled object in the first device region 6 and electrically connected to the aforementioned control IC 14 (gate control circuit 15) in the second device region 7.

In this embodiment, the n-number of the main gate wirings 20 include the first main gate wiring 20A and the second main gate wiring 20B. The first main gate wiring 20A is electrically connected to the first upper electrode 74A, the first lower electrode 75A and the first connection electrode 93 via the corresponding second plug electrode 192 and the corresponding fifth plug electrode 195 and imparts the first gate signal G1. The second main gate wiring 20B is electrically connected to the second upper electrode 74B, the second lower electrode 75B and the second connection electrode 103 via the corresponding second plug electrode 192 and the corresponding fifth plug electrode 195 and imparts the second gate signal G2.

The semiconductor device 1 includes the aforementioned n-number of the monitor gate wirings 21 which are formed inside the interlayer insulating layer 19. The n-number of the monitor gate wirings 21 are selectively routed inside the interlayer insulating layer 19. In this embodiment, the n-number of the monitor gate wirings 21 include the first monitor gate wiring 21A and the second monitor gate wiring 21B.

The first monitor gate wiring 21A is electrically connected to the first upper monitor electrode 124 and the first lower monitor electrode 125 via the corresponding second plug electrode 192 and the corresponding fifth plug electrode 195. In this embodiment, the first monitor gate wiring 21A is integrally formed with the first main gate wiring 20A. The second monitor gate wiring 21B is electrically connected to the second upper monitor electrode 144 and the second lower monitor electrode 145 via the corresponding second plug electrode 192 and the corresponding fifth plug electrode 195. In this embodiment, the second monitor gate wiring 21B is integrally formed with the second main gate wiring 20B.

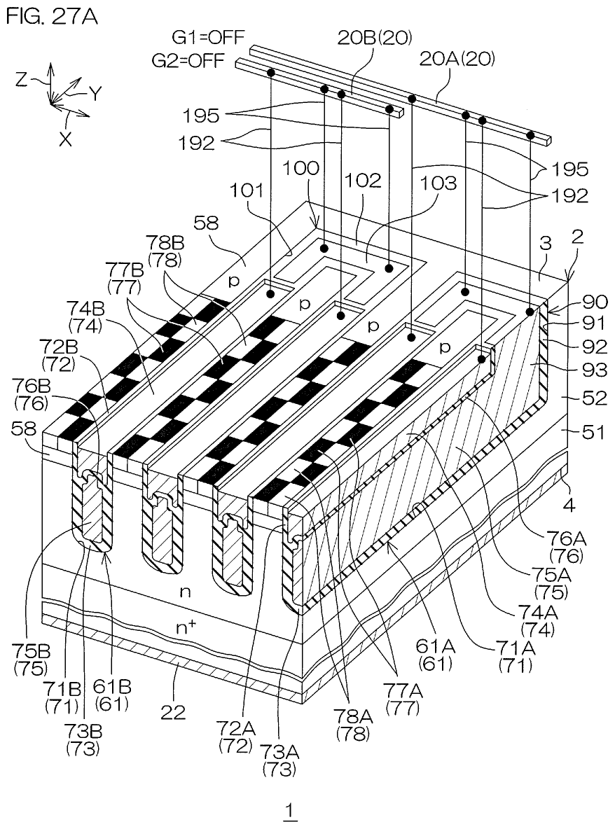

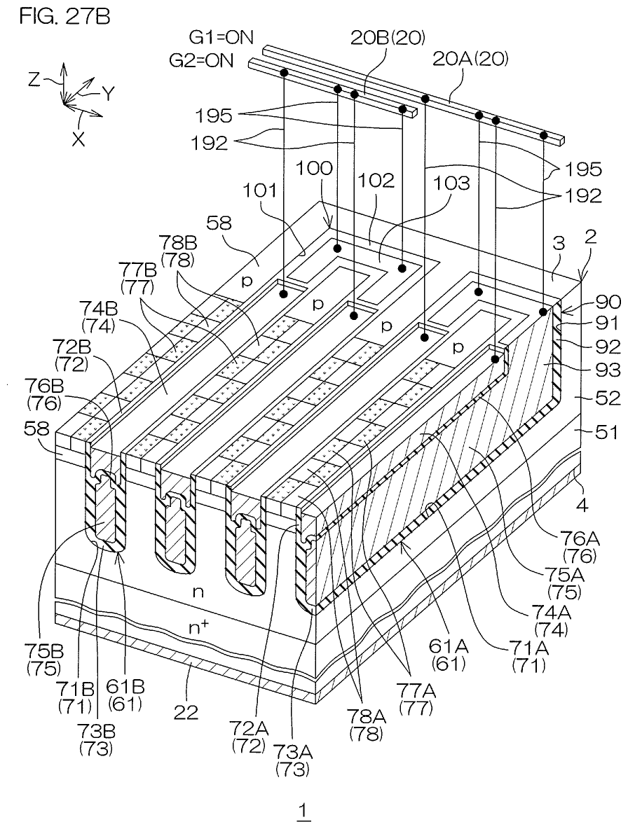

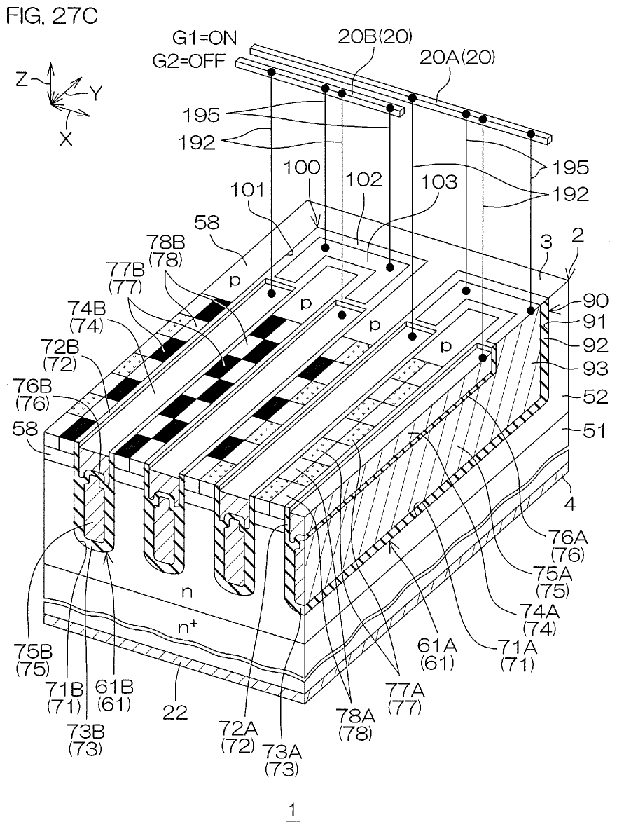

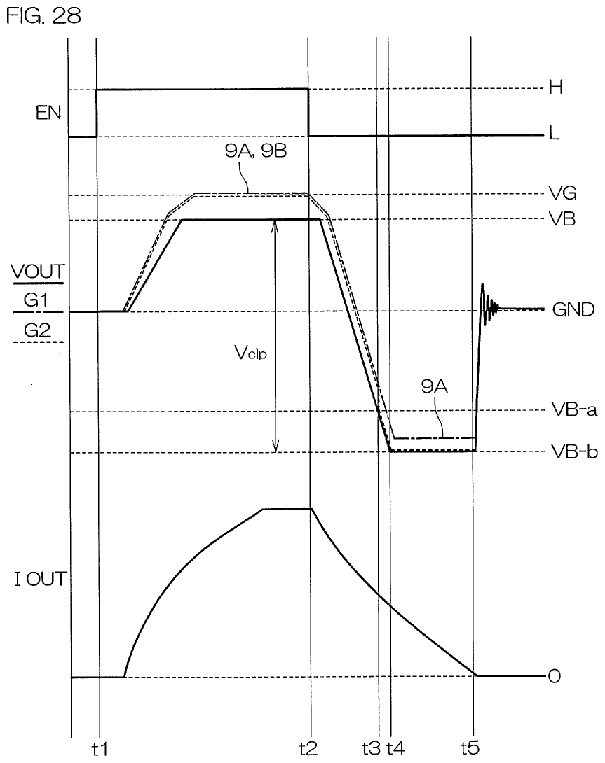

Hereinafter, with reference to FIG. 27A to FIG. 27C and FIG. 28 in addition to the circuit diagram of FIG. 9, a description of a control example of the 2-system main transistor 8 shall be given. FIG. 27A to FIG. 27C are each a cross-sectional perspective view which shows a control example of the main transistor 8. In FIG. 27A to FIG. 27C, there is shown a configuration example where the total channel ratio RT is 50%, the first system channel ratio RSA is 25% and the second system channel ratio RSB is 25% (also see FIG. 17). In FIG. 27A to FIG. 27C, a channel (source region 77) in an off state is indicated by a filled-in hatching. Hereinafter, it is assumed that the total monitor channel ratio RMT is 50%, the first system monitor channel ratio RSMA is 25%, and the second system monitor channel ratio RSMB is 25%.

FIG. 28 is a timing chart which shows the control example of the main transistor 8. There are sequentially shown, from the upper side of the sheet surface of FIG. 28, the enable signal EN, the output voltage VO (solid line), the first gate signal G1 (alternate long and short dashed line), the second gate signal G2 (broken line) and the output current IO. Hereinafter, a gate-source voltage of the first system transistor 9A is given as “Vgs1,” a gate-source voltage of the clamp MISFET 39 is given as “Vgs2,” a gate-source voltage of the drive MISFET 36 is given as “Vgs3,” a breakdown voltage of the Zener diode array 37 is given as “VZ” and a forward direction drop voltage of the diode array 38 is given as “VF.”

With reference to FIG. 28, the enable signal EN is kept at a low level up to a time t1. In the enable signal EN, the low level is a logical level when the main transistor 8 is turned off, and the high level is a logical level when the main transistor 8 is turned on. At this time, since the first and second gate signals G1 and G2 are kept at the low level (≈VOUT), and the first and second system transistors 9A and 9B are controlled so as to be in an off state (see FIG. 27A). This state corresponds to a first operation mode of the main transistor 8.

On the other hand, since the first and second gate signals G1 and G2 are kept in the low level, the first and second system monitor transistors 12A and 12B are controlled so as to be in an off state together with the first and second system transistors 9A and 9B.

At the time t1, the enable signal EN is controlled from a low level to a high level. When the enable signal EN is turned into the high level, the first and second gate signals G1 and G2 are raised from the low level (≈VOUT) to the high level (≈VG) and the first and second system transistors 9A and 9B are both controlled so as to be in an on state at the same time (see FIG. 27B). Thereby, the main transistor 8 is turned into a normal operation (first operation) state. This state corresponds to a second operation mode of the main transistor 8. When the first and second system transistors 9A and 9B are turned into an on state, the output current IO starts to flow. The output voltage VO rises to the vicinity of the power voltage VB. When in the normal operation, the main transistor 8 is driven at the total channel ratio RT (=50%).

On the other hand, when the first and second gate signals G1 and G2 are raised from a low level to a high level, the first and second system monitor transistors 12A and 12B are both controlled so as to be in an on state in conjunction with the first and second system transistors 9A and 9B. Thereby, the monitor transistor 11 is turned into a normal operation state. When the first and second system monitor transistors 12A and 12B are turned into an on state, the output monitor current IOM which monitors the output current IO is generated and output to the overcurrent protection circuit 17. When in the normal operation, the monitor transistor 11 is driven at the total monitor channel ratio RMT (=50%).

At a time t2, the enable signal EN is controlled from a high level to a low level. When the enable signal EN is turned into the low level, the first and second gate signals G1 and G2 are raised from the high level to the low level. At this time, the main transistor 8 continues to flow the output current IO until all of the energy which was accumulated in the inductive load L (see FIG. 9, etc.) during an on state is released. As a result, the output voltage VO abruptly drops down to a negative voltage lower than the ground voltage GND. Thereby, the main transistor 8 is shifted to an active clamp operation (second operation). Also, when the first and second gate signals G1 and G2 are lowered from a high level to a low level, the monitor transistor 11 is shifted to the active clamp operation in conjunction with the main transistor 8.

At a time t3, when the output voltage VO falls down to a channel switching voltage VB-a that is lower than the power voltage VB by a predetermined value a (=VZ+VF+Vgs3), the internal node voltage Vx becomes higher than the gate-source voltage Vgs3. Thereby, the drive MISFET 36 is turned into an on state, and a short circuit a gate-to-source portion of the second system transistor 9B is short-circuited (G2=VOUT). As a result, the second system transistor 9B is controlled so as to be in an off state. At this time, the second system monitor transistor 12B is controlled so as to be in an off state in conjunction with the second system transistor 9B.

On the other hand, at a time t4, when the output voltage VO drops down to a lower limit voltage VB-b which is lower than the power voltage VB by a predetermined value b (=VZ+VF+Vgs1+Vgs2), the first system transistor 9A is controlled so as to be in an on state by the active clamp circuit 16. The lower limit voltage VB-b is less than the channel switching voltage VB-a (VB-b<VB-a). At this time, the first system monitor transistor 12A is controlled so as to be in an on state in conjunction with the first system transistor 9A.

Therefore, the second system transistor 9B is completely stopped by the drive MISFET 36 before the active clamp circuit 16 is operated. Thereby, during the active clamp operation, the main transistor 8 is driven by the first system transistor 9A in a state that the second system transistor 9B is stopped (see FIG. 27C). This state corresponds to a third operation mode of the main transistor 8.

During the active clamp operation, the main transistor 8 is driven at the first system channel ratio RSA (=25%). That is, the main transistor 8 is controlled so that a channel utilization rate during the active clamp operation is more than zero and less than a channel utilization rate during a normal operation. In other words, the main transistor 8 is controlled so that an on-resistance during the active clamp operation is higher than an on-resistance during the normal operation.

Similarly, the second system monitor transistor 12B is completely stopped in conjunction with the second system transistor 9B before the active clamp circuit 16 is operated. Thereby, during the active clamp operation, the monitor transistor 11 is driven by the first system monitor transistor 12A in a state that the second system monitor transistor 12B is stopped.

The monitor transistor 11 is driven at the first system monitor channel ratio RSMA (=25%) during the active clamp operation. That is, the monitor transistor 11 is controlled so that a channel utilization rate during the active clamp operation is more than zero and less than a channel utilization rate during the normal operation. In other words, the monitor transistor 11 is controlled so that an on-resistance during the active clamp operation is higher than an on-resistance during the normal operation.

The output current IO is discharged via the first system transistor 9A. Thereby, the output voltage VO is limited to a voltage not less than the lower limit voltage VB-b. That is, the active clamp circuit 16 limits the output voltage VO on the basis of the power voltage VB and limits a drain-source voltage Vds (=VB−VOUT) of the main transistor 8 to a voltage not more than the clamp voltage Vclp (=b). The active clamp operation continues up to a time t5 when an energy which was accumulated at the inductive load L is completely released out and the output current IO no longer flows.

As described above, according to this control example, it is possible to provide the semiconductor device 1 having the on-resistance changeable main transistor 8 in which an on-resistance can be changed depending on an operation state. That is, according to the semiconductor device 1, during the normal operation (during a first operation), a current is allowed to flow by utilizing the first and second system transistors 9A and 9B. Thereby, an on-resistance can be decreased. On the other hand, during the active clamp operation (during a second operation), in a state that the second system transistor 9B is stopped, a current is allowed to flow by utilizing the first system transistor 9A. Thereby, it is possible to consume (absorb) the back electromotive force by the first system transistor 9A while suppressing an abrupt temperature rise due to a back electromotive force of the inductive load L.

In other words, according to the semiconductor device 1, the main transistor 8 is relatively increased in channel utilization rate during the normal operation, and the main transistor 8 is relatively decreased in channel utilization rate during the active clamp operation. Thereby, an on-resistance can be decreased. Also, since it is possible to suppress an abrupt temperature rise due to the back electromotive force of the inductive load L during the active clamp operation, it is possible to improve an active clamp tolerance Eac. As described above, according to the semiconductor device 1, it is possible to realize both an excellent on-resistance and an excellent active clamp tolerance Eac.

As described above, the semiconductor device 1 includes the n-system (n≥2) main transistor 8 and the m-system (m≥1) monitor transistor 11. The n-system main transistor 8 includes the n-number of the system transistors 9 which are individually subjected to on-off control and each generate the system current IS, and generate the output current IO which includes the plurality of system currents IS. The m-system monitor transistor 11 includes at least one system monitor transistor 12 which generates the system monitor current ISM corresponding to at least one system current IS. According to this structure, it is possible to provide the semiconductor device 1 capable of adding new control by utilizing the system current IS in a structure which has the main transistor 8 including the plurality of system transistors 9.

On/off control of the system monitor transistor 12 is preferably performed in conjunction with the corresponding system transistor 9. The system monitor transistor 12 preferably generates the system monitor current ISM in conjunction with the corresponding system current IS. The system monitor transistor 12 preferably generates the system monitor current ISM less than the corresponding system current IS. The system monitor transistor 12 is preferably connected in parallel to the corresponding system transistor 9.

The monitor transistor 11 is preferably constituted of an m-system (m≥2) monitor transistor including at least two system monitor transistors 12 which generate at least two system monitor currents ISM, each of which monitors at least two system currents IS. The monitor transistor 11 is preferably constituted of an n-system (n=m) monitor transistor including the n-number of the system monitor transistors 12 which generate the n-number of the system monitor currents ISM, each of which monitors the n-number of the system currents IS.

The main transistor 8 is preferably configured so that the system transistor 9 in an on state coexist with the system transistor 9 in an off state. The monitor transistor 11 is preferably configured so that the system monitor transistor 12 in an on state coexist with the system monitor transistor 12 in an off state. The monitor transistor 11 preferably generates the output monitor current IOM including the plurality of system monitor currents ISM.

The plurality of system monitor transistors 12 are preferably provided so as to be mutually adjacent to the corresponding system transistor 9. The plurality of system monitor transistors 12 may be provided so as to face each other across at least one system transistor 9. The plurality of system monitor transistors 12 may be provided so as to be mutually adjacent but not across the system transistor 9. The number of the system monitor transistors 12 is preferably not more than the number of the system transistors 9.

The main transistor 8 is preferably configured so as to be changed in on-resistance by individually controlling the n-number of the system transistors 9. The monitor transistor 11 is preferably configured so as to be changed in on-resistance in conjunction with the main transistor 8. The main transistor 8 is preferably controlled so that an on-resistance during an active clamp operation exceeds an on-resistance during a normal operation by individually controlling the n-number of the system transistors 9. The monitor transistor 11 is preferably controlled so that an on-resistance during the active clamp operation exceeds an on-resistance during the normal operation in conjunction with the main transistor 8.

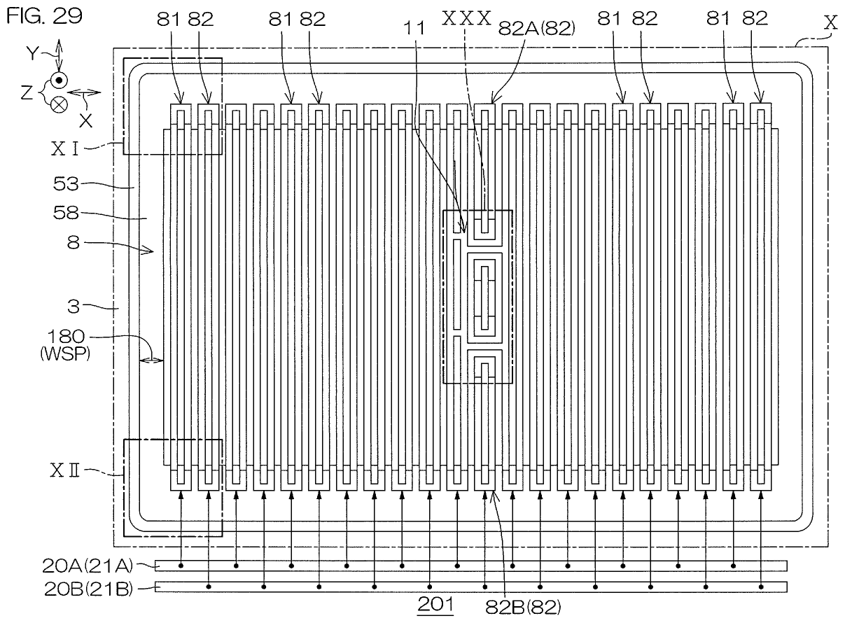

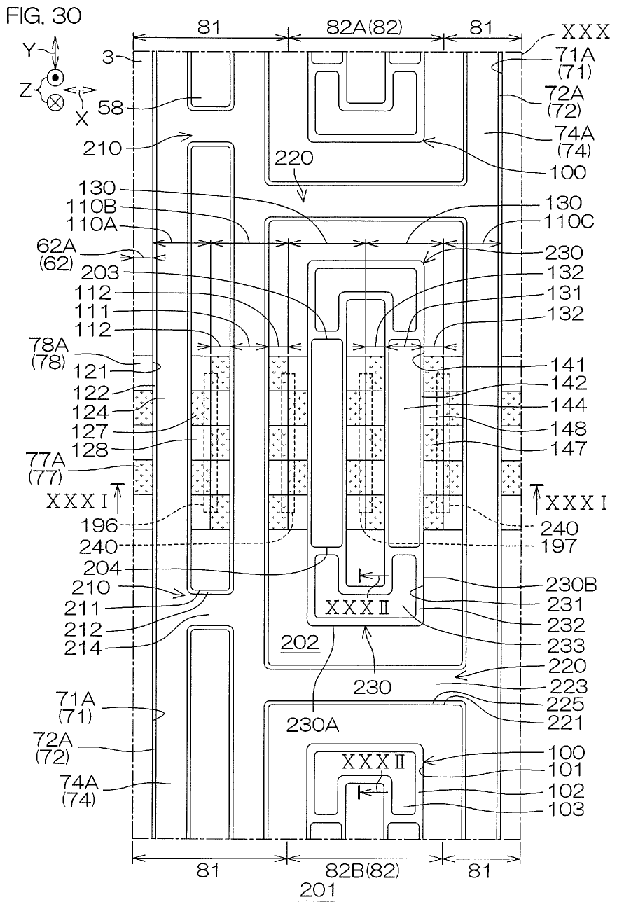

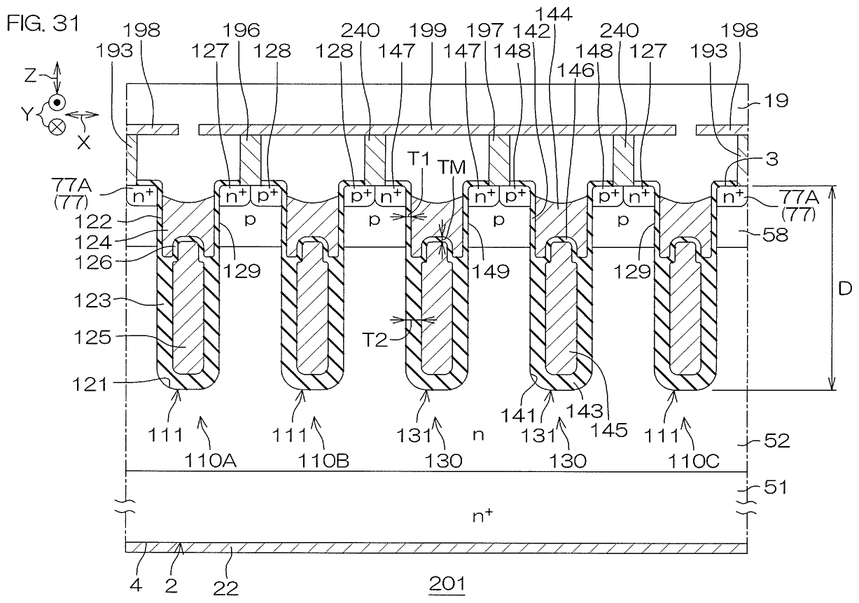

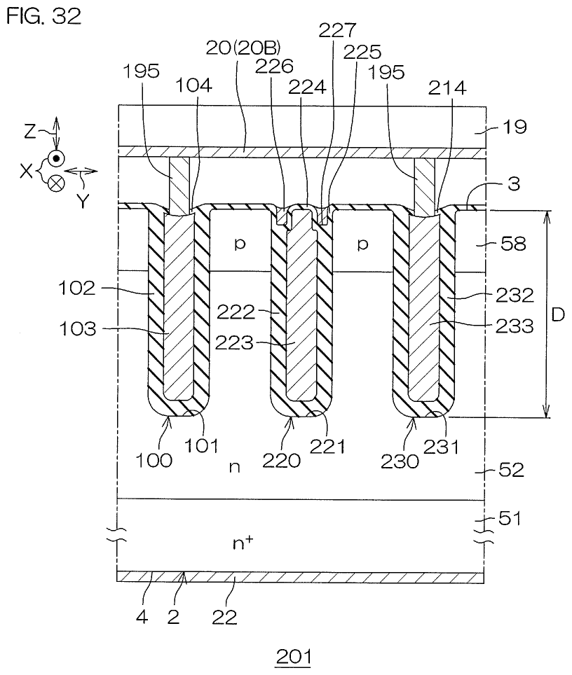

FIG. 29 is an enlarged view of the region X shown in FIG. 3 and a plan view which shows a layout example of a main transistor 8 and a monitor transistor 11 of a semiconductor device 201 according to the second embodiment. FIG. 30 is an enlarged view of a region XXX shown in FIG. 29. FIG. 31 is a cross-sectional view taken along line XXXI-XXXI shown in FIG. 30. FIG. 32 is a cross-sectional view taken along line XXXII-XXXII shown in FIG. 30.

With reference to FIG. 29 to FIG. 32, as with the first embodiment, the semiconductor device 201 includes the plurality of second composite cells 82 which are arrayed alternately with the plurality of first composite cells 81 so as to sandwich one first composite cell 81 therebetween in the first direction X. In this embodiment, the plurality of second composite cells 82 include two second composite cells 82A and 82B which are arranged in an arbitrary region, at an interval in the second direction Y.

In this embodiment, the second composite cells 82A and 82B are arranged in a region between the two first composite cells 81 at an inner portion (specifically, central portion) of the first device region 6. The second composite cells 82A and 82B each have a length less than a length of the other second composite cell 82 with regard to the second direction Y and demarcate a cell space 202 in a region therebetween. It is preferable that the second composite cells 82A and 82B each have a length that is less than one-half the length of the other second composite cell 82.

The semiconductor device 201 includes the plurality of first unit monitor cells 110 (first unit monitor transistors 13A) and the plurality of second unit monitor cells 130 (second unit monitor transistors 13B). In this embodiment, the semiconductor device 201 includes the three first unit monitor cells 110 and the two second unit monitor cells 130. In this embodiment, the plurality of first unit monitor cells 110 (first unit monitor transistors 13A) and the plurality of second unit monitor cells 130 (second unit monitor transistors 13B) are arrayed so as to be mutually adjacent at an inner portion of the first device region 6.

The three first unit monitor cells 110 include a first unit monitor cell 110A of a first layout, a first unit monitor cell 110B of a second layout and a first unit monitor cell 110C of a third layout sequentially from the third side surface 5C side. The first unit monitor cells 110A and 110B of the first and second layouts are arranged on one side (third side surface 5C side) in the first direction X with respect to the second composite cells 82A and 82B.

In this embodiment, the first unit monitor cells 110A and 110B are aligned in a single row in the first direction X so as to be positioned on extension lines of two first unit cell 60A and are each formed as a band extending in the second direction Y. The first unit monitor cells 110A and 110B are each connected to the first unit cell 60A which faces a cell space 202 in the first direction X and corresponds to it in the second direction Y. That is, the first unit monitor cells 110A and 110B are incorporated in the first composite cells 81 arranged on one side (third side surface 5C side) in the first direction X with respect to the cell space 202.

The first unit monitor cell 110C of the third layout is arranged on the other side (fourth side surface 5D side) in the first direction X with respect to the second composite cells 82A and 82B. The first unit monitor cell 110C is arranged so as to be positioned on an extension line of one first unit cell 60A. In this embodiment, the first unit monitor cell 110C is formed as a band extending in the second direction Y. The first unit monitor cell 110C faces the first unit monitor cells 110A and 110B across the cell space 202 in the first direction X and is connected to the first unit cell 60A corresponding thereto in the second direction Y. That is, the first unit monitor cell 110C is incorporated in the first composite cell 81 which is arranged on the other side (fourth side surface 5D side) in the first direction X with respect to the cell space 202.

As with the first embodiment, the first unit monitor cells 110A to 110C each include one first monitor trench structure 111 and the first monitor channel cell 112 which is controlled by the first monitor trench structure 111. The first monitor trench structures 111 of first to third layouts are each connected to the first trench structure 61A corresponding thereto in a one-to-one correspondence with regard to the second direction Y.

As with the first embodiment, each first monitor trench structure 111 has a multi-electrode structure including the first monitor trench 121, the first upper monitor insulating film 122, the first lower monitor insulating film 123, the first upper monitor electrode 124, the first lower monitor electrode 125 and the first intermediate monitor insulating film 126. As with the first embodiment, each first monitor channel cell 112 includes at least one first monitor source region 127, at least one first monitor contact region 128 and at least one first monitor channel region 129.

The first unit monitor cell 110A of the first layout includes one first monitor channel cell 112. The first monitor channel cell 112 of a first layout is formed as a band extending along the first monitor trench structure 111 on the first layout side in a region between the first monitor trench structures 111 of the first and second layouts.

The first unit monitor cell 110B of the second layout includes a pair of the first monitor channel cells 112. One of the first monitor channel cells 112 is formed as a band extending along the first monitor trench structure 111 on the second layout side in a region between the first monitor trench structures 111 of the first and second layouts. The other of the first monitor channel cells 112 is formed as a band extending along the first monitor trench structure 111 of the second layout in a region on the cell space 202 side. The first unit monitor cell 110C of the third layout includes one first monitor channel cell 112. The first monitor channel cell 112 of a third layout is formed as a band extending along the first monitor trench structure 111 of the third layout in the region on the cell space 202 side.

The first monitor channel cells 112 of the first to third layouts each have a length less than the length of the first monitor trench structures 111 of the first to third layouts with regard to the second direction Y. An entire area of each of the first monitor channel cells 112 of the first to third layouts faces the corresponding second upper monitor electrode 144 across the corresponding second upper monitor insulating film 142. The first monitor channel cells 112 of the first to third layouts each have a channel width equivalent to a value that is one-half the trench interval IT.

In a region between the plurality of first monitor trench structures 111, the plurality of first monitor channel regions 129 (first monitor source regions 127) arrayed on the side of one of the first monitor trench structures 111 preferably face a region between the plurality of first monitor channel regions 129 (first monitor source regions 127) arrayed on the side of the other of the first monitor trench structures 111 in the first direction X.

The first unit cell 60A in which the first unit monitor cell 110A of the first layout is incorporated includes the first channel cell 62A (hereinafter, referred to as the “monitor-side first channel cell 62A”) which is controlled by the first monitor trench structure 111. Also, the first unit cell 60A in which the first unit monitor cell 110C of the third layout is incorporated includes the monitor-side first channel cell 62A.

Each monitor-side first channel cell 62A faces the corresponding first unit monitor cell 110A across the first monitor trench structure 111. Each monitor-side first channel cell 62A preferably has a layout (length and channel area) which corresponds to the corresponding first unit monitor cell 110A with regard to the second direction Y. In each monitor-side first channel cell 62A, the plurality of first channel regions 79A (first source regions 77A) preferably face the plurality of first monitor channel regions 129 (first monitor source regions 127) across the corresponding first monitor trench structure 111.

Two second unit monitor cells 130 are arranged inside the cell space 202 so as to be mutually adjacent to the plurality of first unit monitor cells 110A to 110C in the first direction X and also arranged at an interval from the plurality of second composite cells 82A and 82B in the second direction Y. The two second unit monitor cells 130 face the plurality of first unit monitor cells 110A to 110C in the first direction X and face the plurality of second composite cells 82A and 82B in the second direction Y. The two second unit monitor cells 130 are arranged at an interval in the first direction X so as to be each positioned on extension lines of the two second unit cells 60B. In this embodiment, the two second unit monitor cells 130 are each formed as a band extending in the second direction Y.

As with the first embodiment, the two second unit monitor cells 130 each include one second monitor trench structure 131 and the second monitor channel cell 132 which is controlled by the second monitor trench structure 131. The two second monitor trench structures 131 are formed at an interval from the second composite cells 82A and 82B (four second trench structures 61B) in the second direction Y and each face the two second trench structures 61B corresponding thereto in a one-to-one correspondence in the second direction Y. Each second monitor trench structure 131 has a first end portion 203 on one side (second composite cell 82A side) and a second end portion 204 on the other side (second composite cell 82B side) with regard to the second direction Y.

As with the first embodiment, each second monitor trench structure 131 has a multi-electrode structure including the second monitor trench 141, the second upper monitor insulating film 142, the second lower monitor insulating film 143, the second upper monitor electrode 144, the second lower monitor electrode 145 and the second intermediate monitor insulating film 146. As with the first embodiment, each second monitor channel cell 132 includes at least one second monitor source region 147, at least one second monitor contact region 148 and at least one second monitor channel region 149.

The two second unit monitor cells 130 each include the pair of second monitor channel cells 132. The pair of second monitor channel cells 132 are each formed as a band extending in the second direction Y on both sides of each second monitor trench structure 131. The pair of second monitor channel cells 132 have a length less than the length of the second monitor trench structure 131 with regard to the second direction Y. The pair of second monitor channel cells 132 preferably have a layout (length and channel area) substantially equal to that of the plurality of first monitor channel cells 112 with regard to the second direction Y. The pair of second monitor channel cells 132 each have a channel width equivalent to a value that is one-half the trench interval IT.

The plurality of second monitor channel regions 149 (second monitor source regions 147) arrayed on the side of one of the second monitor trench structures 131 in a region between the plurality of second monitor trench structures 131 preferably face a region between the plurality of second monitor channel regions 149 (second monitor source regions 147) arrayed on the side of the other of the second monitor trench structures 131 in the first direction X. In a region between the first monitor trench structure 111 and the second monitor trench structure 131, the plurality of second monitor channel regions 149 (second monitor source regions 147) preferably face a region between the plurality of first monitor channel regions 129 (first monitor source regions 127) in the first direction X.

The monitor transistor 11 includes a plurality (in this embodiment, one pair, a total of two) of first monitor trench connection structures 210 which are formed in a first main surface 3 in the first device region 6. The pair of first monitor trench connection structures 210 are formed in a region between the first monitor trench structures 111 of the first and second layouts. The pair of first monitor trench connection structures 210 are formed at an interval in the second direction Y so as to sandwich the first monitor channel cells 112 of the first and second layouts therebetween in the second direction Y in a plan view and are each formed as a band extending in the first direction X.

The pair of first monitor trench connection structures 210 are connected to the first monitor trench structures 111 of the first and second layouts and electrically separate the first monitor channel cells 112 of the first and second layouts from the first channel cell 62A. With the first monitor trench structures 111 of the first and second layouts, the pair of first monitor trench connection structures 210 configure one annular-shaped trench structure.

The pair of first monitor trench connection structures 210 demarcate a region sandwiched between the first monitor trench structures 111 of the first and second layouts from a region sandwiched between the two first trench structures 61A. That is, the pair of first monitor trench connection structures 210 divide the first composite cell 81 into three regions. The pair of first monitor trench connection structures 210 have a length corresponding to the trench interval IT with regard to the first direction X. In this embodiment, the pair of first monitor trench connection structures 210 are each connected to the first monitor trench structures 111 of the first and second layouts so as to form a T-junction with the first monitor trench structures 111 of the first and second layouts in a plan view.

The pair of first monitor trench connection structures 210 are formed at an interval from the first channel cell 62A and the first monitor channel cell 112 with regard to the second direction Y and face the first channel cell 62A and the first monitor channel cells 112 of the first and second layouts across the body region 58. The plurality of first monitor trench connection structures 210 are connected only to the body region 58 with regard to the first direction X and the second direction Y and are not connected to the first channel cell 62A, the second channel cell 62B, the first monitor channel cell 112 and the second monitor channel cell 132 with regard to the first direction X and the second direction Y.

The pair of first monitor trench connection structures 210 have a multi-electrode structure including a first monitor connection trench 211, an upper monitor connection insulating film 212, a lower monitor connection insulating film 213, an upper monitor connection electrode 214, a lower monitor connection electrode 215 and an intermediate monitor connection insulating film 216. The first monitor connection trench 211, the upper monitor connection insulating film 212, the lower monitor connection insulating film 213, the upper monitor connection electrode 214, the lower monitor connection electrode 215 and the intermediate monitor connection insulating film 216 each have a structure respectively corresponding to the first monitor connection trench 161, the first upper monitor connection insulating film 162, the first lower monitor connection insulating film 163, the first upper monitor connection electrode 164, the first lower monitor connection electrode 165 and the first intermediate monitor connection insulating film 166 according to the first embodiment.

The monitor transistor 11 includes a plurality (in this embodiment, one pair, a total of two) of second monitor trench connection structures 220 which are formed in the first main surface 3 in the first device region 6. The pair of second monitor trench connection structures 220 are formed at an interval in the second direction Y so as to sandwich the two second unit monitor cells 130 therebetween in the second direction Y in a region between the first monitor trench structures 111 of the second and third layouts in a plan view and are each formed as a band extending in the first direction X. That is, the pair of second monitor trench connection structures 220 demarcate the cell space 202 together with the first monitor trench structures 111 of the second and third layouts. Also, the pair of second monitor trench connection structures 220 electrically separate the cell space 202 from the plurality of second composite cells 82A and 82B.

The pair of second monitor trench connection structures 220 are connected to the first monitor trench structures 111 of the second and third layouts and each electrically separate the first monitor channel cells 112 and the second monitor channel cells 132 of the second and third layouts from the first channel cell 62A and the second channel cell 62B. The pair of second monitor trench connection structures 220 configure one annular-shaped trench structure which demarcates the cell space 202 from the first monitor trench structures 111 of the second and third layouts.

The pair of second monitor trench connection structures 220 demarcate a region sandwiched between the first monitor trench structures 111 of the second and third layouts from a region sandwiched between the two first trench structures 61A. That is, the pair of second monitor trench connection structures 220 divides a region sandwiched by the two first composite cells 81 into three regions in the second direction Y. The pair of second monitor trench connection structures 220 has a length corresponding to a distance between the pair of first composite cells 81 with regard to the first direction X. That is, the length of the second monitor trench connection structure 220 exceeds the length of a first monitor trench connection structure 160.

The pair of second monitor trench connection structures 220 are formed at an interval from the first channel cell 62A, the second channel cell 62B, the first monitor channel cell 112 and the second monitor channel cell 132 with regard to the second direction Y and face the first channel cell 62A, the second channel cell 62B, the first monitor channel cell 112 and the second monitor channel cell 132 across the body region 58. The plurality of second monitor trench connection structures 220 are connected only to the body region 58 with regard to the first direction X and the second direction Y and are not connected to the first channel cell 62A, the second channel cell 62B, the first monitor channel cell 112 and the second monitor channel cell 132 in the first direction X and the second direction Y.

In this embodiment, the pair of second monitor trench connection structures 220 are formed so as to be shifted in the second direction Y with respect to the pair of first monitor trench connection structures 210 so as not to be positioned on extension lines of the pair of first monitor trench connection structures 210 with regard to the first direction X. In this embodiment, the pair of second monitor trench connection structures 220 are each connected to the first monitor trench structures 111 of the second and third layouts so as to form a T-junction intersection with the first monitor trench structures 111 of the second and third layouts in a plan view.

The pair of second monitor trench connection structures 220 may be each connected to the first monitor trench structures 111 of the second and third layouts so as to be positioned on the extension lines of the pair of first monitor trench connection structures 210. That is, the first monitor trench connection structure 210 and the second monitor trench connection structure 220 may be connected to the first monitor trench structure 111 of the second layout so as to form a crossroads in a plan view.

In this embodiment, the pair of second monitor trench connection structures 220 have an inner structure different from the first monitor trench connection structure 210. Specifically, the pair of second monitor trench connection structures 220 have a single electrode structure including a second monitor connection trench 221, a first monitor connection insulating film 222, a first monitor connection electrode 223, a first monitor cap insulating film 224, an opening-side insulating film 225 and a side wall portion 226.

The second monitor connection trench 221 is dug down from the first main surface 3 toward the second main surface 4. The second monitor connection trench 221 is formed at an interval from the bottom portion of the second semiconductor region 52 to the first main surface 3 side. The second monitor connection trench 221 includes a side wall and a bottom wall. An angle formed between the side wall of the second monitor connection trench 221 and the first main surface 3 inside the semiconductor chip 2 may be not less than 90° and not more than 92°. The second monitor connection trench 221 may be formed in a tapered shape in which an opening width is narrowed from an opening to the bottom wall. A corner portion of the bottom wall of the second monitor connection trench 221 is preferably formed in a curved shape. An entirety of the bottom wall of the second monitor connection trench 221 may be formed in a curved shape toward the second main surface 4.

The first monitor connection insulating film 222 is formed as a film on a wall surface of the second monitor connection trench 221 and demarcates a recess space inside the second monitor connection trench 221. In this embodiment, the first monitor connection insulating film 222 exposes the side wall of the second monitor connection trench 221 on the opening side of the second monitor connection trench 221. The first monitor connection insulating film 222 preferably includes a silicon oxide film. It is in particular preferable that the first monitor connection insulating film 222 includes a silicon oxide film constituted of an oxide of the semiconductor chip 2. The first monitor connection insulating film 222 has the second thickness T2, as with the lower monitor connection insulating film 213.

The first monitor connection electrode 223 is embedded as an integrated member in the second monitor connection trench 221 across the first monitor connection insulating film 222. The first monitor connection electrode 223 is connected to both of the first upper monitor electrode 124 and the first lower monitor electrode 125 at a communicatively connected portion of the second monitor connection trench 221 and the first monitor trenches 121 of the second and third layouts. Therefore, the first monitor gate signal MG1 (first gate signal G1) is to be input into the first monitor connection electrode 223.

The first monitor connection electrode 223 is formed so as to protrude further on the first main surface 3 side than an upper end portion of the first monitor connection insulating film 222. The first monitor connection electrode 223 has an upper end portion which faces the side wall of the second monitor connection trench 221 in a direction along the first main surface 3. The upper end portion of the first monitor connection electrode 223 demarcates an upper end recess portion 227 between the upper end portion of the first monitor connection insulating film 222 and the side wall of the second monitor connection trench 221. The upper end recess portion 227 is formed further in a region on the first main surface 3 side than a bottom portion of the first upper monitor electrode 124 (upper monitor connection electrode 214). In this embodiment, the first monitor connection electrode 223 includes conductive polysilicon.

The first monitor cap insulating film 224 covers the upper end portion of the first monitor connection electrode 223 as a film inside the second monitor connection trench 221. The first monitor cap insulating film 224 continues to the first monitor connection insulating film 222. The second monitor cap insulating film 234 preferably includes the same insulating material (silicon oxide film) as the first cap insulating film 94, etc.

The opening-side insulating film 225 covers a side wall which is exposed from the first monitor connection insulating film 222 inside the second monitor connection trench 221. The opening-side insulating film 225 is thinner than the first monitor connection insulating film 222 and has the first thickness T1, as with the first upper insulating film 72A. The opening-side insulating film 225 continues to the first monitor connection insulating film 222. The opening-side insulating film 225 preferably includes the same insulating material (silicon oxide film) as the first cap insulating film 94, etc.

The side wall portion 226 is embedded in the upper end recess portion 227 across the first monitor connection insulating film 222, the first monitor cap insulating film 224 and the opening-side insulating film 225. That is, the side wall portion 226 is embedded in a region further on the first main surface 3 side than a depth position of the bottom portion of the first upper monitor electrode 124 (upper monitor connection electrode 214). In a cross-sectional view which crosses the second monitor trench connection structure 220, one first monitor connection electrode 223 and two side wall portions 226 which are positioned on both sides of the first monitor connection electrode 223 appear.

The side wall portion 226 faces the first monitor connection electrode 223 across the first monitor cap insulating film 224 and faces the semiconductor chip 2 (body region 58) across the opening-side insulating film 225. The side wall portion 226 does not face the first monitor source region 127, the first monitor contact region 128, the second monitor source region 147 and the second monitor contact region 148 across the opening-side insulating film 225. In this embodiment, the side wall portion 226 is formed in an electrically floating state. The side wall portion 226 may be electrically connected to the first monitor connection electrode 223. In this embodiment, the side wall portion 226 includes conductive polysilicon.

The monitor transistor 11 includes a pair of third monitor trench connection structures 230 which are formed in the first main surface 3 in the cell space 202. The pair of third monitor trench connection structures 230 includes the third monitor trench connection structure 230 on one side (second composite cell 82A side) and the third monitor trench connection structure 230 on the other side (second composite cell 82B side) which are formed at an interval so as to sandwich the two second unit monitor cells 130 therebetween in the second direction Y.

The third monitor trench connection structure 230 on one side is formed at an interval from the second monitor trench connection structure 220 to the pair of second monitor trench structures 131 side. The third monitor trench connection structure 230 on one side connects the first end portions 203 of the pair of second monitor trench structures 131 each other in an arch shape in a plan view. The third monitor trench connection structure 230 on the other side is formed at an interval from the second monitor trench connection structure 220 to the pair of second monitor trench structures 131 side. The third monitor trench connection structure 230 on the other side connects the second end portions 204 of the pair of second monitor trench structures 131 each other in an arch shape in a plan view. With the pair of second monitor trench structures 131, the pair of third monitor trench connection structures 230 configure one annular-shaped trench structure.

The third monitor trench connection structure 230 on the other side has the same structure as the third monitor trench connection structure 230 on one side except that it is connected to the second end portion 204 of the second monitor trench structure 131. Hereinafter, a description of a configuration of the third monitor trench connection structure 230 on one side shall be given and a description of a configuration of the third monitor trench connection structure 230 on the other side shall be omitted.

The third monitor trench connection structure 230 has a first portion 230A extending in the first direction X and a pair of second portions 230B extending in the second direction Y. The first portion 230A faces the two first end portions 203 in a plan view. The pair of second portions 230B extend from the first portion 230A toward the two first end portions 203 and are connected to the two first end portions 203. The third monitor trench connection structure 230 has the connection width WC and the connection depth DC, as with the first trench connection structure 90, etc.

In this embodiment, the third monitor trench connection structure 230 has a single electrode structure including a third monitor connection trench 231, a second monitor connection insulating film 232, a second monitor connection electrode 233 and a second monitor cap insulating film 234. The third monitor connection trench 231 extends in an arch shape so as to be communicatively connected to the first end portions 203 of the two second monitor trenches 141 in a plan view and is dug down from the first main surface 3 toward the second main surface 4. The third monitor connection trench 231 demarcates the first portion 230A and the second portions 230B of the third monitor trench connection structure 230. The third monitor connection trench 231 is formed at an interval from the bottom portion of the second semiconductor region 52 to the first main surface 3 side.

The third monitor connection trench 231 includes a side wall and a bottom wall. An angle formed between the side wall of the third monitor connection trench 231 and the first main surface 3 inside the semiconductor chip 2 may be not less than 90° and not more than 92°. The third monitor connection trench 231 may be formed in a tapered shape in which an opening width is narrowed from an opening to the bottom wall. A corner portion of the bottom wall of the third monitor connection trench 231 is preferably formed in a curved shape. An entirety of the bottom wall of the third monitor connection trench 231 may be formed in a curved shape toward the second main surface 4. The side wall and the bottom wall of the third monitor connection trench 231 are smoothly connected to the side wall and the bottom wall of the second monitor trench 141.

The second monitor connection insulating film 232 is formed on a wall surface of the third monitor connection trench 231. Specifically, the second monitor connection insulating film 232 is formed as a film in an entire area of the wall surface of the third monitor connection trench 231 and demarcates a recess space inside the third monitor connection trench 231. The second monitor connection insulating film 232 extends in the first direction X at the first portion 230A of the third monitor connection trench 231. The second monitor connection insulating film 232 extends in the second direction Y at the second portions 230B of the third monitor connection trench 231. The second monitor connection insulating film 232 preferably includes the same insulating material (silicon oxide film) as the first connection insulating film 92, etc. The second monitor connection insulating film 232 has the third thickness T3, as with the first connection insulating film 92.

The second monitor connection electrode 233 is embedded as an integrated member in the third monitor connection trench 231 across the second monitor connection insulating film 232. In this embodiment, the second monitor connection electrode 233 includes conductive polysilicon. The second monitor connection electrode 233 extends in the first direction X at the first portion 230A of the third monitor connection trench 231. The second monitor connection electrode 233 extends in the second direction Y at the second portions 230B of the third monitor connection trench 231. The second monitor connection electrode 233 is connected to the second lower monitor electrode 145 at a communicatively connected portion of the second monitor trench 141 and the third monitor connection trench 231.

The second monitor connection electrode 233 is electrically insulated from the second upper monitor electrode 144 across the second intermediate monitor insulating film 146. That is, the second monitor connection electrode 233 is constituted of a lead-out portion which is led out from the second monitor trench 141 to the third monitor connection trench 231 across the second monitor connection insulating film 232 and the second intermediate monitor insulating film 146 in the second lower monitor electrode 145. Therefore, the second monitor gate signal MG2 (second gate signal G2) is to be input into the second monitor connection electrode 233.

The second monitor connection electrode 233 has an electrode surface which is exposed from the third monitor connection trench 231. The electrode surface of the second monitor connection electrode 233 may be recessed in a curved shape toward the bottom wall of the third monitor connection trench 231. The electrode surface of the second monitor connection electrode 233 is preferably positioned (protrudes) further on the first main surface 3 side than a depth position of the electrode surface of the second upper monitor electrode 144 (upper electrode 74 of trench structure 61) of the second monitor trench structure 131 with regard to a depth direction of the third monitor connection trench 231. The electrode surface of the second monitor connection electrode 233 is preferably at an interval of not less than 0 Å and less than 2000 Å from the first main surface 3 to the bottom wall of the third monitor connection trench 231. It is in particular preferable that the electrode surface of the second monitor connection electrode 233 is at an interval of less than 1000 Å from the first main surface 3 to the bottom wall of the third monitor connection trench 231.

The second monitor cap insulating film 234 covers the electrode surface of the second monitor connection electrode 233 as a film inside the third monitor connection trench 231. The second monitor cap insulating film 234 prevents a short circuit of the second monitor connection electrode 233 with another electrode. The second monitor cap insulating film 234 continues to the second monitor connection insulating film 232. The second monitor cap insulating film 234 preferably includes the same insulating material (silicon oxide film) as the first cap insulating film 94, etc.

The semiconductor device 201 includes a plurality of eighth plug electrodes 240 which are embedded in the interlayer insulating layer 19, in addition to the first to seventh plug electrodes 191 to 197. The eighth plug electrode 240 may be constituted of a tungsten plug electrode. The plurality of first plug electrodes 191, the plurality of third plug electrodes 193, the plurality of fourth plug electrodes 194, the sixth plug electrode 196 and the seventh plug electrode 197 are each formed in the same manner as those of the first embodiment.

In this embodiment, the plurality of second plug electrodes 192 are each constituted of a gate plug electrode for the plurality of upper electrodes 74 and the plurality of second upper monitor electrodes 144. In this embodiment, the plurality of second plug electrodes 192 are also each embedded at a portion which covers the plurality of second upper monitor electrodes 144 in the interlayer insulating layer 19. In this embodiment, the plurality of second plug electrodes 192 are each electrically connected to both end portions of the plurality of second upper monitor electrodes 144. The arrangement and shape of the plurality of second plug electrodes 192 are arbitrary. One or the plurality of second plug electrodes 192 extending as a band along the second upper monitor electrode 144 in a plan view may be formed on each of the second upper monitor electrodes 144.

In this embodiment, the plurality of fifth plug electrodes 195 are each constituted of a gate plug electrode for the plurality of first and second connection electrodes 93 and 103 and the plurality of second monitor connection electrodes 233. The plurality of fifth plug electrodes 195 are also each embedded at a portion that covers each of the plurality of second monitor connection electrodes 233 in the interlayer insulating layer 19 and electrically connected to the plurality of second monitor connection electrodes 233. The arrangement and shape of the plurality of fifth plug electrodes 195 are arbitrary. One or the plurality of fifth plug electrodes 195 extending as a band along each of the second monitor connection electrodes 233 in a plan view may be formed on each of the second monitor connection electrodes 233.

The plurality of eighth plug electrodes 240 are each constituted of a common source plug electrode for the first monitor channel cell 112 and the second monitor channel cell 132. The plurality of eighth plug electrodes 240 are each embedded at a portion which covers the first monitor channel cell 112 and the second monitor channel cell 132 in the interlayer insulating layer 19. The plurality of eighth plug electrodes 240 are electrically connected to the plurality of first monitor source regions 127, the plurality of first monitor contact regions 128, the plurality of second monitor source regions 147 and the plurality of second monitor contact regions 148. The arrangement and shape of the plurality of eighth plug electrodes 240 are arbitrary. The plurality of eighth plug electrodes 240 may be arrayed at an interval along the first monitor channel cell 112 and the second monitor channel cell 132 in a plan view.

In this embodiment, one or a plurality of monitor source wirings 199 are electrically connected to the first monitor channel cell 112 and the second monitor channel cell 132 via the sixth plug electrode 196, the seventh plug electrode 197 and the eighth plug electrode 240. One or the plurality of monitor source wirings 199 are electrically connected to the aforementioned overcurrent protection circuit 17.

In this embodiment, the first monitor gate wiring 21A is electrically connected to the first upper monitor electrode 124, the first lower monitor electrode 125 and the first monitor connection electrode 223 via the corresponding second plug electrode 192. The first monitor gate wiring 21A may be integrally formed with the first main gate wiring 20A.

The second monitor gate wiring 21B intersects the second monitor trench connection structure 220 in a plan view and extends over a second trench connection structure 100 and the third monitor trench connection structure 230. The second monitor gate wiring 21B is electrically connected to the second connection electrode 103 of the second trench connection structure 100 via the corresponding fifth plug electrode 195 and electrically connected to the second monitor connection electrode 233 of the third monitor trench connection structure 230 via the corresponding fifth plug electrode 195. The second monitor gate wiring 21B may be integrally formed with the second main gate wiring 20B.

As described above, the same effects as the effects described for the semiconductor device 1 can be exhibited also by the semiconductor device 201.

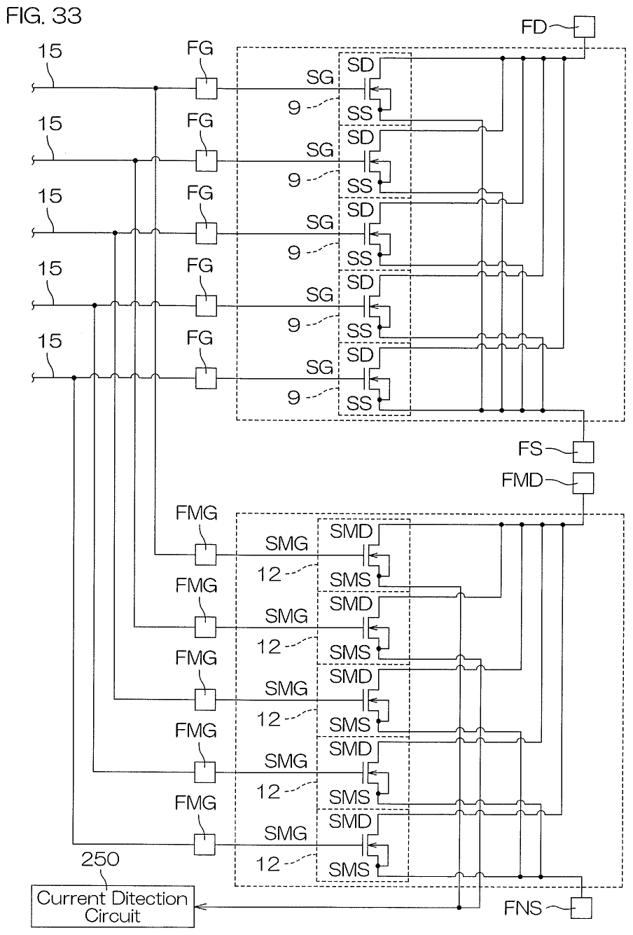

Hereinafter, modification examples of the monitor transistor 11 are shown. FIG. 33 is an equivalent circuit diagram which shows the circuit diagram of FIG. 5 together with the monitor transistor 11 according to a first modification example. In each of the above-described embodiments, an example where the system monitor currents ISM of the plurality of system monitor transistors 12 are taken out as the output monitor current IOM from the first monitor drain FMD and the first monitor source FMS was shown.

However, the second monitor source SMS of at least one system monitor transistor 12 may be electrically separated from the first monitor source FMS and may form a current path which is electrically independent of the first monitor source FMS. That is, in the monitor transistor 11, a structure in which at least one system monitor current ISM is individually taken out may be adopted. Also, in the monitor transistor 11, the plurality of system monitor currents ISM may be individually taken out via a plurality of current paths or the same current path.

In FIG. 33, an example where the second monitor sources SMS of the two system monitor transistors 12 form a current path which is electrically independent of the first monitor source FMS, and two system monitor currents ISM are taken out from a current path different from that of the output monitor current IOM was shown. For example, where the three-system main transistor 8 including the first to third system transistors 9 is adopted, the output monitor current IOM may be constituted of the system monitor currents ISM of the first and second system transistors 9, and the system monitor current ISM of the third system transistor 9 may be taken out from a current path different from that of the output monitor current IOM.

The system monitor current ISM that is different from the output monitor current IOM may be input into, for example, a current detection circuit 250 included in the control IC 14. The control IC 14 may be configured so as to control the main transistor 8 on the basis of the system monitor current ISM input into the current detection circuit 250 or may be configured so as to control a functional circuit other than the main transistor 8 (for example, a state detection circuit such as an overvoltage protection circuit and an overheating protection circuit).

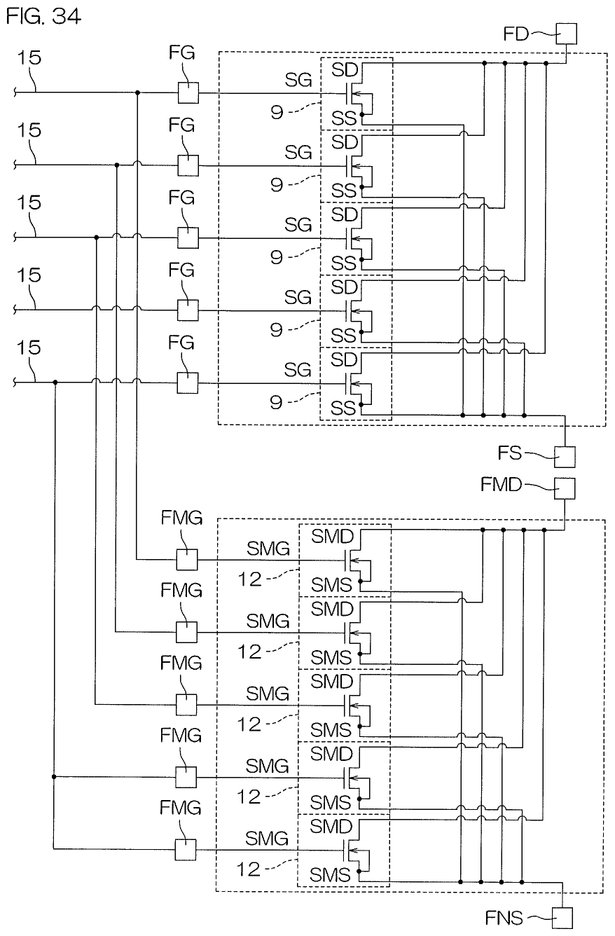

FIG. 34 is an equivalent circuit diagram which shows the circuit diagram of FIG. 5 together with the monitor transistor 11 according to a second modification example. In each of the above-described embodiments, an example where the plurality of system monitor transistors 12 are connected to the corresponding system transistor 9 in a one-to-one correspondence was shown. However, the plurality of first monitor gates FMG may be connected to one first gate FG.

That is, the monitor transistor 11 may include the plurality of system monitor transistors 12 which generate the plurality of system monitor currents ISM monitoring one system current IS. At least one or all of the plurality of system monitor currents ISM monitoring one system current IS may configure a part of the output monitor current IOM. At least one or all of the plurality of system monitor currents ISM monitoring one system current IS may configure the system monitor current ISM different from the output monitor current IOM as shown in FIG. 33.

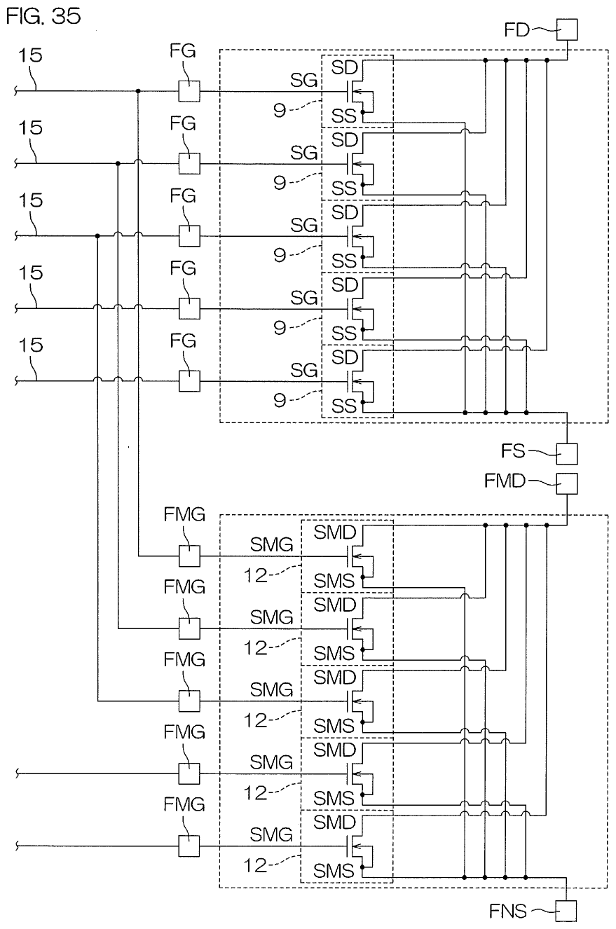

FIG. 35 is an equivalent circuit diagram which shows the circuit diagram of FIG. 5 together with the monitor transistor 11 of a third modification example. In each of the above-described embodiments, an example where the monitor transistor 11 includes the system monitor transistor 12 which is electrically connected to the system transistor 9 was shown. However, the monitor transistor 11 may include at least one system monitor transistor 12 which is electrically independent of the system transistor 9.

That is, at least one first monitor gate FMG of the monitor transistor 11 may be controlled by at least one monitor gate signal MG which is electrically independent of the gate signal G. In this case, the monitor transistor 11 may be configured so as to generate the output monitor current IOM in which a current corresponding to at least one system monitor current ISM that is electrically independent is added to another system monitor current ISM.

Each of the above-described embodiments can be executed by still other embodiments. In each of the above-described embodiments, a description of a specific structure of the two-system main transistor 8 and the two-system monitor transistor 11 has been given. Where the n-system main transistor 8 is adopted, the n-number of the system transistors 9 each include at least one unit cell 60. Also, where the m-system (n-system) monitor transistor 11 is adopted, the m-number (n-number) of the system monitor transistors 12 each include at least one unit monitor cell (a cell corresponding to the first unit monitor cell 110 or the second unit monitor cell 130). An electrical connection mode of the n-number of the system transistors 9 and the m-number (n-number) of the system monitor transistors 12 is adjusted by the number of the plurality of plug electrodes 191 to 197 and 240, the number of the plurality of main source wirings 198, the number of the plurality of monitor source wirings 199, the number of the plurality of main gate wirings 20, etc., or a manner that they are routed.

In each of the above-described embodiments, a description of an example where, during the active clamp operation, the first system transistor 9A and the first system monitor transistor 12A are controlled so as to be in an on state, and the second system transistor 9B and the second system monitor transistor 12B are controlled so as to be in an off state has been given. However, during the active clamp operation, the second system transistor 9B and the second system monitor transistor 12B may be controlled so as to be in an on state, and the first system transistor 9A and the first system monitor transistor 12A may be controlled so as to be in an off state. In this case, a relationship between the first system transistor 9A and the second system transistor 9B as well as a relationship between the first system monitor transistor 12A and the second system monitor transistor 12B may be understood by replacing one of the relationships with the other of the relationships.

In each of the above-described embodiments, a description of an example where one gate control circuit 15 is connected to the main transistor 8 and the monitor transistor 11 has been given. However, a structure that the first gate control circuit 15 is connected to the main transistor 8 and the second gate control circuit 15 is connected to the monitor transistor 11 may be adopted. In this case, the monitor transistor 11 may be controlled so as to work with the main transistor 8 or may be controlled so as not to work with the main transistor 8.

In each of the above-described embodiments, a description of an example where one active clamp circuit 16 is connected to the main transistor 8 and the monitor transistor 11 has been given. However, a structure that the first active clamp circuit 16 is connected to the main transistor 8 and the second active clamp circuit 16 is connected to the monitor transistor 11 may be adopted.

In each of the above-described embodiments, a description of the semiconductor device 1, 201 which has the control IC 14 has been given. However, the semiconductor device 1, 201 which does not have control IC 14 may be adopted.

In each of the above-described embodiments, a description of an example where the first lower electrode 75A is fixed at the same potential as the first upper electrode 74A has been given. However, the first lower electrode 75A may be fixed at a potential different from the first upper electrode 74A. In this case, the first lower electrode 75A may be formed as a source electrode and may be fixed at a source potential. According to this structure, it is possible to lower a parasitic capacitance between the semiconductor chip 2 and the first lower electrode 75A. Thereby, the first unit transistor 10A (main transistor 8) can be improved in switching speed.

In each of the above-described embodiments, a description of an example where the second lower electrode 75B is fixed at the same potential as the second upper electrode 74B has been given. However, the second lower electrode 75B may be fixed at a potential different from the second upper electrode 74B. In this case, the second lower electrode 75B may be formed as a source electrode and may be fixed at a source potential. According to this structure, it is possible to lower a parasitic capacitance between the semiconductor chip 2 and the second lower electrode 75B. Thereby, the second unit transistor 10B (main transistor 8) can be improved in switching speed.

In each of the above-described embodiments, a description of an example where the first lower monitor electrode 125 is fixed at the same potential as the first upper monitor electrode 124 has been given. However, the first lower monitor electrode 125 may be fixed at a potential different from the first upper monitor electrode 124. In this case, the first lower monitor electrode 125 may be formed as a source electrode and fixed at a source potential. According to this structure, it is possible to lower a parasitic capacitance between the semiconductor chip 2 and the first lower monitor electrode 125. Thereby, the unit monitor transistor 13 (monitor transistor 11) can be improved in switching speed.

In each of the above-described embodiments, a description of an example where the second lower monitor electrode 145 is fixed at the same potential as the second upper monitor electrode 144 has been given. However, the second lower monitor electrode 145 may be fixed at a potential different from the second upper monitor electrode 144. In this case, the second lower monitor electrode 145 may be formed as a source electrode and fixed at a source potential. According to this structure, it is possible to lower a parasitic capacitance between the semiconductor chip 2 and the second lower monitor electrode 145. Thereby, the unit monitor transistor 13 (monitor transistor 11) can be improved in switching speed.

In the above-described first embodiment, a description of a structure in which the first composite cell 81 is divided into three regions by the two first monitor trench connection structures 160 has been given. However, a region for the first unit cell 60A (first unit transistor 10A) may be formed on one side of the first composite cell 81 in the second direction Y and a region for the first unit monitor cell 110 (first unit monitor transistor 13A) may be formed on the other side of the first composite cell 81 in the second direction Y.

In this case, the first composite cell 81 may be divided by one first monitor trench connection structure 160 into a region for the first unit cell 60A and a region for the first unit monitor cell 110. As a matter of course, two first trench structures 61A of the first composite cell 81 may be utilized as two first monitor trench structures 111, and an entirety of a region sandwiched between the two first monitor trench structures 111 may be used as a region for the first unit monitor cell 110 (first unit monitor transistor 13A).

In the above-described first embodiment, a description of a structure in which the second composite cell 82 is divided into three regions by the two second monitor trench connection structures 170 has been given. However, a region for the second unit cell 60B (second unit transistor 10B) may be formed on one side of the second composite cell 82 in the second direction Y, and a region for the second unit monitor cell 130 (second unit monitor transistor 13B) may be formed on the other side of the second composite cell 82 in the second direction Y.

In this case, the second composite cell 82 may be divided by one second monitor trench connection structure 170 into a region for the second unit cell 60B and a region for the second unit monitor cell 130. As a matter of course, two second trench structures 61B of the second composite cell 82 may be utilized as two second monitor trench structures 131, and an entirety of a region sandwiched between the two second monitor trench structures 131 may be used as a region for the second unit monitor cell 130 (second unit monitor transistor 13B).

In the above-described second embodiment, a description of a structure in which the first composite cell 81 is divided into three regions by the two first monitor trench connection structures 210 has been given. However, a region for the first unit cell 60A (first unit transistor 10A) may be formed on one side of the first composite cell 81 in the second direction Y, and a region for the first unit monitor cell 110 (first unit monitor transistor 13A) may be formed on the other side of the first composite cell 81 in the second direction Y.

In this case, the first composite cell 81 may be divided by one first monitor trench connection structure 210 into a region for the first unit cell 60A and a region for the first unit monitor cell 110. As a matter of course, two first trench structures 61A of the first composite cell 81 may be utilized as two first monitor trench structures 111, and an entirety of a region sandwiched between the two first monitor trench structures 111 may be used as a region for the first unit monitor cell 110 (first unit monitor transistor 13A).

In the above-described second embodiment, a description of an example where two second composite cells 82A and 82B are formed at an interval in the second direction Y and one second unit monitor cell 130 is formed at the cell space 202 therebetween has been given. However, one of or both of the two second composite cells 82A and 82B may be removed. In this case, the first unit monitor cell 110 and/or the second unit monitor cell 130 can be extended up to a site at which one of or both of the second composite cells 82A and 82B was formed. In this case as well, the second unit monitor cell 130 is preferably demarcated from other regions by the pair of second monitor trench connection structures 220. As a matter of course, the plurality of second unit monitor cells 130 may be formed at the cell space 202.

In the above-described embodiments, a description of an example where the first conductivity type is an n-type and the second conductivity type is a p-type has been given, however, the first conductivity type may be a p-type and the second conductivity type may be an n-type. A specific configuration of this case is obtained by replacing the n-type region with the p-type region and replacing the n-type region with the p-type region in the above description and attached drawings.

Hereinafter, examples of features extracted from this description and the drawings are shown. Hereinafter, a semiconductor device capable of adding new control by utilizing a current of a system transistor in a structure which has a main transistor including a plurality of system transistors shall be provided. Hereinafter, although alphanumeric characters within parentheses express corresponding components, etc., in the above-described embodiments, these are not meant to limit the scopes of respective items (Clauses) to the embodiments.
[A1] A semiconductor device (1, 201) comprising: an n-system main transistor (8) which includes the n-number (n≥2) of system transistors (9) that are individually subjected to on/off control and each generate a system current (IS), and which generates an output current (IO) including a plurality of the system currents (IS); and an m-system (m≥1) monitor transistor (11) which includes at least one system monitor transistor (12) that generates a system monitor current (ISM) corresponding to at least one of the system currents (IS).
[A2] The semiconductor device (1, 201) according to A1, wherein the system monitor transistor (12) generates the system monitor current (ISM) in conjunction with an increase or a decrease in the corresponding system current (IS).
[A3] The semiconductor device (1, 201) according to A1 or A2, wherein the system monitor transistor (12) generates the system monitor current (ISM) that is less than the corresponding system current (IS).
[A4] The semiconductor device (1, 201) according to any one of A1 to A3, wherein the system monitor transistor (12) is connected in parallel to the corresponding system transistor (9).
[A5] The semiconductor device (1, 201) according to any one of A1 to A4, wherein the monitor transistor (11) is constituted of an m-system (m≥2) monitor transistor (11) including at least two of the system monitor transistors (12) which generate at least two of the system monitor currents (ISM), each of which corresponds to at least two of the system currents (IS).
[A6] The semiconductor device (1, 201) according to any one of A1 to A5, wherein the monitor transistor (11) is constituted of an n-system (n=m) monitor transistor (11) including the n-number of the system monitor transistors (12) which generate the n-number of the system monitor currents (ISM), each of which corresponds to the n-number of the system currents (IS).
[A7] The semiconductor device (1, 201) according to A5 or A6, wherein the main transistor (8) is configured so that the system transistor (9) in an on state coexist with the system transistor (9) in an off state, and the monitor transistor (11) is configured so that the system monitor transistor (12) in an on state coexist with the system monitor transistor (12) in an off state.
[A8] The semiconductor device (1, 201) according to any one of A5 to A7, wherein the monitor transistor (11) generates the output monitor current (IOM) including a plurality of the system monitor currents (ISM).
[A9] The semiconductor device (1, 201) according to any one of A5 to A8, wherein a plurality of the system monitor transistors (12) are provided so as to be mutually adjacent to the corresponding system transistor (9).
[A10] The semiconductor device (1, 201) according to any one of A5 to A9, wherein a plurality of the system monitor transistors (12) are provided so as to be adjacent to each other.
[A11] The semiconductor device (1, 201) according to any one of A1 to A10, wherein the number of the system monitor transistors (12) is not more than the number of the system transistors (9).
[A12] The semiconductor device (1, 201) according to any one of A1 to A11, wherein the main transistor (8) is configured so as to be changed in on-resistance by individually controlling the n-number of the system transistors (9), and the monitor transistor (11) is configured so as to be changed in on-resistance in conjunction with the main transistor (8).
[A13] The semiconductor device (1, 201) according to A12, wherein the main transistor (8) is controlled so that an on-resistance during an active clamp operation exceeds an on-resistance during a normal operation by individually controlling the n-number of the system transistors (9), and the monitor transistor (11) is controlled so that an on-resistance during the active clamp operation exceeds an on-resistance during the normal operation in conjunction with the main transistor (8).
[A14] The semiconductor device (1, 201) according to any one of A1 to A13, wherein the system transistor (9) includes one or a plurality of unit transistors (10) which are systematized as an individually controlled object, and the system monitor transistor (12) includes one or a plurality of unit monitor transistors (13) which are systematized as an individually controlled object.
[A15] The semiconductor device (1, 201) according to A14, wherein the system transistor (9) includes a unit parallel circuit which is constituted of one or the plurality of unit transistors (10), and the system monitor transistor (12) includes a unit monitor parallel circuit which is constituted of one or the plurality of unit monitor transistors (13).
[A16] The semiconductor device (1, 201) according to A15, wherein the unit transistor (10) includes a trench structure (61) that has a gate electrode (74, 75) inside a trench (71), and the unit monitor transistor (13) includes a monitor trench structure (111, 131) that has a monitor gate electrode (124, 125, 144, 145) inside a monitor trench (121, 141).
[A17] The semiconductor device (1, 201) according to A16, wherein the monitor trench (121, 141) is communicatively connected to the trench (71), and the monitor gate electrode (124, 125, 144, 145) is connected to the gate electrode (74, 75) at a communicatively connected portion of the trench (71) and the monitor trench (121, 141).
[A18] The semiconductor device (1, 201) according to A16 or A17, wherein the gate electrode (74, 75) has a multi-electrode structure including an upper electrode (74) and a lower electrode (75) which are embedded inside the trench (71) so as to be insulated and separated in an up/down direction, and the monitor gate electrode (124, 125, 144, 145) has a multi-electrode structure including an upper monitor electrode (124, 144) and a lower monitor electrode (125, 145) which are embedded inside the monitor trench (121, 141) so as to be insulated and separated in an up/down direction.
[A19] The semiconductor device (1, 201) according to A18, wherein the upper monitor electrode (124, 144) is electrically connected to the upper electrode (74), and the lower monitor electrode (125, 145) is electrically connected to the lower electrode (75).
[A20] The semiconductor device (1, 201) according to A18 or A19, wherein the lower electrode (75) is electrically connected to the upper electrode (74), and the lower monitor electrode (125, 145) is electrically connected to the upper monitor electrode (124, 144).
[B1] A semiconductor device (1, 201) comprising: a main transistor (8) which includes a first system transistor (9, 9A) generating a first system current (IS, IS1) and a second system transistor (9, 9B) generating a second system current (IS, IS2) independently of the first system transistor (9, 9A), and which generates an output current (IO) including the first system current (IS, IS1) and the second system current (IS, IS2); a first system monitor transistor (12, 12A) which generates a first system monitor current (ISM, ISM1) that corresponds to the first system current (IS, IS1); and a second system monitor transistor (12, 12B) which generates a second system monitor current (ISM, ISM2) that corresponds to the second system current (IS, IS2).
[B2] The semiconductor device (1, 201) according to B1, wherein on/off control of the first system monitor transistor (12, 12A) is performed in conjunction with the first system transistor (9, 9A), and on/off control of the second system monitor transistor (12, 12B) is performed in conjunction with the second system transistor (9, 9B).
[B3] The semiconductor device (1, 201) according to B1 or B2, wherein the first system monitor current (ISM, ISM1) is less than the first system current (IS, IS1), and the second system monitor current (ISM, ISM2) is less than the second system current (IS, IS2).
[B4] The semiconductor device (1, 201) according to any one of B1 to B3, wherein the first system monitor transistor (12, 12A) is electrically connected to the first system transistor (9, 9A), and the second system monitor transistor (12, 12B) is electrically connected to the second system transistor (9, 9B).
[B5] The semiconductor device (1, 201) according to any one of B1 to B4, wherein a drain (SMD) of the first system monitor transistor (12, 12A) is electrically connected to a drain (SD) of the first system transistor (9, 9A), and a drain (SMD) of the second system monitor transistor (12, 12B) is electrically connected to a drain (SD) of the second system transistor (9, 9B).
[B6] The semiconductor device (1, 201) according to any one of B1 to B5, wherein a source (SMS) of the first system monitor transistor (12, 12A) is electrically separated from a source (SS) of the first system transistor (9, 9A), and a source (SMS) of the second system monitor transistor (12, 12B) is electrically separated from a source (SS) of the second system transistor (9, 9B).
[B7] The semiconductor device (1, 201) according to any one of B1 to B6, wherein a source (SMS) of the second system monitor transistor (12, 12B) is electrically connected to a source (SMS) of the first system monitor transistor (12, 12A).
[B8] The semiconductor device (1, 201) according to any one of B1 to B7, wherein a gate (SMG) of the first system monitor transistor (12, 12A) is electrically connected to a gate (SG) of the first system transistor (9, 9A), and a gate (SMG) of the second system monitor transistor (12, 12B) is electrically connected to a gate (SG) of the second system transistor (9, 9B).
[B9] The semiconductor device (1, 201) according to any one of B1 to B8, wherein the first system monitor transistor (12, 12A) is connected in parallel to the first system transistor (9, 9A), and the second system monitor transistor (12, 12B) is connected in parallel to the second system transistor (9, 9B).
[B10] The semiconductor device (1, 201) according to any one of B1 to B9, further comprising: a monitor transistor (11) which includes the first system monitor transistor (12, 12A) and the second system monitor transistor (12, 12B), and which generates an output monitor current (IOM) including the first system monitor current (ISM, ISM1) and the second system monitor current (ISM, ISM2).
[B11] The semiconductor device (1, 201) according to B10, wherein the main transistor (8) is configured so that the first system transistor (9, 9A) in an on state coexist with the second system transistor (9, 9B) in an off state, and the monitor transistor (11) is configured so that the first system monitor transistor (12, 12A) in an on state coexist with the second system monitor transistor (12, 12B) in an off state.
[B12] The semiconductor device (1, 201) according to B10 or B11, wherein the main transistor (8) is configured so as to be changed in on-resistance by individually controlling the first system transistor (9, 9A) and the second system transistor (9, 9B), and the monitor transistor (11) is configured so as to be changed in on-resistance by individually controlling the first system monitor transistor (12, 12A) and the second system monitor transistor (12, 12B).
[B13] The semiconductor device (1, 201) according to B12, wherein the monitor transistor (11) is configured so as to be changed in on-resistance in conjunction with the main transistor (8).
[B14] The semiconductor device (1, 201) according to B12 or B13, wherein the main transistor (8) is controlled so that an on-resistance during an active clamp operation exceeds an on-resistance during a normal operation, and the monitor transistor (11) is controlled so that an on-resistance during the active clamp operation exceeds an on-resistance during the normal operation.
[B15] The semiconductor device (1, 201) according to any one of B1 to B14, wherein the first system transistor (9, 9A) has a trench gate structure (61A), the second system transistor (9, 9B) has a trench gate structure (61B), the first system monitor transistor (12, 12A) has a trench gate structure (111), and the second system monitor transistor (12, 12B) has a trench gate structure (131).
[B16] The semiconductor device (1, 201) according to any one of B1 to B15, wherein the first system monitor transistor (12, 12A) is provided so as to be mutually adjacent to one of or both of the first system transistor (9, 9A) and the second system transistor (9, 9B), and the second system monitor transistor (12, 12B) is provided so as to be mutually adjacent to one of or both of the first system transistor (9, 9A) and the second system transistor (9, 9B).
[B17] The semiconductor device (1, 201) according to any one of B1 to B16, wherein the first system monitor transistor (12, 12A) is provided so as to be mutually adjacent to the second system monitor transistor (12, 12B).
[B18] The semiconductor device (1, 201) according to any one of B1 to B17, wherein the first system transistor (9, 9A), the second system transistor (9, 9B), the first system monitor transistor (12, 12A) and the second system monitor transistor (12, 12B) are provided in one device region (6).
[B19] The semiconductor device (1, 201) according to any one of B1 to B18, wherein the first system transistor (9, 9A) includes one or a plurality of first unit transistors (10, 10A) which are systematized as an individually controlled object, the second system transistor (9, 9B) includes one or a plurality of second unit transistors (10, 10B) which are systematized as an individually controlled object, the first system monitor transistor (12, 12A) includes one or a plurality of first unit monitor transistors (13, 13A) which are systematized as an individually controlled object, and the second system monitor transistor (12, 12B) includes one or a plurality of second unit monitor transistors (13, 13B) which are systematized as an individually controlled object.
[B20] The semiconductor device (1, 201) according to any one of B1 to B19, further comprising: a gate control circuit (15) which is electrically connected to the first system transistor (9, 9A) and the second system transistor (9, 9B), imparts a first gate signal (G1) to the first system transistor (9, 9A) and imparts a second gate signal (G2) to the second system transistor (9, 9B); and an overcurrent protection circuit (17) which is configured so as to detect an overcurrent in the main transistor on the basis of one of or both of the first system monitor current (ISM, ISM1) and the second system monitor current (ISM, ISM2) and limits one of or both of the first gate signal (G1) and the second gate signal (G2) upon detection of the overcurrent.

In the aforementioned [A1] to [A20] and the aforementioned [B1] to [B20], the “semiconductor device” may be replaced by an “electric circuit” or a “semiconductor circuit.” In this case, an “electric circuit” or a “semiconductor circuit” capable of adding another control can be provided in a structure that has a main transistor including a plurality of system transistors.

While the embodiments of the present invention have been described in detail, these are merely specific examples used to clarify the technical contents of the present invention and the present invention should not be interpreted as being limited to these specific examples, and the scope of the present invention is to be limited by the appended claims.

What is claimed is:

1. A semiconductor device comprising:
a main transistor which includes a first system transistor generating a first system current and a second system transistor generating a second system current independently of the first system transistor, and which generates an output current including the first system current and the second system current;
a first system monitor transistor which generates a first system monitor current that corresponds to the first system current; and
a second system monitor transistor which generates a second system monitor current that corresponds to the second system current.

2. The semiconductor device according to claim 1,
wherein on/off control of the first system monitor transistor is performed in conjunction with the first system transistor, and
on/off control of the second system monitor transistor is performed in conjunction with the second system transistor.

3. The semiconductor device according to claim 1,
wherein the first system monitor current is less than the first system current, and
the second system monitor current is less than the second system current.

4. The semiconductor device according to claim 1,
wherein the first system monitor transistor is electrically connected to the first system transistor, and
the second system monitor transistor is electrically connected to the second system transistor.

5. The semiconductor device according to claim 1,
wherein a drain of the first system monitor transistor is electrically connected to a drain of the first system transistor, and
a drain of the second system monitor transistor is electrically connected to a drain of the second system transistor.

6. The semiconductor device according to claim 1,
wherein a source of the first system monitor transistor is electrically separated from a source of the first system transistor, and
a source of the second system monitor transistor is electrically separated from a source of the second system transistor.

7. The semiconductor device according to claim 1,
wherein a source of the second system monitor transistor is electrically connected to a source of the first system monitor transistor.

8. The semiconductor device according to claim 1,
wherein a gate of the first system monitor transistor is electrically connected to a gate of the first system transistor, and
a gate of the second system monitor transistor is electrically connected to a gate of the second system transistor.

9. The semiconductor device according to claim 1,
wherein the first system monitor transistor is connected in parallel to the first system transistor, and
the second system monitor transistor is connected in parallel to the second system transistor.

10. The semiconductor device according to claim 1, further comprising:
a monitor transistor which includes the first system monitor transistor and the second system monitor transistor, and which generates an output monitor current including the first system monitor current and the second system monitor current.

11. The semiconductor device according to claim 10,
wherein the main transistor is configured so that the first system transistor in an on state coexist with the second system transistor in an off state, and
the monitor transistor is configured so that the first system monitor transistor in an on state coexist with the second system monitor transistor in an off state.

12. The semiconductor device according to claim 10,
wherein the main transistor is configured so as to be changed in on-resistance by individually controlling the first system transistor and the second system transistor, and
the monitor transistor is configured so as to be changed in on-resistance by individually controlling the first system monitor transistor and the second system monitor transistor.

13. The semiconductor device according to claim 12,
wherein the monitor transistor is configured so as to be changed in on-resistance in conjunction with the main transistor.

14. The semiconductor device according to claim 12,
wherein the main transistor is controlled so that an on-resistance during an active clamp operation exceeds an on-resistance during a normal operation, and
the monitor transistor is controlled so that an on-resistance during the active clamp operation exceeds an on-resistance during the normal operation.

15. The semiconductor device according to claim 1,
wherein the first system monitor transistor is provided so as to be mutually adjacent to one of or both of the first system transistor and the second system transistor, and
the second system monitor transistor is provided so as to be mutually adjacent to one of or both of the first system transistor and the second system transistor.

16. The semiconductor device according to claim 1,
wherein the first system monitor transistor is provided so as to be mutually adjacent to the second system monitor transistor.

17. The semiconductor device according to claim 1,
wherein the first system transistor, the second system transistor, the first system monitor transistor and the second system monitor transistor are provided in one device region.

18. The semiconductor device according to claim 1,
wherein the first system transistor incudes one or a plurality of first unit transistors which are systematized as an individually controlled object,
the second system transistor includes one or a plurality of second unit transistors which are systematized as an individually controlled object,
the first system monitor transistor includes one or a plurality of first unit monitor transistors which are systematized as an individually controlled object, and
the second system monitor transistor includes one or a plurality of second unit monitor transistors which are systematized as an individually controlled object.

19. A semiconductor device comprising:
a main transistor which includes a plurality of system transistors that are individually subjected to on/off control and each generate a system current, and which generates an output current including a plurality of the system currents; and
a monitor transistor which includes at least one system monitor transistor generating a system monitor current that corresponds to at least one of the system currents.

20. The semiconductor device according to claim 19,
wherein the system monitor transistor generates the system monitor current in conjunction with the corresponding system current.
